(19) United States
(12) Patent Application Publication
(10) Pub. No.: US 2025/0291250 A1
(43) Pub. Date: Sep. 18, 2025

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, AND METHOD FOR PRODUCING ELECTRONIC DEVICE

(71) Applicant: FUJIFILM CORPORATION, Tokyo (JP)

(72) Inventors: Tsutomu Yoshimura, Haibara-gun (JP); Masafumi Kojima, Haibara-gun (JP); Akiyoshi Goto, Haibara-gun (JP); Asahi Takaki, Haibara-gun (JP); Hideyuki Ishihara, Haibara-gun (JP)

(21) Appl. No.: 19/003,735

(22) Filed: Dec. 27, 2024

Related U.S. Application Data
(63) Continuation of application No. PCT/JP2023/021619, filed on Jun. 9, 2023.

(30) Foreign Application Priority Data
Jun. 29, 2022 (JP) 2022-105172
Mar. 10, 2023 (JP) 2023-037998

(51) Int. Cl. G03F 7/039; G03F 7/00; H01L 21/027

(52) U.S. Cl. CPC G03F 7/0397; H01L 21/0274; G03F 7/70033

(57) ABSTRACT

An actinic ray-sensitive or radiation-sensitive resin composition including: a resin (A) including a repeating unit (i) of a formula (N-0) below, a repeating unit (ii) having a cyano group and a lactone structure, and a repeating unit (iii) having a phenolic hydroxy group, wherein a content of a repeating unit having an acid-decomposable group in the resin (A) relative to all repeating units in the resin (A) is 35 mol % or more,

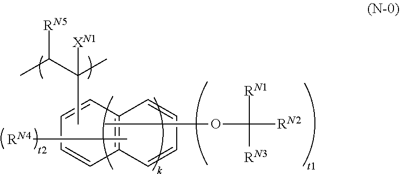

in the formula (N-0), each of X^{N1}, R^{N1} to R^{N3}, R^{N4} and R^{N5} represent a specific atom or a specific group; k represents 0 or 1; R^{N4} and R^{N5}, as well as any two among R^{N1} to R^{N3} may be bonded together to form a ring; when multiple R^{N1} to R^{N4} are present, R^{N1} to R^{N4} may be individually the same or different; and each of t1 and t2 represents a specific integer.

### CROSS REFERENCE TO RELATED APPLICATION

This is a continuation of International Application No. PCT/JP2023/021619 filed on Jun. 9, 2023, and claims priorities from Japanese Patent Application No. 2022-105172 filed on Jun. 29, 2022 and Japanese Patent Application No. 2023-037998 filed on Mar. 10, 2023, the entire disclosures of which are incorporated herein by reference.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, and a method for producing an electronic device.

### 2. Description of the Related Art

In the manufacturing process of semiconductor devices such as IC (Integrated Circuit, integrated circuits) and LSI (LargeScale Integrated circuit, large-scale integrated circuits), microfabrication by lithography using photosensitive compositions has been performed.

Examples of the lithography method include a method of using a photosensitive composition to form a resist film, subsequently exposing the obtained film, and subsequently developing the film. In particular, in recent years, the use of, in addition to the ArF excimer laser, EB (Electron Beam) or EUV (Extreme ultraviolet) light during exposure has been studied, and an actinic ray-sensitive or radiation-sensitive resin composition suitable for EUV exposure has been developed.

In the formation of a resist pattern using EUV (having a wavelength of 13.5 nm) or an electron beam for the purpose of forming a fine pattern, requirements for various performances are stricter than in the related-art cases of using ArF (having a wavelength of 193 nm) light or the like.

For example, JP2011-154216A describes an actinic ray-sensitive or radiation-sensitive resin composition including a resin containing a repeating unit that is decomposed upon irradiation with an actinic ray or a radiation to generate an acidic anion in a side chain of the resin and that at least contains an aromatic ring in a side chain except for the counter cation of the acidic anion, and at least two repeating unit species that are decomposed by the action of an acid to generate an alkali-soluble group.

WO2022/024929A describes an actinic ray-sensitive or radiation-sensitive resin composition including a resin including a specified repeating unit that is decomposed by the action of an acid to provide increased polarity, and a compound having a specified structure that generates an acid upon irradiation with an actinic ray or a radiation.

JP2015-52769A describes a radiation-sensitive resin composition containing a resin having a structural unit having a specified structure and a radiation-sensitive acid generator.

### SUMMARY OF THE INVENTION

In recent years, for example, in pattern formation using EUV or an electron beam, the sizes of the formed patterns have been reduced, so that there has been a demand for further improvements in various performances. In particular, there is room for improvement in suppression of defects and roughness performance. In the case of line-and-space patterns, the roughness performance is, for example, line width roughness (Line Width Roughness: LWR) performance.

An object of the present invention is to provide an actinic ray-sensitive or radiation-sensitive resin composition that can suppress generation of defects and has high roughness performance in formation of an ultrafine pattern (for example, a line-and-space pattern having a line width of 35 nm or less, or a hole pattern having a hole diameter of 35 nm or less); an actinic ray-sensitive or radiation-sensitive resin film formed from the actinic ray-sensitive or radiation-sensitive resin composition; and a pattern forming method and a method for producing an electronic device that use the actinic ray-sensitive or radiation-sensitive resin composition.

The inventors of the present invention have found that the following features can address the above-described object.

[1]

An actinic ray-sensitive or radiation-sensitive resin composition including a resin (A) including a repeating unit (i) represented by a formula (N-0) below, a repeating unit (ii) having a cyano group and a lactone structure, and a repeating unit (iii) having a phenolic hydroxy group,
wherein a content of a repeating unit having an acid-decomposable group in the resin (A) relative to all repeating units in the resin (A) is 35 mol % or more,

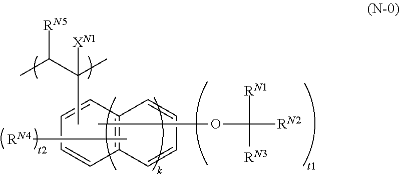

in the formula (N-0), X^{N1} represents a hydrogen atom, a halogen atom, a hydroxy group, or an organic group;
k represents 0 or 1;
R^{N1} to R^{N3} each independently represent an alkyl group having 1 to 12 carbon atoms or a cycloalkyl group having 3 to 12 carbon atoms;
two among R^{N1} to R^{N3} may be bonded together to form a ring;
R^{N4} represents a halogen atom, a hydroxy group, or an organic group;
when a plurality of R^{N1} to R^{N4} are present, the plurality of R^{N1} to R^{N4} may be individually the same or different;
R^{N5} represents a hydrogen atom or an organic group;
R^{N4} and R^{N5} may be bonded together to form a ring;
t1 represents an integer of 1 or more and (5+2k) or less; and
t2 represents an integer of 0 or more and (5+2k−t1) or less.
   [2]

The actinic ray-sensitive or radiation-sensitive resin composition according to [1], wherein the repeating unit (i) is a repeating unit represented by a formula (N-1) below:

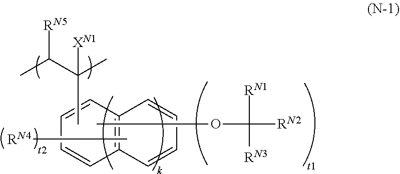

in the formula (N-1), each of X^{N1}, R^{N1} to R^{N5}, k, t1, and t2 has the same meaning as each of X^{N1}, R^{N1} to R^{N5}, k, t1, and t2 in the formula (N-0).
   [3]

The actinic ray-sensitive or radiation-sensitive resin composition according to [1] or [2], wherein the repeating unit (i) is a repeating unit represented by a formula (N-2) below:

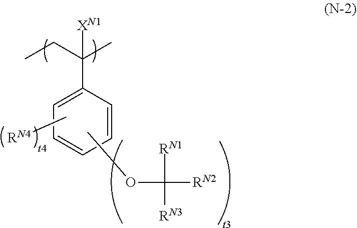

in the formula (N-2), each of X^{N1} and R^{N1} to R^{N4} has the same meaning as each of X^{N1} and R^{N1} to R^{N4} in the formula (N-0); t3 represents an integer of 1 or more and 5 or less; and t4 represents an integer of 0 or more and 4 or less.
   [4]

The actinic ray-sensitive or radiation-sensitive resin composition according to any one of [1] to [3], wherein the repeating unit (ii) is a repeating unit represented by a formula (Q-1) below:

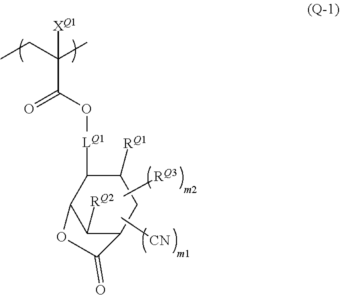

in the formula (Q-1), X^{Q1} represents a hydrogen atom, a halogen atom, a hydroxy group, or an organic group;
L^{Q1} represents a single bond or a divalent organic group;
R^{Q1} and R^{Q2} each independently represent a hydrogen atom, an alkyl group having 1 to 5 carbon atoms, an alkoxy group having 1 to 5 carbon atoms, or an alkylthio group having 1 to 5 carbon atoms, or R^{Q1} and R^{Q2} are bonded together to represent an alkylene group having 1 to 6 carbon atoms that may include at least one of an oxygen atom or a sulfur atom, an ether bond, or a thioether bond;
R^{Q3} represents a halogen atom, a hydroxy group, or an organic group;
m1 represents an integer of 1 to 6; and
m2 represents an integer of 0 to 5.
   [5]

The actinic ray-sensitive or radiation-sensitive resin composition according to any one of [1] to [4], wherein the repeating unit (i) is a repeating unit represented by a formula (N-3) below:

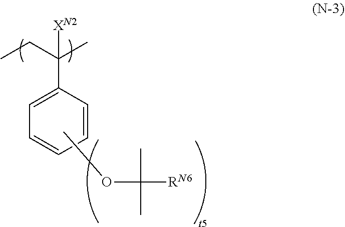

in the formula (N-3), X^{N2} represents a hydrogen atom, a halogen atom, or a methyl group; R^{N6} represents a methyl group or an ethyl group; and t5 represents 1 or 2.
   [6]

The actinic ray-sensitive or radiation-sensitive resin composition according to any one of [1] to [5], wherein the resin (A) includes a repeating unit represented by a formula (E-1) below:

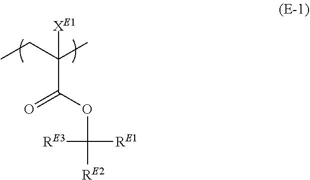

in the formula (E-1), X^{E1} represents a hydrogen atom, a halogen atom, a hydroxy group, or an organic group; R^{E1} to R^{E3} each independently represent a hydrocarbon group having 1 to 12 carbon atoms; two among REI to R^{E3} may be bonded together to form a ring; and when hydrocarbon groups represented by R^{E1} to R^{E3} include alkylene groups, a part of the alkylene groups may be replaced by an ether group, a thioether group, or a carbonyl group.
   [7]

The actinic ray-sensitive or radiation-sensitive resin composition according to any one of [1] to [6], wherein the content of the repeating unit having an acid-decomposable group in the resin (A) relative to the all repeating units in the resin (A) is 40 mol % or more.

[8]

The actinic ray-sensitive or radiation-sensitive resin composition according to any one of [1] to [7], wherein the content of the repeating unit having an acid-decomposable group in the resin (A) relative to the all repeating units in the resin (A) is 45 mol % or more.

[9]

The actinic ray-sensitive or radiation-sensitive resin composition according to any one of [1] to [8], wherein the resin (A) includes a repeating unit represented by a formula (E-2) below:

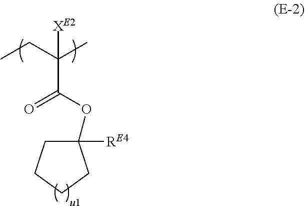

in the formula (E-2), X^{E2} represents a hydrogen atom, a halogen atom, or a methyl group; R^{E4} represents a hydrocarbon group having 6 or less carbon atoms; and u1 represents 1 or 2.
   [10]

The actinic ray-sensitive or radiation-sensitive resin composition according to any one of [1] to [9], wherein the resin (A) has a molecular-weight dispersity of 1.70 or less.

[11]

The actinic ray-sensitive or radiation-sensitive resin composition according to any one of [1] to [10], containing an onium salt compound as a compound other than the resin (A).

[12]

The actinic ray-sensitive or radiation-sensitive resin composition according to any one of [1] to [11], containing a photoacid generator.

[13]

The actinic ray-sensitive or radiation-sensitive resin composition according to any one of [1] to [3], wherein a total number of carbon atoms of R^{N1} to R^{N3} above is 3 to 25.

[14]

An actinic ray-sensitive or radiation-sensitive film formed from the actinic ray-sensitive or radiation-sensitive resin composition according to any one of [1] to [13].

[15]

A pattern forming method including:
using the actinic ray-sensitive or radiation-sensitive resin composition according to any one of [1] to [13] to form an actinic ray-sensitive or radiation-sensitive film on a substrate;
exposing the actinic ray-sensitive or radiation-sensitive film; and
using a developer to develop the exposed actinic ray-sensitive or radiation-sensitive film to form a pattern.
   [16]

A method for producing an electronic device, the method including the pattern forming method according to [15].

The present invention can provide an actinic ray-sensitive or radiation-sensitive resin composition that can suppress generation of defects and has high roughness performance in formation of an ultrafine pattern (for example, a line-and-space pattern having a line width of 35 nm or less, or a hole pattern having a hole diameter of 35 nm or less); an actinic ray-sensitive or radiation-sensitive resin film formed from the actinic ray-sensitive or radiation-sensitive resin composition; and a pattern forming method and a method for producing an electronic device that use the actinic ray-sensitive or radiation-sensitive resin composition.

### DESCRIPTION OF THE PREFERRED EMBODIMENTS

Hereinafter, the present invention will be described in detail.

Features may be described below on the basis of representative embodiments according to the present invention; however, the present invention is not limited to the embodiments.

In this Specification, for written forms of groups (atomic groups), written forms without referring to substituted or unsubstituted encompass, in addition to groups not having a substituent, groups including a substituent without departing from the spirit and scope of the present invention. For example, “alkyl group” encompasses not only alkyl groups not having a substituent (unsubstituted alkyl groups), but also alkyl groups having a substituent (substituted alkyl groups). In this Specification, “organic group” refers to a group including at least one carbon atom.

The substituent is preferably a monovalent substituent unless otherwise specified.

In this Specification, in the case of using a phrase “may have a substituent”, the type of the substituent, the position of the substituent, and the number of such substituents are not particularly limited. The number of the substituents may be, for example, one, two, three, or more. Examples of the substituents include monovalent non-metallic atomic groups except for the hydrogen atom and, for example, can be selected from the group consisting of the following Substituents T.

### Substituents T

Substituents T include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; alkyl groups; cycloalkyl groups; aryl groups; heteroaryl groups; a hydroxy group; a carboxy group; a formyl group; a sulfo group; a cyano group; alkylaminocarbonyl groups; arylaminocarbonyl groups; a sulfonamide group; a silyl group; an amino group; monoalkylamino groups; dialkylamino groups; arylamino groups; a nitro group; a formyl group; and combinations of the foregoing.

In this Specification, “actinic ray” or “radiation” means, for example, the emission line spectrum of a mercury lamp, far-ultraviolet rays represented by excimer lasers, extreme ultraviolet rays (EUV: Extreme Ultraviolet), X-rays, or an electron beam (EB: Electron Beam).

In this Specification, “light” means an actinic ray or a radiation.

In this Specification, “exposure” includes, unless otherwise specified, not only exposure using, for example, the emission line spectrum of a mercury lamp, far-ultraviolet rays represented by excimer lasers, extreme ultraviolet rays, or X-rays, but also patterning using a corpuscular beam such as an electron beam or an ion beam.

In this Specification, “a value ‘to’ another value” is used to mean that it includes the value and the other value as the lower limit value and the upper limit value.

In this Specification, the described bonding directions of divalent linking groups are not limited unless otherwise specified. For example, in a compound represented by a formula “X—Y—Z” where Y is —COO—, Y may be —CO—O— or —O—CO—. The compound may be “X—CO—O—Z” or may be “X—O—CO—Z”.

In this Specification, (meth)acrylate represents acrylate and methacrylate, and (meth)acrylic represents acrylic and methacrylic.

In this Specification, the weight-average molecular weight (Mw), the number-average molecular weight (Mn), and the molecular-weight dispersity (also referred to as “molecular-weight distribution”)(Mw/Mn) are defined as polystyrene-equivalent values measured using a GPC (Gel Permeation Chromatography) apparatus (HLC-8120GPC manufactured by Tosoh Corporation) by GPC measurement (solvent: tetrahydrofuran, flow rate (sample injection amount): 10 μL, column: TSK gel Multipore HXL-M manufactured by Tosoh Corporation, column temperature: 40° C., flow rate: 1.0 mL/min, detector: differential refractive index detector (Refractive Index Detector)).

In this Specification, the acid dissociation constant (pKa) represents pKa in an aqueous solution, specifically, a value determined using the following Software package 1, on the basis of the Hammett's substituent constant and the database of values in publicly known documents, by calculation.

Software package 1: Advanced Chemistry Development (ACD/Labs) Software V8.14 for Solaris (1994-2007 ACD/Labs)

Alternatively, pKa can be determined by the molecular orbital calculation method. Specifically, this method may be a method of, on the basis of a thermodynamic cycle, calculating H⁺ dissociation free energy in an aqueous solution to achieve the determination. As the calculation method for H⁺ dissociation free energy, for example, DFT (density function theory) can be performed for calculation; however, other various methods have been reported in documents and the like and the calculation method is not limited to DFT. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density function theory) using Gaussian 16 is employed.

In this Specification, as described above, pKa refers to “pKa in an aqueous solution”; however, when pKa in an aqueous solution cannot be determined, “pKa in a dimethyl sulfoxide (DMSO) solution” is employed.

“Solid content” means components forming the actinic ray-sensitive or radiation-sensitive film (typically, a resist film) and does not include solvents. As long as a component forms the actinic ray-sensitive or radiation-sensitive film, even when the component has the form of liquid, it is regarded as the solid content.

### Actinic Ray-Sensitive or Radiation-Sensitive Resin Composition

Hereinafter, an actinic ray-sensitive or radiation-sensitive resin composition of the present invention will be described.

An actinic ray-sensitive or radiation-sensitive resin composition of the present invention (hereafter, also referred to as “composition of the present invention”) is typically a resist composition, and may be a positive resist composition or may be a negative resist composition. The resist composition may be a resist composition for alkali development or may be a resist composition for organic-solvent development. The resist composition may be a chemical amplification resist composition or may be a non-chemical amplification resist composition. A composition of the present invention is preferably a chemical amplification resist composition.

A composition of the present invention is an actinic ray-sensitive or radiation-sensitive resin composition containing a resin (A) including a repeating unit (i) represented by a formula (N-0) below, a repeating unit (ii) having a cyano group and a lactone structure, and a repeating unit (iii) having a phenolic hydroxy group,
wherein a content of a repeating unit having an acid-decomposable group in the resin (A) relative to all repeating units in the resin (A) is 35 mol % or more,

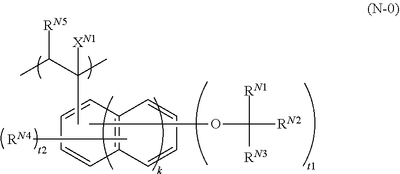

in the formula (N-0), X^{N1} represents a hydrogen atom, a halogen atom, a hydroxy group, or an organic group; k represents 0 or 1; R^{N1} to R^{N3} each independently represent an alkyl group having 1 to 12 carbon atoms or a cycloalkyl group having 3 to 12 carbon atoms; two among R^{N1} to R^{N3} may be bonded together to form a ring; R^{N4} represents a halogen atom, a hydroxy group, or an organic group; when a plurality of R^{N1} to R^{N4} are present, the plurality of R^{N1} to R^{N4} may be individually the same or different; R^{N5} represents a hydrogen atom or an organic group; R^{N4} and R^{N5} may be bonded together to form a ring; t1 represents an integer of 1 or more and (5+2k) or less; and t2 represents an integer of 0 or more and (5+2k-t1) or less.

First, various components of a composition of the present invention will be described in detail.

### Resin (A)

A composition of the present invention contains a resin (A) including a repeating unit (i) represented by the formula (N-0), a repeating unit (ii) having a cyano group and a lactone structure, and a repeating unit (iii) having a phenolic hydroxy group.

The resin (A) is a resin that is decomposed by the action of an acid to provide increased polarity (also referred to as “acid-decomposable resin”).

The resin (A) includes a repeating unit having a group that is decomposed by the action of an acid to provide increased polarity (also referred to as “acid-decomposable group”).

The acid-decomposable group refers to a group that is decomposed by the action of an acid to generate a polar group. The acid-decomposable group preferably has a structure in which the polar group is protected with a group (leaving group) that leaves by the action of an acid. Thus, the resin (A) has a repeating unit having a group that is decomposed by the action of an acid to generate a polar group. The resin having the repeating unit is subjected to the action of an acid to have increased polarity to have an increased degree of solubility in the alkali developer, but have a decreased degree of solubility in organic solvents.

The resin (A) is an acid-decomposable resin and hence, in a pattern forming method using a composition of the present invention, typically, in the case of employing a developer that is an alkali developer, a positive-type pattern is suitably formed or, in the case of employing a developer that is an organic-based developer, a negative-type pattern is suitably formed.

In the resin (A), the repeating unit (i), the repeating unit (ii), and the repeating unit (iii) are preferably repeating units different from each other.

### Repeating Unit (i)

The resin (A) includes the repeating unit (i) represented by the formula (N-0).

The repeating unit (i) is a repeating unit having an acid-decomposable group, and is a repeating unit having a group that is decomposed by the action of an acid to generate a phenolic hydroxy group.

The repeating unit (i) has higher leaving reactivity than, for example, the repeating unit derived from (meth)acrylate, which has been often used as a repeating unit having an acid-decomposable group in the related art. When the repeating unit having an acid-decomposable group has high leaving reactivity, generation of defects tends to be suppressed. In addition, when the repeating unit having an acid-decomposable group has high leaving reactivity, the fluctuation of leaving (deprotection) is reduced and the roughness performance is improved. In general, in order to improve the leaving reactivity, the size of the leaving group may be increased; however, the repeating unit (i) has high leaving reactivity not by the size of the leaving group, but by the skeleton represented by the formula (N-0); this eliminates the necessity of increasing the size of the leaving group in order to improve the leaving reactivity. The lower the molecular weight of the leaving group, the higher the volatility of the leaving product, so that the remaining of the leaving product in the actinic ray-sensitive or radiation-sensitive film is suppressed, and a decrease in the Tg (glass transition temperature) of the actinic ray-sensitive or radiation-sensitive film can be suppressed. The higher the Tg of the actinic ray-sensitive or radiation-sensitive film, the further the diffusion of acid can be suppressed, so that defects during formation of an ultrafine pattern can be suppressed and the roughness performance is also improved, inferentially.

As described later, a composition of the present invention preferably contains a photoacid generator; the repeating unit (i) has a phenolic hydroxy group as the polar group generated by the leaving reaction and has high compatibility with the photoacid generator; therefore, particularly when a composition of the present invention contains a photoacid generator, defects during formation of an ultrafine pattern can be further suppressed and the roughness performance is also further improved, inferentially.

In the formula (N-0), X^{N1} represents a hydrogen atom, a halogen atom, a hydroxy group, or an organic group.

For X^{N1}, the halogen atom is, for example, a fluorine atom, a chlorine atom, a bromine atom, or an iodine atom, and is preferably a fluorine atom.

For X^{N1}, the organic group is, for example, an alkyl group, a cycloalkyl group, an aryl group, or an alkenyl group, and is preferably an alkyl group. For X^{N1}, the organic group preferably has 1 to 10 carbon atoms, and more preferably 1 to 5 carbon atoms. For X^{N1}, the organic group is particularly preferably a methyl group.

X^{N1} is preferably a hydrogen atom, a fluorine atom, or a methyl group, more preferably a hydrogen atom or a methyl group, and particularly preferably a hydrogen atom.

In the formula (N-0), k represents 0 or 1, and preferably represents 0. In the formula (N-0), the aromatic ring represents, in a case where k is 0, a benzene ring, or represents, in a case where k is 1, a naphthalene ring.

In the formula (N-0), R^{N1} to R^{N3} each independently represent an alkyl group having 1 to 12 carbon atoms or a cycloalkyl group having 3 to 12 carbon atoms.

For R^{N1} to R^{N3}, the alkyl group may be linear or branched, and is preferably an alkyl group having 1 to 8 carbon atoms, more preferably an alkyl group having 1 to 5 carbon atoms, still more preferably an alkyl group having 1 to 3 carbon atoms, and particularly preferably a methyl group or an ethyl group. Specifically, the alkyl group is preferably a methyl group, an ethyl group, an n-propyl group, an isopropyl group, an n-butyl group, an isobutyl group, a t-butyl group, or the like.

For R^{N1} to R^{N3}, the cycloalkyl group may be monocyclic or polycyclic, and is preferably a cycloalkyl group having 5 to 12 carbon atoms, more preferably a cycloalkyl group having 5 to 10 carbon atoms, and particularly preferably a cycloalkyl group having 5 to 8 carbon atoms. Specifically, the cycloalkyl group is preferably a cyclopentyl group, a cyclohexyl group, a norbornyl group, an adamantyl group, or the like.

Two among R^{N1} to R^{N3} may be bonded together to form a ring.

The ring formed by bonding together two among R^{N1} to R^{N3} is preferably an alicyclic ring, and is preferably a monocyclic or polycyclic cycloalkane ring.

The ring formed by bonding two among R^{N1} to R^{N3} has preferably 3 to 20 carbon atoms, more preferably 4 to 15 carbon atoms, and particularly preferably 5 to 12 carbon atoms. Specifically, the ring is preferably a cyclopentane ring, a cyclohexane ring, a norbornane ring, an adamantane ring, or the like.

The total number of carbon atoms of R^{N1} to R^{N3} is preferably 3 to 25, more preferably 3 to 20, and particularly preferably 3 to 15.

The alkyl group and cycloalkyl group represented by R^{N1} to R^{N3} and the ring formed by bonding together two among R^{N1} to R^{N3} may have a substituent. Examples of the substituent include the above-described Substituents T.

When R^{N1} to R^{N3} represent an alkyl group having a substituent or a cycloalkyl group having a substituent, the number of carbon atoms including that of the substituent is preferably in the above-described range. When the ring formed by bonding together two among R^{N1} to R^{N3} has a substituent, the number of carbon atoms including that of the substituent is preferably in the above-described range.

In the formula (N-0), R^{N4} represents a halogen atom, a hydroxy group, or an organic group.

For R^{N4}, the halogen atom is, for example, a fluorine atom, a chlorine atom, a bromine atom, or an iodine atom, and is preferably a fluorine atom.

For R^{N4}, the organic group is, for example, an alkyl group, a cycloalkyl group, an aryl group, or an alkenyl group, and is preferably an alkyl group. For R^{N4}, the organic group preferably has 1 to 10 carbon atoms, and more preferably 1 to 5 carbon atoms.

In the formula (N-0), R^{N5} represents a hydrogen atom or an organic group.

For R^{N5}, the organic group is, for example, an alkyl group, a cycloalkyl group, an aryl group, or an alkenyl group, and is preferably an alkyl group. For R^{N5}, the organic group preferably has 1 to 10 carbon atoms, and more preferably 1 to 5 carbon atoms.

R^{N5} preferably represents a hydrogen atom.

R^{N4} and R^{N5} may be bonded together to form a ring.

In the formula (N-0), t1 represents an integer of 1 or more and (5+2k) or less, preferably represents an integer of 1 or more and 5 or less, more preferably represents an integer of 1 or more and 3 or less, particularly preferably represents 1 or 2, and most preferably represents 1.

t2 represents an integer of 0 or more and (5+2k-t1) or less, preferably represents an integer of 0 or more and 4 or less, more preferably represents an integer of 0 or more and 2 or less, particularly preferably represents 0 or 1, and most preferably represents 0. The repeating unit (i) is preferably a repeating unit represented by the following formula

### (N-1).

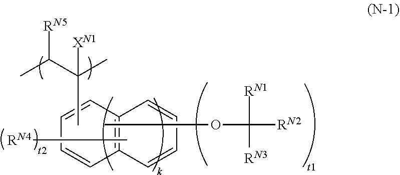

In the formula (N-1), X^{N1}, R^{N1} to R^{N5}, k, t1, and t2 respectively have the same meanings as X^{N1}, R^{N1} to R^{N5}, k, t1, and t2 in the formula (N-0).

In the formula (N-1), X^{N1}, R^{N1} to R^{N5}, k, t1, and t2 respectively have the same meanings as X^{N1}, R^{N1} to R^{N5}, k, t1, and t2 in the formula (N-0), and preferred ranges and specific examples thereof are also the same.

The repeating unit (i) is more preferably a repeating unit represented by the following formula (N-2).

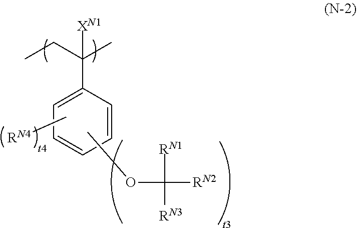

In the formula (N-2), X^{N1} and R^{N1} to R^{N4} respectively have the same meanings as X^{N1} and R^{N1} to R^{N4} in the formula (N-0). t3 represents an integer of 1 or more and 5 or less. t4 represents an integer of 0 or more and 4 or less.

In the formula (N-2), X^{N1} and R^{N1} to R^{N4} respectively have the same meanings as X^{N1} and R^{N1} to R^{N4} in the formula (N-0), and preferred ranges and specific examples thereof are also the same.

t3 represents an integer of 1 or more and 5 or less, preferably represents an integer of 1 or more and 3 or less, more preferably represents 1 or 2, and most preferably represents 1.

t4 represents an integer of 0 or more and 4 or less, preferably represents an integer of 0 or more and 2 or less, more preferably represents 0 or 1, and most preferably represents 0.

The repeating unit (i) is more preferably a repeating unit represented by the following formula (N-3).

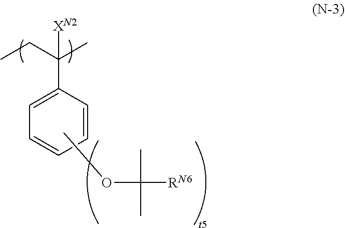

In the formula (N-3), X^{N2} represents a hydrogen atom, a halogen atom, or a methyl group. R^{N6} represents a methyl group or an ethyl group. t5 represents 1 or 2.

In the formula (N-3), for X^{N2}, the halogen atom is, for example, a fluorine atom, a chlorine atom, a bromine atom, or an iodine atom, and preferably a fluorine atom.

In the formula (N-3), t5 represents 1 or 2, and preferably represents 1.

Non-limiting specific examples of the monomer that provides the repeating unit (i) (monomer corresponding to the repeating unit (i)) are as follows.

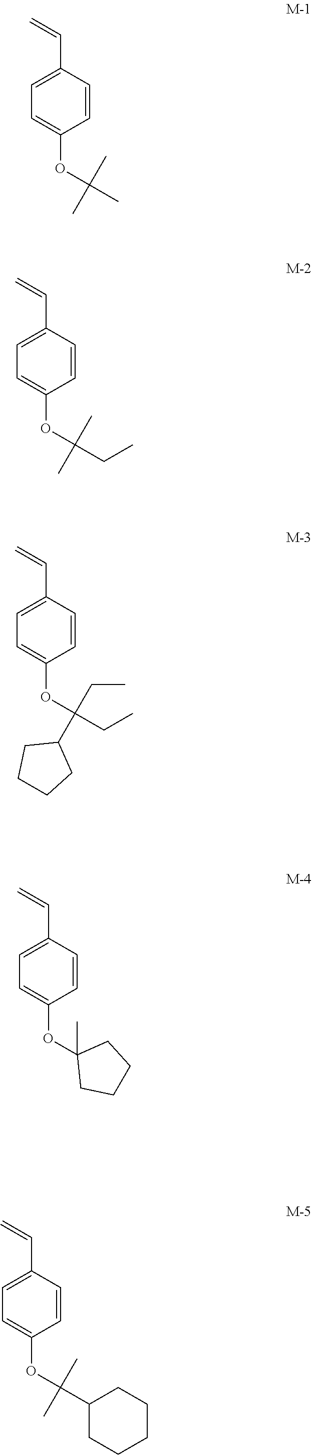

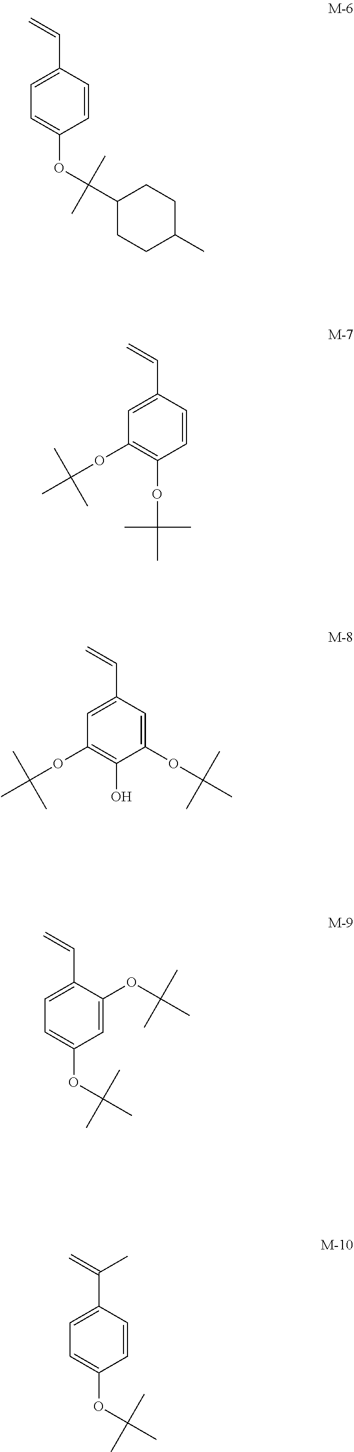

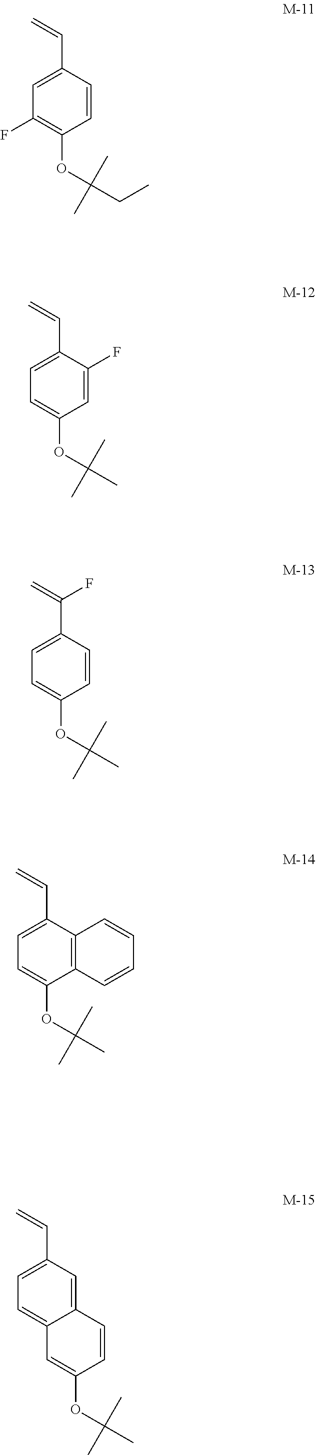

The resin (A) may include one type of the repeating unit (i) or two or more types of the repeating unit (i).

The content of the repeating unit (i) is not particularly limited.

The content of the repeating unit (i) is, relative to all the repeating units in the resin (A), preferably 5 mol % or more, more preferably 10 mol % or more, and still more preferably 15 mol % or more.

The content of the repeating unit (i) is, relative to all the repeating units in the resin (A), preferably 70 mol % or less, more preferably 60 mol % or less, still more preferably 50 mol % or less, and particularly preferably 40 mol % or less.

Repeating unit (ii)

The resin (A) includes a repeating unit (ii) having a cyano group and a lactone structure.

The repeating unit (ii) has a cyclic structure, so that the actinic ray-sensitive or radiation-sensitive film formed from a composition of the present invention can have increased Tg. The higher the Tg of the actinic ray-sensitive or radiation-sensitive film, the further the diffusion of acid can be suppressed, so that defects during formation of an ultrafine pattern can be suppressed and the roughness performance is also improved, inferentially.

In addition, as described later, a composition of the present invention preferably contains a photoacid generator; the repeating unit (ii) has a lactone structure, which is a hydrophilic structure, to thereby provide high compatibility with the photoacid generator. Therefore, in particular, when a composition of the present invention contains a photoacid generator, defects during formation of an ultrafine pattern can be further suppressed and the roughness performance is also further improved, inferentially.

Furthermore, the repeating unit (ii) has a cyano group, so that the effect of increasing the Tg of the actinic ray-sensitive or radiation-sensitive film and the effect of enhancing the compatibility with the photoacid generator are improved, defects during formation of an ultrafine pattern are further suppressed, and the roughness performance is further improved, inferentially.

The repeating unit (ii) is preferably a repeating unit represented by the following formula (Q-1).

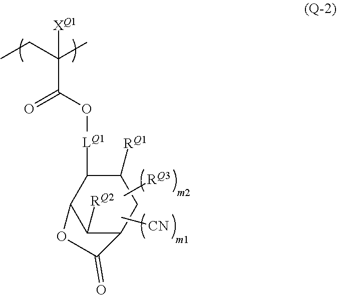

In the formula (Q-1), X^{Q1} represents a hydrogen atom, a halogen atom, a hydroxy group, or an organic group. L^{Q1} represents a single bond or a divalent organic group. R^{Q1} and R^{Q2} each independently represent a hydrogen atom, an alkyl group having 1 to 5 carbon atoms, an alkoxy group having 1 to 5 carbon atoms, or an alkylthio group having 1 to 5 carbon atoms, or R^{Q1} and R^{Q2} are bonded together to represent an alkylene group having 1 to 6 carbon atoms that may include at least one of an oxygen atom or a sulfur atom, an ether bond, or a thioether bond. R^{Q3} represents a halogen atom, a hydroxy group, or an organic group. m1 represents an integer of 1 to 6. m2 represents an integer of 0 to 5.

In the formula (Q-1), X^{Q1} represents a hydrogen atom, a halogen atom, a hydroxy group, or an organic group.

For X^{Q1}, the halogen atom is, for example, a fluorine atom, a chlorine atom, a bromine atom, or an iodine atom, and is preferably a fluorine atom.

For X^{Q1}, the organic group is, for example, an alkyl group, a cycloalkyl group, an aryl group, or an alkenyl group, and is preferably an alkyl group. For X^{Q1}, the organic group preferably has 1 to 10 carbon atoms, and more preferably 1 to 5 carbon atoms. For X^{N1}, the organic group is particularly preferably a methyl group.

X^{Q1} is preferably a hydrogen atom, a fluorine atom, or a methyl group, more preferably a hydrogen atom or a methyl group, and particularly preferably a hydrogen atom.

In the formula (Q-1), L^{Q1} represents a single bond or a divalent organic group.

For L^{Q1}, the divalent organic group may be an alkylene group, a cycloalkylene group, an arylene group, a heteroarylene group, —Rt^{Q1}—COO—, —Rt^{Q1}—O—, or the like. Rt^{Q1} represents an alkylene group or a cycloalkylene group. Rt^{Q1} is preferably an alkylene group having 1 to 5 carbon atoms, and more preferably —CH₂—, —(CH₂)₂—, or —(CH₂)₃—.

L^{Q1} is preferably a single bond or an —Rt^{Q1}-COO— group.

In the formula (Q-1), R^{Q1} and R^{Q2} each independently represent a hydrogen atom, an alkyl group having 1 to 5 carbon atoms, an alkoxy group having 1 to 5 carbon atoms, or an alkylthio group having 1 to 5 carbon atoms, or R^{Q1} and R^{Q2} are bonded together to represent an alkylene group having 1 to 6 carbon atoms that may include at least one of an oxygen atom or a sulfur atom, an ether bond, or a thioether bond.

For R^{Q1} and R^{Q2}, the alkyl group having 1 to 5 carbon atoms may be linear or branched, and is preferably an alkyl group having 1 to 3 carbon atoms, and more preferably a methyl group or an ethyl group. Specifically, the alkyl group is preferably a methyl group, an ethyl group, an n-propyl group, an isopropyl group, an n-butyl group, an isobutyl group, a t-butyl group, or the like.

For R^{Q1} and R^{Q2}, the alkoxy group having 1 to 5 carbon atoms is preferably linear or branched, and preferably an alkoxy group having 1 to 3 carbon atoms. Specifically, the alkoxy group may be a methoxy group, an ethoxy group, or the like.

For R^{Q1} and R^{Q2}, the alkylthio group having 1 to 5 carbon atoms is preferably linear or branched, and is preferably an alkylthio group having 1 to 3 carbon atoms. Specifically, the alkylthio group may be a methylthio group, an ethylthio group, or the like.

When R^{Q1} and R^{Q2} are bonded together to represent an alkylene group, the alkylene group has 1 to 6 carbon atoms, preferably 1 to 5 carbon atoms, and more preferably 1 to 3 carbon atoms. Specifically, the alkylene group may be a methylene group, an ethylene group, or the like.

When R^{Q1} and R^{Q2} are bonded together to represent an alkylene group, the alkylene group may include at least one of an oxygen atom or a sulfur atom. For example, the alkylene group may have an ether bond or a thioether bond in the chain or at a terminal.

R^{Q1} and R^{Q2} may be bonded together to represent an ether bond or a thioether bond.

The alkyl group, alkoxy group, and alkylthio group represented by R^{Q1} and R^{Q2}, and the alkylene group formed by bonding together R^{Q1} and R^{Q2} may have a substituent. Examples of the substituent include the above-described Substituents T.

When R^{Q1} and R^{Q2} represent an alkyl group having a substituent, an alkoxy group having a substituent, or an alkylthio group having a substituent, the number of carbon atoms including that of the substituent is preferably in the above-described range. When the alkylene group formed by bonding together R^{Q1} and R^{Q2} has a substituent, the number of carbon atoms including that of the substituent is preferably in the above-described range.

In the formula (Q-1), R^{Q3} represents a halogen atom, a hydroxy group, or an organic group.

For R^{Q3}, the halogen atom is, for example, a fluorine atom, a chlorine atom, a bromine atom, or an iodine atom, and is preferably a fluorine atom.

For R^{Q3}, the organic group is, for example, an alkyl group, a cycloalkyl group, an aryl group, or an alkenyl group, and is preferably an alkyl group. For R^{Q3}, the organic group preferably has 1 to 10 carbon atoms, and more preferably 1 to 5 carbon atoms. The organic group represented by R^{Q3} is particularly preferably a methyl group.

In the formula (Q-1), ml represents an integer of 1 to 6, preferably represents an integer of 1 to 4, and more preferably represents 1 or 2.

In the formula (Q-1), m2 represents an integer of 0 to 5, preferably represents an integer of 0 to 3, and more preferably represents 0 or 1.

Non-limiting specific examples of the monomer that provides the repeating unit (ii) (monomer corresponding to the repeating unit (ii)) are as follows.

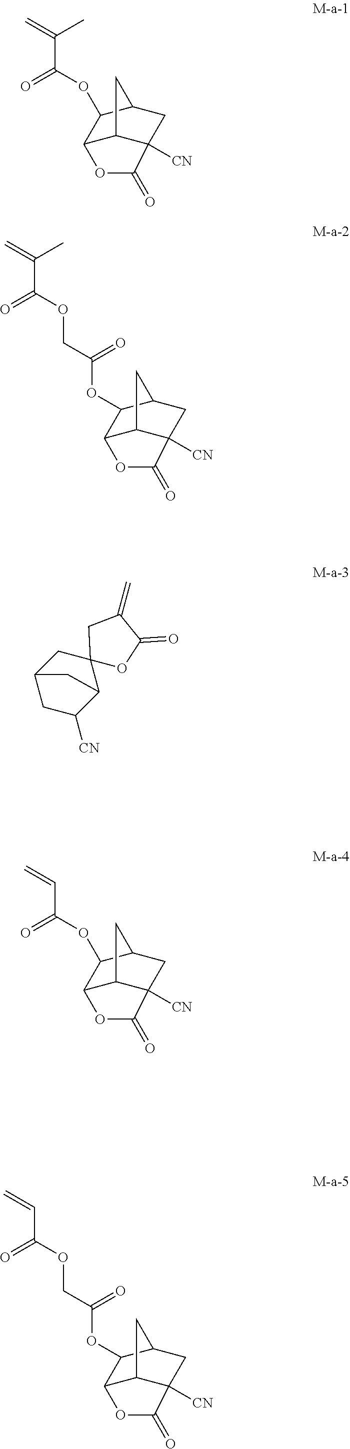

The resin (A) may include one type of the repeating unit (ii) or two or more types of the repeating unit (ii).

The content of the repeating unit (ii) is not particularly limited.

The content of the repeating unit (ii) is, relative to all the repeating units in the resin (A), preferably 3 mol % or more, more preferably 5 mol % or more, and still more preferably 10 mol % or more.

The content of the repeating unit (ii) is, relative to all the repeating units in the resin (A), preferably 60 mol % or less, more preferably 50 mol % or less, still more preferably 40 mol % or less, and particularly preferably 30 mol % or less.

Repeating Unit (iii)

The resin (A) includes a repeating unit (iii) having a phenolic hydroxy group.

The repeating unit (iii) has a phenolic hydroxy group, so that the actinic ray-sensitive or radiation-sensitive film formed from a composition of the present invention can have increased Tg. The higher the Tg of the actinic ray-sensitive or radiation-sensitive film, the further the diffusion of acid can be suppressed, so that defects during formation of an ultrafine pattern can be suppressed and the roughness performance is also improved, inferentially.

In addition, as described later, a composition of the present invention preferably contains a photoacid generator; the repeating unit (iii) has a phenolic hydroxy group and hence provides high compatibility with the photoacid generator. Therefore, in particular, when a composition of the present invention contains a photoacid generator, defects during formation of an ultrafine pattern can be further suppressed and the roughness performance is also further improved, inferentially.

Furthermore, the phenolic hydroxy group of the repeating unit (iii) serves as a proton source and has hydrophilicity, to thereby enhance the leaving reactivity of the acid-decomposable group, inferentially. When the acid-decomposable group has high leaving reactivity, generation of defects tends to be suppressed. In addition, when the acid-decomposable group has high leaving reactivity, the fluctuation of leaving (deprotection) is reduced and the roughness performance is improved.

The repeating unit (iii) is preferably a repeating unit represented by the following formula (G-1).

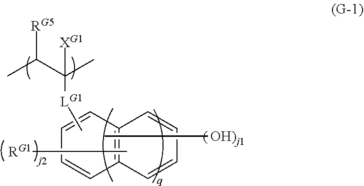

In the formula (G-1), X^{G1} represents a hydrogen atom, an alkyl group, a cycloalkyl group, a halogen atom, or a cyano group. q represents 0 or 1. RGI represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group. When a plurality of RGI are present, the plurality of RGI may be the same or different. R^{G2} represents a hydrogen atom or an organic group. L^{G1} represents a single bond or a divalent linking group. j1 represents an integer of 1 or more and (5+2q) or less. j2 represents an integer of 0 or more and (5+2q-j1) or less.

In the formula (G-1), X^{G1} represents a hydrogen atom, an alkyl group, a cycloalkyl group, a halogen atom, or a cyano group.

For X^{G1}, the halogen atom is, for example, a fluorine atom, a chlorine atom, a bromine atom, or an iodine atom, and is preferably a fluorine atom.

For X^{G1}, the alkyl group may be linear or branched, and is preferably an alkyl group having 1 to 8 carbon atoms, more preferably an alkyl group having 1 to 5 carbon atoms, still more preferably an alkyl group having 1 to 3 carbon atoms, and particularly preferably a methyl group.

For X^{G1}, the cycloalkyl group may be monocyclic or polycyclic, and is preferably a cycloalkyl group having 5 to 12 carbon atoms, more preferably a cycloalkyl group having 5 to 10 carbon atoms, and particularly preferably a cycloalkyl group having 5 to 8 carbon atoms.

X^{G1} is preferably a hydrogen atom, a fluorine atom, or a methyl group, and more preferably a hydrogen atom or a methyl group.

In the formula (G-1), q represents 0 or 1 and preferably represents 0. In the formula (G-1), the aromatic ring represents, in a case where q is 0, a benzene ring or, in a case where q is 1, represents a naphthalene ring.

In the formula (G-1), R^{G1} represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group.

For R^{G1}, the halogen atom is, for example, a fluorine atom, a chlorine atom, a bromine atom, or an iodine atom, and is preferably a fluorine atom or an iodine atom.

For R^{G1}, the alkyl group, alkoxy group, or alkylsulfonyloxy group may be linear or branched, and preferably has 1 to 10 carbon atoms, and more preferably 1 to 5 carbon atoms.

For R^{G1}, the alkenyl group, alkylcarbonyloxy group, or alkyloxycarbonyl group may be linear or branched, and preferably has 2 to 10 carbon atoms, and more preferably 2 to 5 carbon atoms.

For R^{G1}, the cycloalkyl group may be monocyclic or polycyclic, and preferably has 3 to 20 carbon atoms, and more preferably 5 to 15 carbon atoms.

For R^{G1}, the aryl group, aralkyl group, or aryloxycarbonyl group may be monocyclic or polycyclic, and preferably has 6 to 20 carbon atoms, and more preferably 6 to 15 carbon atoms. In the formula (G-1), R^{G2} represents a hydrogen atom or an organic group.

For R^{G2}, the organic group is, for example, an alkyl group, a cycloalkyl group, an aryl group, or an alkenyl group, and is preferably an alkyl group. For R^{G2}, the organic group preferably has 1 to 10 carbon atoms, and more preferably 1 to 5 carbon atoms.

R^{G2} preferably represents a hydrogen atom.

In the formula (G-1), L^{G1} represents a single bond or a divalent linking group.

For L^{G1}, the divalent linking group may be an alkylene group, a cycloalkylene group, an arylene group, a heteroarylene group, —Rt^{G1}—COO—,-Rt^{G1}—O—, or the like. Rt^{G1} represents a single bond, an alkylene group, or a cycloalkylene group. Rt^{G1} is preferably a single bond or an alkylene group having 1 to 5 carbon atoms.

L^{G1} is preferably a single bond or an-Rt^{Q1}-COO-group, and more preferably a single bond.

In the formula (G-1), j1 represents an integer of 1 or more and (5+2q) or less, preferably represents an integer of 1 or more and 5 or less, more preferably represents an integer of 1 or more and 3 or less, particularly preferably represents 1 or 2, and most preferably represents 1.

j2 represents an integer of 0 or more and (5+2q-j1) or less, preferably represents an integer of 0 or more and 4 or less, more preferably represents an integer of 0 or more and 2 or less, particularly preferably represents 0 or 1, and most preferably represents 0.

The repeating unit (iii) is preferably a repeating unit represented by the following formula (G-2).

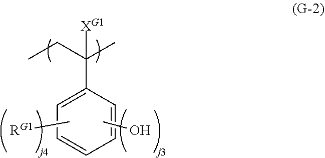

In the formula (G-2), X^{G1} and RGI respectively have the same meanings as X^{G1} and R^{G1} in the formula (G-1). j3 represents an integer of 1 or more and 3 or less. j4 represents an integer of 0 or more and (5-j3) or less.

In the formula (G-2), X^{G1} and RGI respectively have the same meanings as X^{G1} and R^{G1} in the formula (G-1), and preferred ranges and specific examples thereof are also the same.

j3 represents an integer of 1 or more and 3 or less, more preferably represents 1 or 2, and most preferably represents 1.

j4 represents an integer of 0 or more and (5-j3) or less, more preferably represents 0 or 1, and most preferably represents 0.

Non-limiting specific examples of the monomer that provides the repeating unit (iii) (monomer corresponding to the repeating unit (iii)) are as follows.

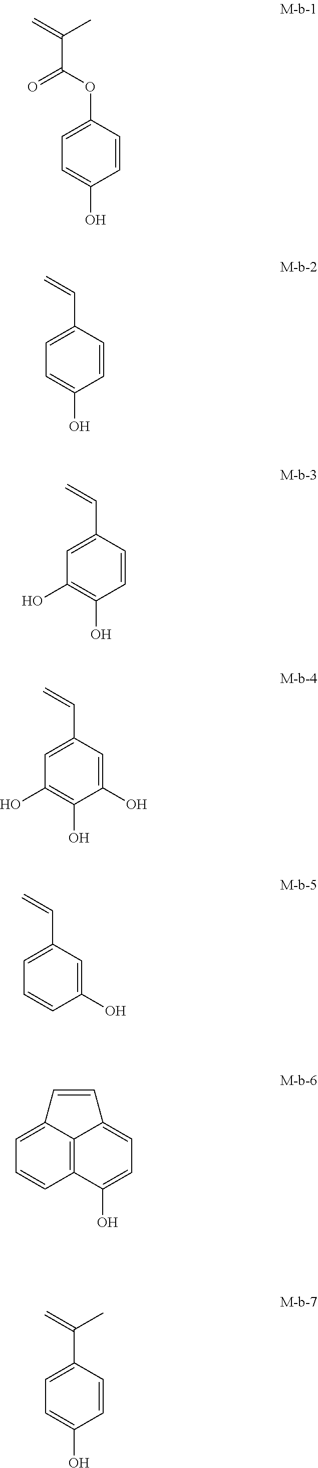

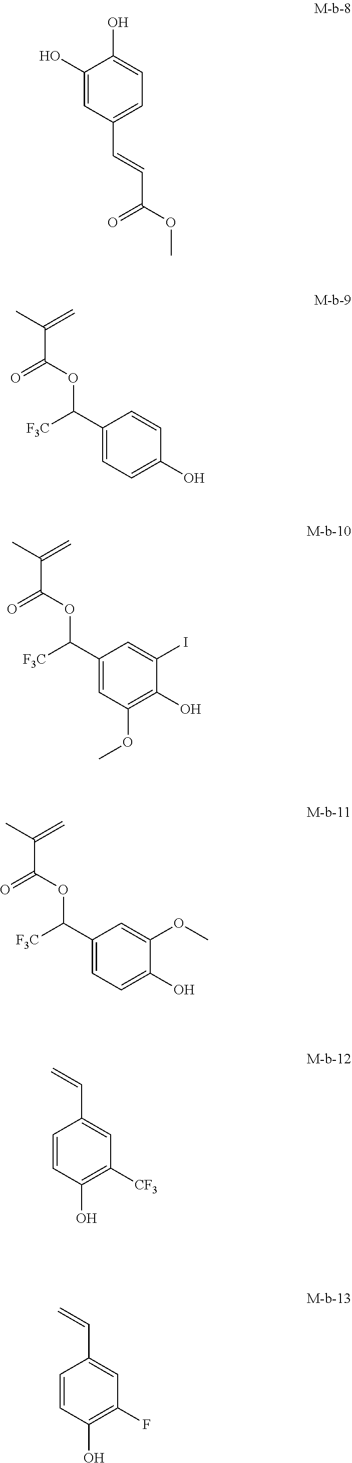

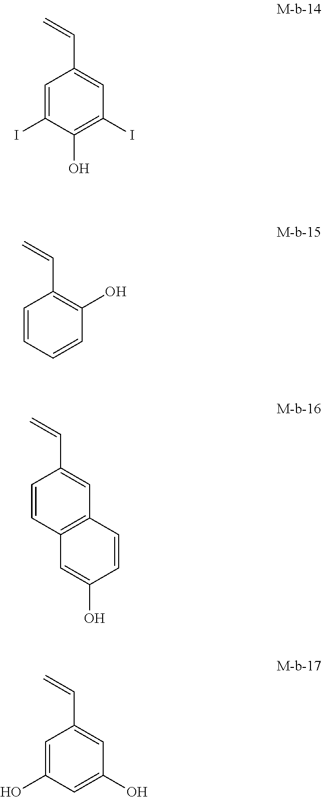

The resin (A) may include one type of the repeating unit (iii) or two or more types of the repeating unit (iii).

The content of the repeating unit (iii) is not particularly limited.

The content of the repeating unit (iii) is, relative to all the repeating units in the resin (A), preferably 5 mol % or more, more preferably 10 mol % or more, still more preferably 20 mol % or more, and particularly preferably 30 mol % or more.

The content of the repeating unit (iii) is, relative to all the repeating units in the resin (A), preferably 70 mol % or less, more preferably 65 mol % or less, and still more preferably 60 mol % or less.

The resin (A) may include, in addition to the above-described repeating unit (i), repeating unit (ii), and repeating unit (iii), further another repeating unit.

The aromatic ring of the repeating unit (i), the phenolic hydroxy group generated by the leaving reaction of the repeating unit (i), the cyano group and the lactone structure of the repeating unit (ii), and the phenolic hydroxy group of the repeating unit (iii) interact with each other to form a resin film in which acid is less likely to diffuse, so that defects during formation of an ultrafine pattern can be suppressed and the roughness performance is also improved, inferentially. In addition, as described above, the repeating unit having an acid-decomposable group in the resin (A) also contributes to the interaction, so that, when the content of the repeating unit having an acid-decomposable group is 35 mol % or more, higher advantages are provided.

In addition, as described later, a composition of the present invention preferably contains a photoacid generator; the aromatic ring of the repeating unit (i), the cyano group and the lactone structure of the repeating unit (ii), and the phenolic hydroxy group of the repeating unit (iii) interact with each other and form a homogeneous mixture with the photoacid generator, inferentially. Therefore, in particular, when a composition of the present invention contains a photoacid generator, defects during formation of an ultrafine pattern can be further suppressed and the roughness performance is also further improved, inferentially.

### Repeating Unit (iv)

The resin (A) may include a repeating unit having an acid-decomposable group different from the repeating unit (i)(also referred to as “repeating unit (iv)”).

The acid-decomposable group refers to a group that is decomposed by the action of an acid to generate a polar group. The acid-decomposable group preferably has a structure in which the polar group is protected with a group (leaving group) that leaves by the action of an acid.

The polar group is preferably an alkali-soluble group; examples include acidic groups such as a carboxyl group, a phenolic hydroxy group, fluorinated alcohol groups, a sulfonic acid group, a phosphoric acid group, a sulfonamide group, a sulfonylimide group, (alkylsulfonyl)(alkylcarbonyl)methylene groups, (alkylsulfonyl)(alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and an alcoholic hydroxy group.

In particular, the polar group is preferably a carboxyl group, a phenolic hydroxy group, a fluorinated alcohol group (preferably a hexafluoroisopropanol group), or a sulfonic acid group.

Examples of the group that leaves by the action of an acid include groups represented by formulas (Y1) to (Y4).

—C(Rx₁)(Rx₂)(Rx₃) formula (Y1)

—C(═O)OC(Rx₁)(Rx₂)(Rx₃) formula (Y2)

—C(R₃₆)(R₃₇)(OR₃₈) formula (Y3)

—C(Rn)(H)(Ar) formula (Y4)

In the formula (Y1) and the formula (Y2), Rx₁ to Rx₃ each independently represent an alkyl group (linear or branched), a cycloalkyl group (monocyclic or polycyclic), an alkenyl group (linear or branched), or an aryl group (monocyclic or polycyclic). Note that, when Rx₁ to Rx₃ are all alkyl groups (linear or branched), at least two among Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group.

Two among Rx₁ to Rx₃ may be bonded together to form a monocycle or a polycycle.

For Rx₁ to Rx₃, the alkyl group is preferably an alkyl group having 1 to 5 carbon atoms such as a methyl group, an ethyl group, an n-propyl group, an isopropyl group, an n-butyl group, an isobutyl group, or a t-butyl group.

For Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Rx₁ to Rx₃, the aryl group is preferably an aryl group having 6 to 10 carbon atoms, and may be, for example, a phenyl group, a naphthyl group, or an anthryl group.

For Rx₁ to Rx₃, the alkenyl group is preferably a vinyl group.

The ring formed by bonding together two among Rx₁ to Rx₃ is preferably a cycloalkyl group. The cycloalkyl group formed by bonding together two among Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms.

In the cycloalkyl group formed by bonding together two among Rx₁ to Rx₃, one of methylene groups constituting the ring may be replaced by a heteroatom such as an oxygen atom, a group including a heteroatom such as a carbonyl group, or a vinylidene group. In the cycloalkyl group, one or more ethylene groups constituting the cycloalkane ring may be replaced by vinylene groups.

The group represented by the formula (Y1) or the formula (Y2) preferably has a form in which, for example, Rx₁ is a methyl group or an ethyl group, and Rx₂ and Rx₃ are bonded together to form the above-described cycloalkyl group.

When a composition of the present invention is, for example, a resist composition used for EUV exposure, the alkyl groups, cycloalkyl groups, alkenyl groups, and aryl groups represented by Rx₁ to Rx₃ and the ring formed by bonding together two among Rx₁ to Rx₃ also preferably further have, as a substituent, a fluorine atom or an iodine atom.

In the formula (Y3), R₃₆ to R₃₈ each independently represent a hydrogen atom or a monovalent organic group. R₃₇ and R₃₈ may be bonded together to form a ring. The monovalent organic group may be an alkyl group, a cycloalkyl group, an aryl group, an aralkyl group, or an alkenyl group. R₃₆ is also preferably a hydrogen atom.

Note that the alkyl group, the cycloalkyl group, the aryl group, and the aralkyl group may include a heteroatom such as an oxygen atom and/or a group including a heteroatom such as a carbonyl group. For example, in the alkyl group, the cycloalkyl group, the aryl group, and the aralkyl group, one or more methylene groups may be replaced by a heteroatom such as an oxygen atom and/or a group including a heteroatom such as a carbonyl group.

R₃₈ and another substituent of the main chain of the repeating unit may be bonded together to form a ring. The group formed by bonding together R₃₈ and another substituent of the main chain of the repeating unit is preferably an alkylene group such as a methylene group.

When a composition of the present invention is, for example, a resist composition used for EUV exposure, the monovalent organic groups represented by R₃₆ to R₃₈ and the ring formed by bonding together R₃₇ and R₃₈ also preferably further have, as a substituent, a fluorine atom or an iodine atom.

The formula (Y3) is preferably a group represented by the following formula (Y3-1).

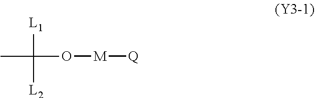

L₁ and L₂ above each independently represent a hydrogen atom, an alkyl group, a cycloalkyl group, an aryl group, or a group that is a combination of the foregoing (for example, a group that is a combination of an alkyl group and an aryl group).

M represents a single bond or a divalent linking group.

Q represents an alkyl group that may include a heteroatom, a cycloalkyl group that may include a heteroatom, an aryl group that may include a heteroatom, an amino group, an ammonium group, a mercapto group, a cyano group, an aldehyde group, or a group that is a combination of the foregoing (for example, a group that is a combination of an alkyl group and a cycloalkyl group).

In the alkyl group and the cycloalkyl group, for example, one of methylene groups may be replaced by a heteroatom such as an oxygen atom or a group including a heteroatom such as a carbonyl group.

Note that one of Li and L₂ is preferably a hydrogen atom and the other is preferably an alkyl group, a cycloalkyl group, an aryl group, or a group that is a combination of an alkylene group and an aryl group.

At least two among Q, M, and Li may be bonded together to form a ring (preferably a 5-membered or 6-membered ring).

From the viewpoint of forming finer patterns, L₂ is preferably a secondary or tertiary alkyl group, and more preferably a tertiary alkyl group. Examples of the secondary alkyl group include an isopropyl group, a cyclohexyl group, and a norbornyl group; examples of the tertiary alkyl group include a tert-butyl group and an adamantane group. In such examples, Tg (glass transition temperature) and activation energy are increased, so that film hardness is ensured and fogging can also be suppressed.

When a composition of the present invention is, for example, a resist composition used for EUV exposure, the alkyl groups, cycloalkyl groups, aryl groups, and groups that are combinations of the foregoing represented by Li and L₂ also preferably further have, as a substituent, a fluorine atom or an iodine atom. The alkyl groups, the cycloalkyl groups, the aryl groups, and the aralkyl groups also preferably include, in addition to a fluorine atom and an iodine atom, a heteroatom such as an oxygen atom. Specifically, in the alkyl groups, the cycloalkyl groups, the aryl groups, and the aralkyl groups, for example, one of methylene groups may be replaced by a heteroatom such as an oxygen atom or a group including a heteroatom such as a carbonyl group.

When a composition of the present invention is, for example, a resist composition used for EUV exposure, in the alkyl group that may include a heteroatom, cycloalkyl group that may include a heteroatom, aryl group that may include a heteroatom, amino group, ammonium group, mercapto group, cyano group, aldehyde group, and group that is a combination of the foregoing represented by Q, such a heteroatom is also preferably a heteroatom selected from the group consisting of a fluorine atom, an iodine atom, and an oxygen atom.

In the formula (Y4), Ar represents an aromatic ring group. Rn represents an alkyl group, a cycloalkyl group, or an aryl group. Rn and Ar may be bonded together to form a non-aromatic ring. Ar is preferably an aryl group.

When a composition of the present invention is, for example, a resist composition used for EUV exposure, the aromatic ring group represented by Ar and the alkyl group, cycloalkyl group, and aryl group represented by Rn also preferably have, as a substituent, a fluorine atom or an iodine atom.

From the viewpoint of providing a repeating unit having high acid-decomposability, in the leaving group protecting the polar group, when a non-aromatic ring is directly bonded to the polar group (or its residue), in the non-aromatic ring, a ring-member atom adjacent to a ring-member atom directly bonded to the polar group (or its residue) also preferably does not have, as a substituent, a halogen atom such as a fluorine atom.

Alternatively, the group that leaves by the action of an acid may be a 2-cyclopentenyl group having a substituent (such as an alkyl group) such as a 3-methyl-2-cyclopentenyl group, or a cyclohexyl group having a substituent (such as an alkyl group) such as a 1,1,4,4-tetramethylcyclohexyl group.

The repeating unit (iv) is also preferably a repeating unit represented by a formula (AI).

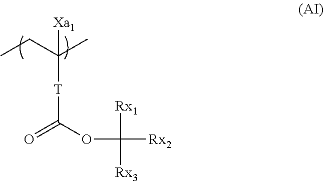

In the formula (AI), Xa₁ represents a hydrogen atom or an alkyl group that may have a substituent. T represents a single bond or a divalent linking group. Rx₁ to Rx₃ each independently represent an alkyl group (linear or branched), a cycloalkyl group (monocyclic or polycyclic), an alkenyl group (linear or branched), or an aryl(monocyclic or polycyclic) group. Note that, when Rx₁ to Rx₃ are all alkyl groups (linear or branched), at least two among Rx₁ to Rx₃ are preferably methyl groups.

Two among Rx₁ to Rx₃ may be bonded together to form a monocycle or polycycle (such as a monocyclic or polycyclic cycloalkyl group).

The alkyl group that is represented by Xa₁ and may have a substituent may be, for example, a methyl group or a group represented by —CH₂-R₁₁. R₁₁ represents a halogen atom (such as a fluorine atom), a hydroxy group, or a monovalent organic group. The monovalent organic group represented by R₁₁ is, for example, an alkyl group that has 5 or less carbon atoms and that may be substituted with a halogen atom, an acyl group that has 5 or less carbon atoms and that may be substituted with a halogen atom, or an alkoxy group that has 5 or less carbon atoms and that may be substituted with a halogen atom, and is preferably an alkyl group having 3 or less carbon atoms, and more preferably a methyl group. Xa₁ is preferably a hydrogen atom, a methyl group, a trifluoromethyl group, or a hydroxymethyl group.

For T, the divalent linking group may be an alkylene group, an aromatic ring group, a —COO-Rt-group, or an —O-Rt-group. In the formulas, Rt represent an alkylene group or a cycloalkylene group.

Tis preferably a single bond or a-COO-Rt-group. When T represents a-COO-Rt-group, Rt is preferably an alkylene group having 1 to 5 carbon atoms, and more preferably a-CH₂-group, a-(CH₂)₂-group, or a-(CH₂)₃-group.

For Rx₁ to Rx₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

For Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Rx₁ to Rx₃, the aryl group is preferably an aryl group having 6 to 10 carbon atoms and may be, for example, a phenyl group, a naphthyl group, or an anthryl group.

For Rx₁ to Rx₃, the alkenyl group is preferably a vinyl group.

The cycloalkyl group formed by bonding together two among Rx₁ to Rx₃ is preferably a monocyclic cycloalkyl group such as a cyclopentyl group or a cyclohexyl group. Also preferred are polycyclic cycloalkyl groups such as a norbornyl group, a tetracyclodecanyl group, a tetracyclododecanyl group, and an adamantyl group. In particular, preferred is a monocyclic cycloalkyl group having 5 to 6 carbon atoms.

In the cycloalkyl group formed by bonding together two among Rx₁ to Rx₃, for example, one of methylene groups constituting the ring may be replaced by a heteroatom such as an oxygen atom, a group including a heteroatom such as a carbonyl group, or a vinylidene group. In the cycloalkyl group, one or more of the ethylene groups constituting the cycloalkane ring may be replaced by vinylene groups.

The repeating unit represented by the formula (AI) preferably has a form in which, for example, Rx₁ is a methyl group or an ethyl group, and Rx₂ and Rx₃ are bonded together to form the above-described cycloalkyl group.

When the groups have a substituent, examples of the substituent include an alkyl group (having 1 to 4 carbon atoms), a halogen atom, a hydroxy group, an alkoxy group (having 1 to 4 carbon atoms), a carboxyl group, and an alkoxycarbonyl group (having 2 to 6 carbon atoms). The substituent preferably has 8 or less carbon atoms.

The repeating unit represented by the formula (AI) is preferably an acid-decomposable (meth)acrylic acid tertiary alkyl ester-based repeating unit (the repeating unit where Xa₁ represents a hydrogen atom or a methyl group and T represents a single bond).

The repeating unit (iv) is preferably a repeating unit represented by a formula (E-1) below.

In a preferred embodiment, the resin (A) includes a repeating unit represented by the following formula (E-1).

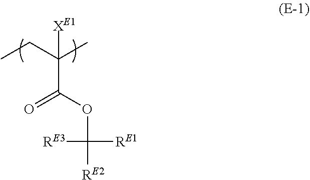

In the formula (E-1), X^{E1} represents a hydrogen atom, a halogen atom, a hydroxy group, or an organic group. R^{E1} to R^{E3} each independently represent a hydrocarbon group having 1 to 12 carbon atoms. Two among REI to R^{E3} may be bonded together to form a ring. When the hydrocarbon groups represented by R^{E1} to R^{E3} include alkylene groups, a part of the alkylene groups may be replaced with an ether group, a thioether group, or a carbonyl group.

In the formula (E-1), X^{E1} represents a hydrogen atom, a halogen atom, a hydroxy group, or an organic group.

For X^{E1}, the halogen atom is, for example, a fluorine atom, a chlorine atom, a bromine atom, or an iodine atom, and is preferably a fluorine atom.

For X^{E1}, the organic group is, for example, an alkyl group, a cycloalkyl group, an aryl group, or an alkenyl group, and is preferably an alkyl group. For X^{N1}, the number of carbon atoms of the organic group is preferably 1 to 10, and more preferably 1 to 6. For X^{E1}, the organic group is particularly preferably a methyl group.

X^{E1} is preferably a hydrogen atom, a fluorine atom or a methyl group, and more preferably a hydrogen atom or a methyl group.

In the formula (E-1), REI to R^{E3} each independently represent a hydrocarbon group having 1 to 12 carbon atoms. The hydrocarbon group is preferably an alkyl group (linear or branched), a cycloalkyl group (monocyclic or polycyclic), an alkenyl group (linear or branched), or an aryl(monocyclic or polycyclic) group.

For R^{E1} to R^{E3}, the alkyl group is preferably an alkyl group having 1 to 4 carbon atoms such as a methyl group, an ethyl group, an n-propyl group, an isopropyl group, an n-butyl group, an isobutyl group, or a t-butyl group.

For R^{E1} to R^{E3}, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For R^{E1} to R^{E3}, the aryl group is preferably an aryl group having 6 to 10 carbon atoms and may be, for example, a phenyl group, a naphthyl group, or an anthryl group.

For R^{E1} to R^{E3}, the alkenyl group is preferably a vinyl group.

Two among R^{E1} to R^{E3} may be bonded together to form a ring.

The ring formed by bonding together two among R^{E1} to R^{E3} is preferably an alicyclic ring, and preferably a monocyclic or polycyclic cycloalkane ring.

The ring formed by bonding together two among R^{E1} to R^{E3} preferably has 3 to 20 carbon atoms, more preferably 4 to 15 carbon atoms, and particularly preferably 5 to 12 carbon atoms. Specifically, the ring is preferably a cyclopentane ring, a cyclohexane ring, a norbornane ring, an adamantane ring, or the like.

The hydrocarbon groups represented by R^{E1} to R^{E3} and the ring formed by bonding together two among R^{E1} to R^{E3} may have a substituent. Examples of the substituent include the above-described Substituents T. The substituent may be, for example, an alkyl group (having 1 to 4 carbon atoms), a halogen atom, a hydroxy group, an alkoxy group (having 1 to 4 carbon atoms), a carboxyl group, or an alkoxycarbonyl group (having 2 to 6 carbon atoms). The substituent preferably has 8 or less carbon atoms.

When R^{E1} to R^{E3} represent a hydrocarbon group having a substituent, the number of carbon atoms including that of the substituent is preferably in the above-described range. When the ring formed by bonding together two among R^{E1} to R^{E3} has a substituent, the number of carbon atoms including that of the substituent is preferably in the above-described range.

The repeating unit (iv) is also preferably a repeating unit represented by a formula (E-2) below.

In a preferred embodiment, the resin (A) includes a repeating unit represented by the following formula (E-2).

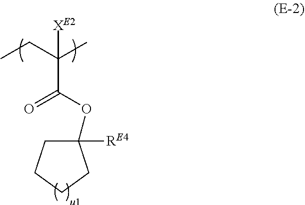

In the formula (E-2), X^{E2} represents a hydrogen atom, a halogen atom, or a methyl group. R^{E4} represents a hydrocarbon group having 6 or less carbon atoms. u1 represents 1 or 2.

In the formula (E-2), X^{E2} represents a hydrogen atom, a halogen atom, or a methyl group. For X^{E2}, the halogen atom is, for example, a fluorine atom, a chlorine atom, a bromine atom, or an iodine atom, and is preferably a fluorine atom.

X^{E2} is preferably a hydrogen atom, a fluorine atom, or a methyl group, and more preferably a hydrogen atom or a methyl group.

In the formula (E-2), R^{E4} represents a hydrocarbon group having 6 or less carbon atoms. The hydrocarbon group is preferably an alkyl group (linear or branched), a cycloalkyl group, an alkenyl group (linear or branched), or a phenyl group.

For R^{E4}, the alkyl group is preferably an alkyl group having 1 to 4 carbon atoms such as a methyl group, an ethyl group, an n-propyl group, an isopropyl group, an n-butyl group, an isobutyl group, or a t-butyl group.

For R^{E4}, the cycloalkyl group is preferably a cyclopentyl group or a cyclohexyl group.

For R^{E4}, the alkenyl group is preferably a vinyl group.

For R^{E4}, the hydrocarbon group may have a substituent. Examples of the substituent include the above-described Substituents T. The substituent may be, for example, an alkyl group (having 1 to 4 carbon atoms), a halogen atom, a hydroxy group, an alkoxy group (having 1 to 4 carbon atoms), a carboxyl group, or an alkoxycarbonyl group (having 2 to 5 carbon atoms).

When R^{E4} represents a hydrocarbon group having a substituent, the number of carbon atoms including that of the substituent is preferably in the above-described range. When the ring formed by bonding together two among R^{E1} to R^{E3} has a substituent, the number of carbon atoms including that of the substituent is preferably in the above-described range.

Non-limiting specific examples of the monomer that provides the repeating unit (iv) (monomer corresponding to the repeating unit (iv)) are as follows.

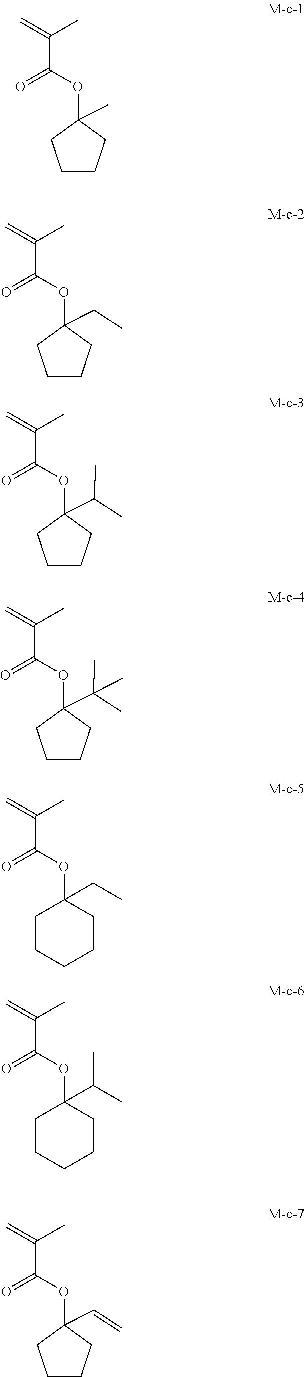

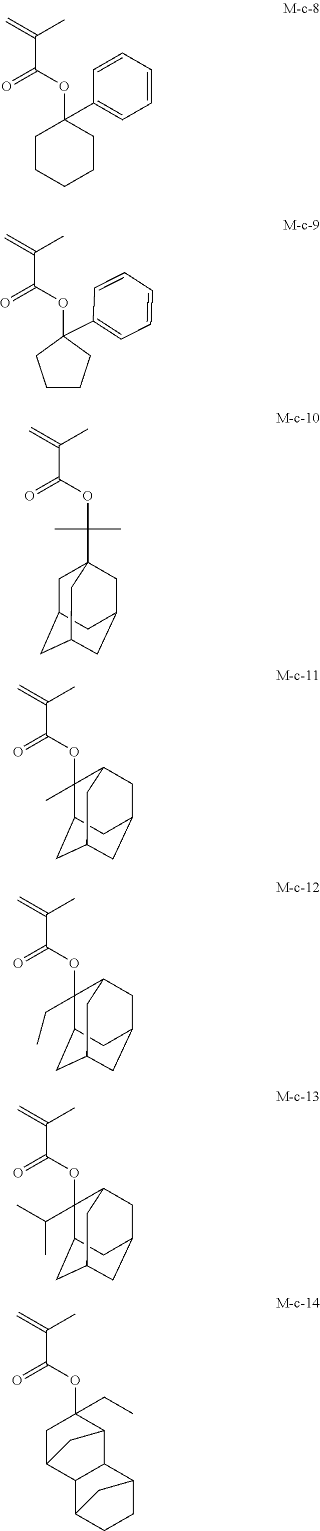

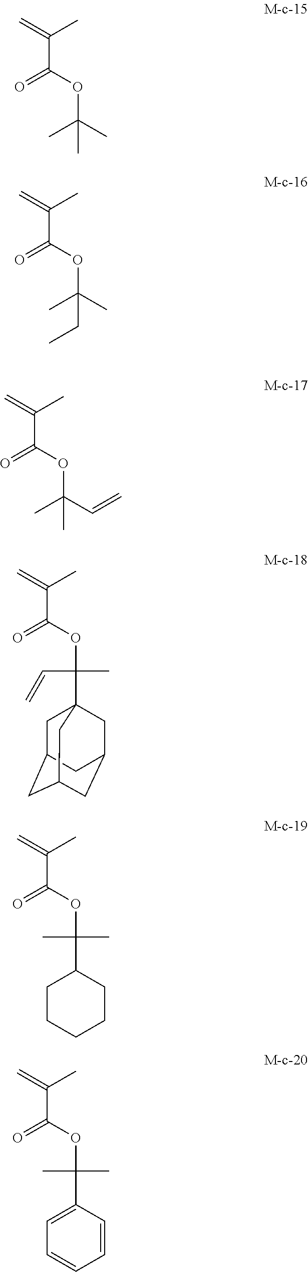

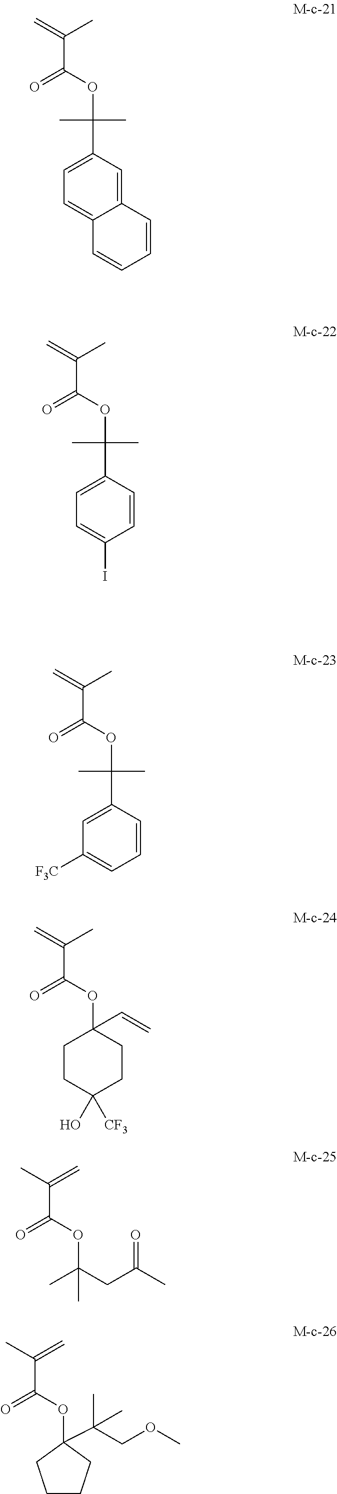

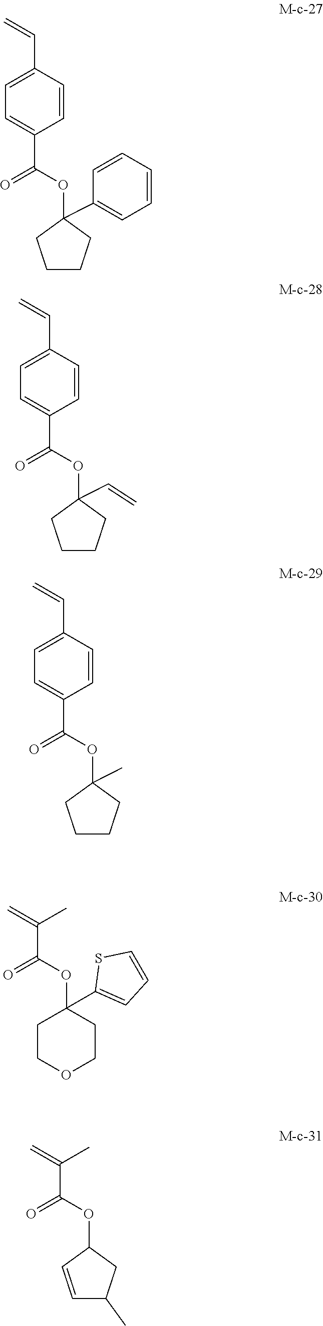

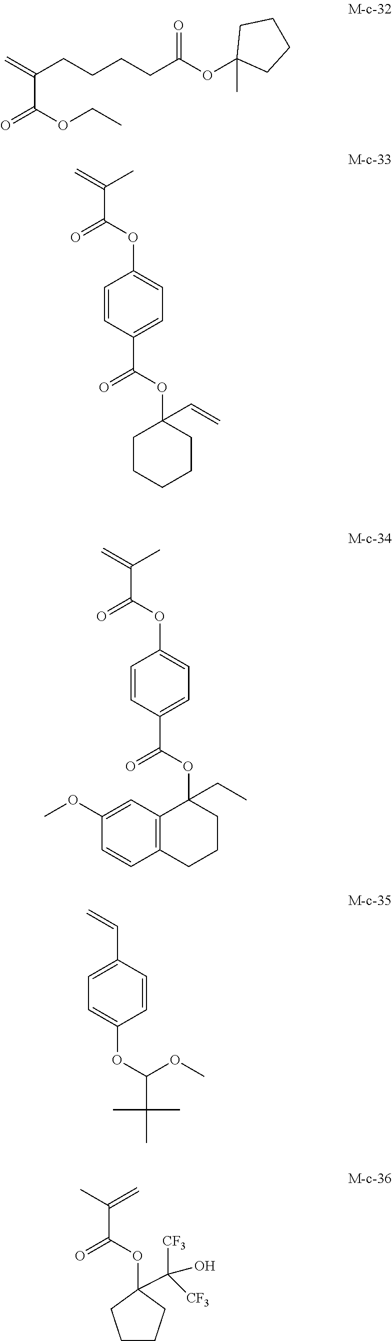

When the resin (A) includes the repeating unit (iv), the resin (A) may include one type of the repeating unit (iv) or two or more types of the repeating unit (iv).

When the resin (A) includes the repeating unit (iv), the content of the repeating unit (iv) is not particularly limited.

When the resin (A) includes the repeating unit (iv), the content of the repeating unit (iv) is, relative to all the repeating units in the resin (A), preferably 3 mol % or more, more preferably 5 mol % or more, and still more preferably 10 mol % or more.

When the resin (A) includes the repeating unit (iv), the content of the repeating unit (iv) is, relative to all the repeating units in the resin (A), preferably 60 mol % or less, more preferably 55 mol % or less, and still more preferably 50 mol % or less.

The resin (A) may not necessarily include the repeating unit (iv). In other words, the content of the repeating unit (iv) relative to all the repeating units in the resin (A) may be 0 mol %.

The content of the repeating unit having an acid-decomposable group in the resin (A) (the total content of the repeating unit (i) and the repeating unit (iv)) is, relative to all the repeating units in the resin (A), 35 mol % or more, preferably 40 mol % or more, and particularly preferably 45 mol % or more.

As the content of the repeating unit having an acid-decomposable group increases, the dissolution contrast increases. The repeating unit (i) tends to provide a relatively low dissolution contrast during the leaving reaction and hence its content is set to 35 mol % or more. In particular, in the case of forming an ultrafine pattern, a high dissolution contrast is required and hence the content of the repeating unit (i) is set to 35 mol % or more. When the resin (A) has a repeating unit (i) content of 35 mol % or more and includes the repeating unit (ii) having a cyano group and a lactone structure and the repeating unit (iii) having a phenolic hydroxy group, the solubility before the leaving reaction is optimally adjusted and the solubility is considerably changed during leaving of the leaving group, which inferentially results in high dissolution contrast.

The content of the repeating unit having an acid-decomposable group in the resin (A) is, relative to all the repeating units in the resin (A), preferably 90% or less, and more preferably 80% or less.

### Repeating Unit Having Acid Group

The resin (A) may further have a repeating unit (also referred to as “repeating unit (v)”) having an acid group different from that of the above-described repeating unit (iii).

The acid group is preferably an acid group having a pKa of 13 or less. The acid group preferably has an acid dissociation constant of 13 or less, more preferably 3 to 13, and still more preferably 5 to 10.

When the resin (A) has an acid group having a pKa of 13 or less, the content of the acid group in the resin (A) is not particularly limited, but is often 0.2 to 6.0 mmol/g. In particular, preferred is 0.8 to 6.0 mmol/g, more preferred is 1.2 to 5.0 mmol/g, and still more preferred is 1.6 to 4.0 mmol/g. When the content of the acid group is within such a range, development suitably proceeds to form a pattern having a good profile at high resolution.

The acid group is, for example, preferably a carboxyl group, a fluorinated alcohol group (preferably a hexafluoroisopropanol group), a sulfonic acid group, a sulfonamide group, or an isopropanol group.

In the hexafluoroisopropanol group, one or more (preferably one to two) of the fluorine atoms may be substituted with groups other than fluorine atoms (such as alkoxycarbonyl groups). The acid group is also preferably-C(CF₃)(OH)-CF₂-formed in this manner. Alternatively, one or more of the fluorine atoms may be substituted with groups other than fluorine atoms, to form a ring including-C(CF₃)(OH)-CF₂-.

The repeating unit having an acid group is preferably a repeating unit different from the above-described repeating unit having a structure in which a polar group is protected with a group that leaves by the action of an acid and repeating units described later and having a lactone group, a sultone group, or a carbonate group.

The repeating unit having an acid group may have a fluorine atom or an iodine atom.

Examples of the repeating unit having an acid group include the following repeating units.

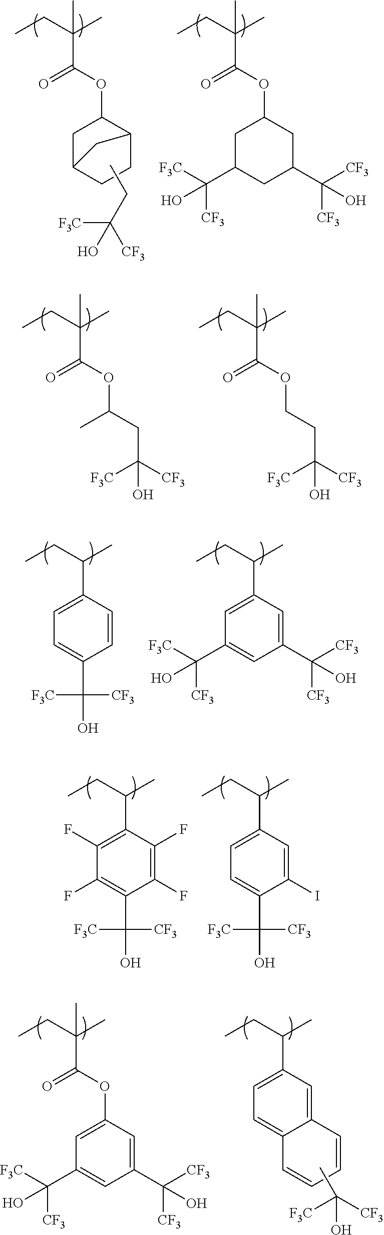

When the resin (A) includes the repeating unit (v), the resin (A) may include one type of the repeating unit (v) or two or more types of the repeating unit (v).

When the resin (A) includes the repeating unit (v), the content of the repeating unit (v) is not particularly limited.

When the resin (A) includes the repeating unit (v), the content of the repeating unit (v) is, relative to all the repeating units in the resin (A), preferably 1 mol % or more, more preferably 3 mol % or more, and still more preferably 5 mol % or more.

When the resin (A) includes the repeating unit (v), the content of the repeating unit (v) is, relative to all the repeating units in the resin (A), preferably 50 mol % or less, more preferably 40 mol % or less, and still more preferably 30 mol % or less.

The resin (A) may not necessarily include the repeating unit (v). In other words, the content of the repeating unit (v) relative to all the repeating units in the resin (A) may be 0 mol %. Repeating unit not having acid-decomposable group or acid group, but having fluorine atom, bromine atom, or iodine atom

The resin (A) may have a repeating unit that is different from the above-described repeating units (i) to (v), that does not have an acid-decomposable group or an acid group, but that has a fluorine atom, a bromine atom, or an iodine atom (hereafter, also referred to as “unit X”). This <repeating unit not having an acid-decomposable group or an acid group, but having a fluorine atom, a bromine atom, or an iodine atom> is preferably different from other repeating unit species such as a <repeating unit having a lactone group, a sultone group, or a carbonate group> and a <repeating unit having a photoacid generation group> described later.

The unit X is preferably a repeating unit represented by a formula (C).

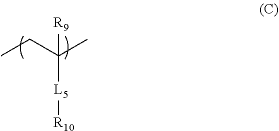

L₅ represents a single bond or an ester group. R₉ represents a hydrogen atom or an alkyl group that may have a fluorine atom or an iodine atom. R₁₀ represents a hydrogen atom, an alkyl group that may have a fluorine atom or an iodine atom, a cycloalkyl group that may have a fluorine atom or an iodine atom, an aryl group that may have a fluorine atom or an iodine atom, or a group that is a combination of the foregoing.

Examples of the repeating unit having a fluorine atom or an iodine atom are as follows.

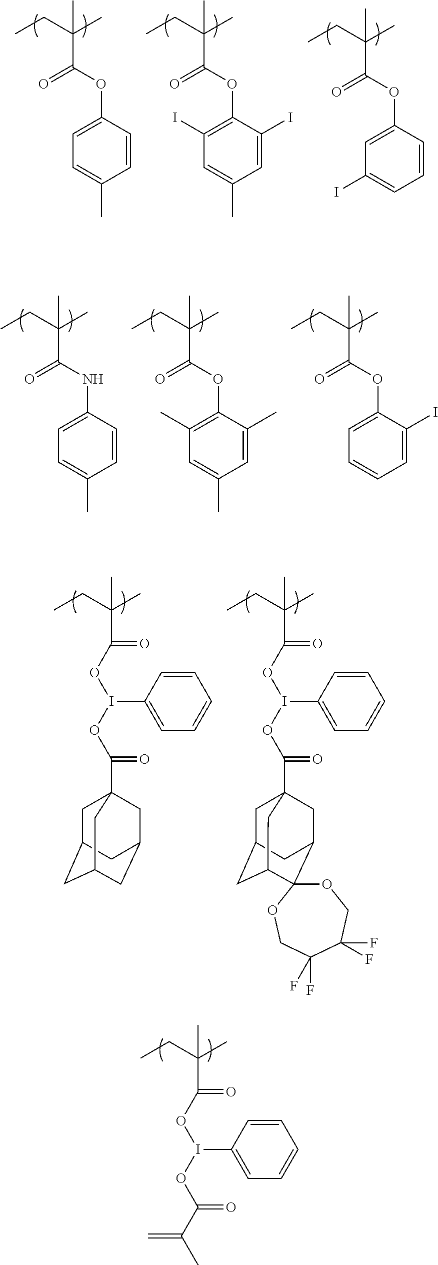

The unit X content relative to all the repeating units in the resin (A) is preferably 0 mol % or more, more preferably 5 mol % or more, and still more preferably 10 mol % or more. The upper limit value relative to all the repeating units in the resin (A) is preferably 50 mol % or less, more preferably 45 mol % or less, and still more preferably 40 mol % or less.

Of the repeating units of the resin (A), the total content of the repeating unit including at least one of a fluorine atom, a bromine atom, or an iodine atom relative to all the repeating units of the resin (A) is preferably 10 mol % or more, more preferably 20 mol % or more, still more preferably 30 mol % or more, and particularly preferably 40 mol % or more. The upper limit value is not particularly limited, but is, for example, relative to all the repeating units of the resin (A), 100 mol % or less.

Note that examples of the repeating unit including at least one of a fluorine atom, a bromine atom, or an iodine atom include a repeating unit having a fluorine atom, a bromine atom, or an iodine atom and having an acid-decomposable group, a repeating unit having a fluorine atom, a bromine atom, or an iodine atom and having an acid group, and a repeating unit having a fluorine atom, a bromine atom, or an iodine atom.

Repeating unit having lactone group, sultone group, or carbonate group

The resin (A) may have a repeating unit that is different from the above-described repeating unit (ii) and has at least one species selected from the group consisting of a lactone group, a sultone group, and a carbonate group (hereafter, also referred to as “unit Y”).

The unit Y also preferably does not have acid groups such as a hydroxy group and a hexafluoropropanol group.

The lactone group or the sultone group has a lactone structure or a sultone structure. The lactone structure or the sultone structure is preferably a 5- to 7-membered lactone structure or a 5- to 7-membered sultone structure. In particular, more preferred is a 5- to 7-membered lactone structure to which another ring structure is fused so as to form a bicyclo structure or a spiro structure, or a 5- to 7-membered sultone structure to which another ring structure is fused so as to form a bicyclo structure or a spiro structure.

The resin (A) preferably has a repeating unit having a lactone group or a sultone group provided by withdrawing, from ring-member atoms of the lactone structure represented by any one of formulas (LC1-1) to (LC1-21) below or the sultone structure represented by any one of formulas (SL1-1) to (SL1-3) below, one or more hydrogen atoms, and a lactone group or a sultone group may be directly bonded to the main chain. For example, ring-member atoms of a lactone group or a sultone group may constitute the main chain of the resin (A).

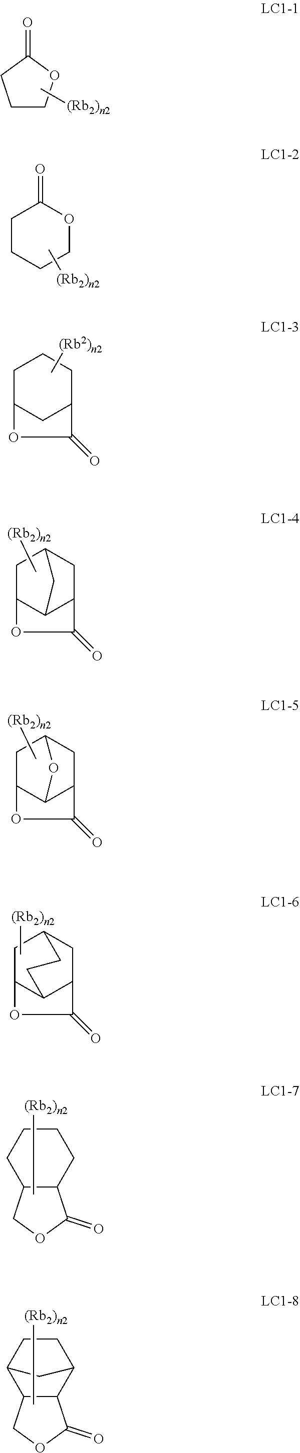

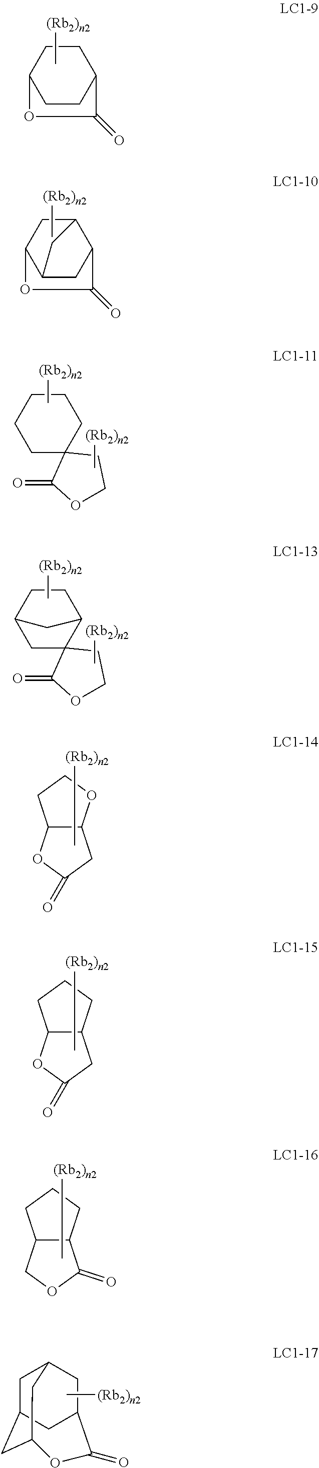

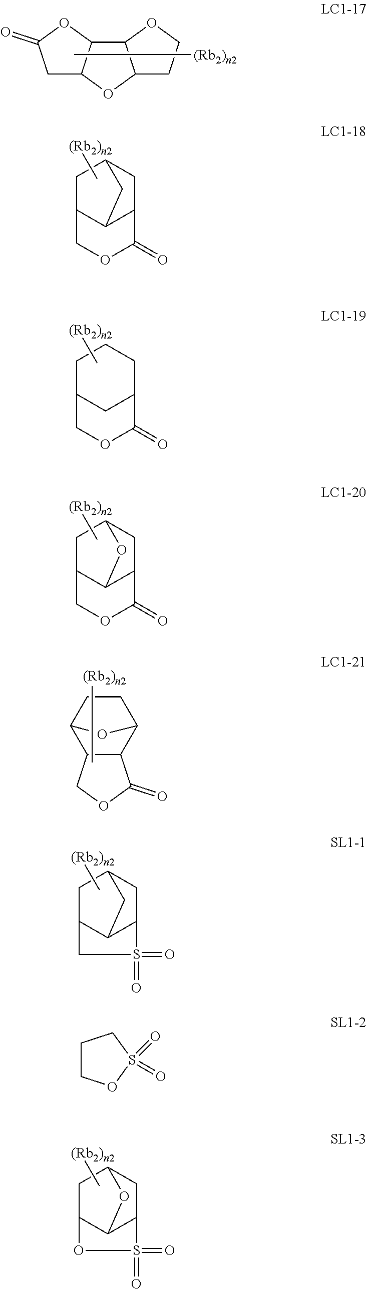

The lactone structure or the sultone structure may have a substituent (Rb₂). The substituent (Rb₂) may be preferably an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, or an acid-decomposable group. n2 represent an integer of 0 to 4. When n2 is 2 or more, the plurality of Rb₂'s present may be different, and the plurality of Rb₂'s present may be bonded together to form a ring.

The repeating unit having a group including the lactone structure represented by any one of the formulas (LC1-1) to (LC1-21) or the sultone structure represented by any one of the formulas (SL1-1) to (SL1-3) may be, for example, a repeating unit represented by the following formula (AI).

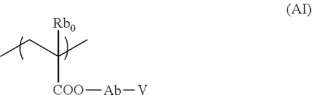

In the formula (AI), Rb₀ represents a hydrogen atom, a halogen atom, or an alkyl group having 1 to 4 carbon atoms. The substituent that the alkyl group of Rb₀ may have may be a hydroxy group or a halogen atom.

For Rb₀, the halogen atom may be a fluorine atom, a chlorine atom, a bromine atom, or an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent linking group that is a combination of the foregoing. In particular, Ab is preferably a single bond or a linking group represented by-Ab₁-CO₂-. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group formed by withdrawing, from a ring-member atom of the lactone structure represented by any one of the formulas (LC1-1) to (LC1-21), a single hydrogen atom, or a group formed by withdrawing, from a ring-member atom of the sultone structure represented by any one of the formulas (SL1-1) to (SL1-3), a single hydrogen atom.

When the repeating unit having a lactone group or a sultone group has an optical isomer, any optical isomer may be used. A single optical isomer may be used alone, or a plurality of optical isomers may be used in combination. In the case of mainly using one of the optical isomers, its optical purity (ee) is preferably 90 or more, and more preferably 95 or more. The carbonate group is preferably a cyclic carbonic acid ester group.

The repeating unit having a cyclic carbonic acid ester group is preferably a repeating unit represented by the following formula (A-1).

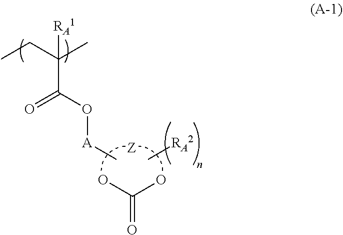

In the formula (A-1), R_{A}¹ represents a hydrogen atom, a halogen atom, or a monovalent organic group (preferably a methyl group). n represents an integer of 0 or more. R_{A}² represents a substituent. When n is 2 or more, the plurality of R_{A}²'s present may be the same or different. A represents a single bond or a divalent linking group. The divalent linking group is preferably an alkylene group, a divalent linking group having a monocyclic or polycyclic alicyclic hydrocarbon structure, an ether group, an ester group, a carbonyl group, a carboxyl group, or a divalent linking group that is a combination of the foregoing. Z represents an atomic group that forms, together with the group represented by-O—CO-O— in the formula, a monocycle or a polycycle.

When the resin (A) includes the unit Y, the content of the unit Y relative to all the repeating units in the resin (A) is preferably 1 mol % or more, and more preferably 10 mol % or more. The upper limit value relative to all the repeating units in the resin (A) is preferably 85 mol % or less, more preferably 80 mol % or less, still more preferably 70 mol % or less, and particularly preferably 60 mol % or less.

The resin (A) may not necessarily include the unit Y. In other words, the content of the unit Y relative to all the repeating units in the resin (A) may be 0 mol %.

### Repeating Unit Having Photoacid Generation Group

The resin (A) may have, as another repeating unit, a repeating unit having a group that generates an acid upon irradiation with an actinic ray or a radiation (also referred to as “photoacid generation group”).

The repeating unit having a photoacid generation group may be a repeating unit represented by a formula (4).

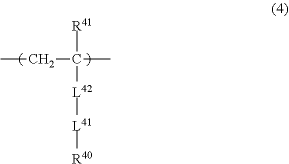

R⁴¹ represents a hydrogen atom or a methyl group. L⁴¹ represents a single bond or a divalent linking group. L⁴² represents a divalent linking group. R⁴⁰ represents a structural moiety that is decomposed upon irradiation with an actinic ray or a radiation to generate an acid in the side chain.

Examples of the repeating unit having a photoacid generation group are as follows.

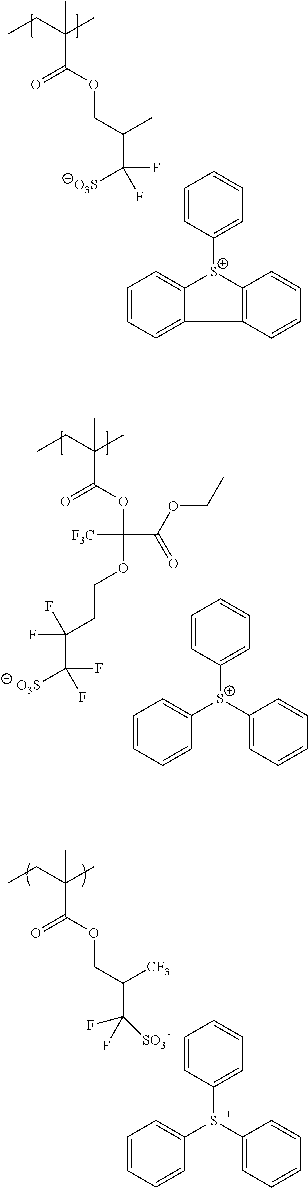

Other examples of the repeating unit represented by the formula (4) include the repeating units described in Paragraphs to of JP2014-041327A and the repeating units described in Paragraph of WO2018/193954A.

When the resin (A) includes a repeating unit having a photoacid generation group, the content of the repeating unit having a photoacid generation group is, relative to all the repeating units in the resin (A), preferably 1 mol % or more, and more preferably 5 mol % or more. The upper limit value relative to all the repeating units in the resin (A) is preferably 40 mol % or less, more preferably 35 mol % or less, and still more preferably 30 mol % or less.

The resin (A) may not necessarily include a repeating unit having a photoacid generation group. In other words, the content of the repeating unit having a photoacid generation group may be, relative to all the repeating units in the resin (A), 0 mol %.

Repeating unit represented by formula (V-1) or formula (V-2) below

The resin (A) may have a repeating unit represented by a formula (V-1) below or a formula (V-2) below.

The repeating unit represented by the formula (V-1) below or the formula (V-2) below is preferably a repeating unit different from the above-described repeating units.

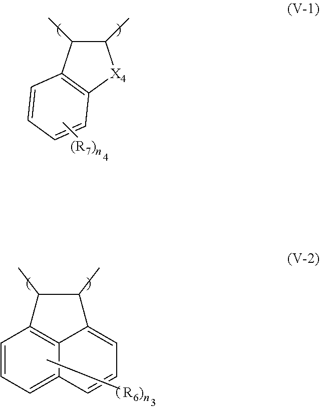

In the formulas,

R₆ and R₇ each independently represent a hydrogen atom, a hydroxy group, an alkyl group, an alkoxy group, an acyloxy group, a cyano group, a nitro group, an amino group, a halogen atom, an ester group (—OCOR or —COOR: R is an alkyl group or fluorinated alkyl group having 1 to 6 carbon atoms), or a carboxyl group. The alkyl group is preferably a linear, branched, or cyclic alkyl group having 1 to 10 carbon atoms.
n₃ represents an integer of 0 to 6.
n₄ represents an integer of 0 to 4.
X₄ is a methylene group, an oxygen atom, or a sulfur atom.

Examples of the repeating unit represented by the formula (V-1) or (V-2) are as follows.

Examples of the repeating unit represented by the formula (V-1) or (V-2) include the repeating units described in Paragraph of WO2018/193954A.

The resin (A) may have a repeating unit having an alkali-soluble group.

The alkali-soluble group may be a carboxyl group, a sulfonamide group, a sulfonylimide group, a bissulfonylimide group, or an aliphatic alcohol group substituted, at the a position, with an electron-withdrawing group (for example, a hexafluoroisopropanol group), and is preferably a carboxyl group. When the resin (A) includes the repeating unit having an alkali-soluble group, increased resolution is provided in the contact hole application. Examples of the repeating unit having an alkali-soluble group include those described in Paragraphs and of JP2014-098921A.

### Repeating Unit Having Alicyclic Hydrocarbon Structure and not Exhibiting Acid-Decomposability

The resin (A) may have a repeating unit having an alicyclic hydrocarbon structure and not exhibiting acid-decomposability. This results in, during liquid immersion exposure, a reduction in leaching of, from the resist film to the immersion liquid, low-molecular-weight components. Examples of the repeating unit having an alicyclic hydrocarbon structure and not exhibiting acid-decomposability include a repeating unit derived from 1-adamantyl(meth)acrylate, diamantyl(meth)acrylate, tricyclodecanyl(meth)acrylate, or cyclohexyl (meth)acrylate.

### Repeating Unit not Having Hydroxy Group or Cyano Group and Represented by Formula (III)

The resin (A) may have a repeating unit not having a hydroxy group or a cyano group and represented by a formula (III).

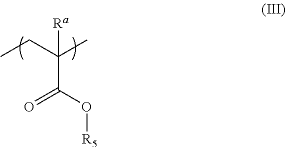

In the formula (III), R₅ represents a hydrocarbon group having at least one ring structure and not having a hydroxy group or a cyano group.

Ra represents a hydrogen atom, an alkyl group, or a-CH₂-O-Ra₂ group. In the formula, Ra₂ represents a hydrogen atom, an alkyl group, or an acyl group.

Examples of the repeating unit not having a hydroxy group or a cyano group and

represented by the formula (III) include those described in Paragraphs to of JP2014-098921A.

### Other Repeating Unit

Furthermore, the resin (A) may have another repeating unit other than the above-described repeating units.

For example, the resin (A) may have a repeating unit selected from the group consisting of a repeating unit having an oxathiane ring group, a repeating unit having an oxazolone ring group, a repeating unit having a dioxane ring group, and a repeating unit having a hydantoin ring group.

The resin (A) may have, in addition to such repeating structure units, for the purpose of adjusting, for example, dry etching resistance, standard developer suitability, substrate adhesiveness, resist profile, resolution, heat resistance, and sensitivity, various repeating structure units.

The resin (A) can be synthesized by standard procedures (for example, radical polymerization).

The weight-average molecular weight of the resin (A) determined as a polystyrene-equivalent value by the GPC method is preferably 30000 or less, more preferably 1000 to 30000, still more preferably 3000 to 30000, and particularly preferably 5000 to 15000.

The resin (A) preferably has a molecular-weight dispersity (Mw/Mn) of 3.0 or less, more preferably 2.0 or less, still more preferably 1.70 or less, and particularly preferably 1.60 or less. When the resin (A) has a molecular-weight dispersity of 1.70 or less, variation in the solubility of the resin (A) is suppressed, and in particular, defects during formation of an ultrafine pattern can be suppressed, and the roughness performance is also improved.

The molecular-weight dispersity of the resin (A) is ordinarily 1.0 or more, and may be 1.2 or more.

A composition of the present invention may include one type of the resin (A) or two or more types of the resin (A).

The content of the resin (A) in a composition of the present invention is, relative to the total solid content of the composition of the present invention, preferably 20.0 to 99.9 mass %, and more preferably from 30.0 to 90.0 mass %.

### Onium Salt Compound

A composition of the present invention preferably contains an onium salt compound.

In a preferred embodiment, a composition of the present invention contains, as a compound other than the resin (A), an onium salt compound.

Examples of the onium salt compound include a photoacid generator and an acid diffusion control agent described later.

### Photoacid Generator

A composition of the present invention preferably contains a photoacid generator (also referred to as “photoacid generator (B)” or “compound (B)).

The photoacid generator is a compound that generates an acid upon irradiation with an actinic ray or a radiation.

The pKa of the acid generated from the photoacid generator (B) is not particularly limited, but is preferably-12 to 1, and more preferably −12 to −2.

The acid generated from the photoacid generator (B) ordinarily reacts with the acid-decomposable group of the resin (A).

The photoacid generator (B) may have the form of a low-molecular-weight compound or may have the form of being incorporated into a portion of a polymer. Alternatively, the form of a low-molecular-weight compound and the form of being incorporated into a portion of a polymer may be used in combination.

When the photoacid generator (B) has the form of a low-molecular-weight compound, the photoacid generator (B) preferably has a molecular weight of 3000 or less, more preferably 2000 or less, and still more preferably 1000 or less. The lower limit is not particularly limited, and may be, for example, 100 or more.

When the photoacid generator (B) has the form of being incorporated into a portion of a polymer, it may be incorporated into a portion of the resin (A) or may be incorporated into a resin different from the resin (A).

The photoacid generator (B) is preferably a compound different from the resin (A).

The photoacid generator (B) preferably has the form of a low-molecular-weight compound.

The photoacid generator (B) is preferably an onium salt compound, may be a compound represented by “M⁺ X⁻” (onium salt compound), and is preferably a compound that generates an organic acid upon exposure.

Examples of the organic acid include sulfonic acids (such as aliphatic sulfonic acids, aromatic sulfonic acids, and camphorsulfonic acid), carboxylic acids (such as aliphatic carboxylic acids, aromatic, carboxylic acids, and aralkyl carboxylic acids), carbonylsulfonylimidic acid, bis(alkylsulfonyl) imidic acids, and tris(alkylsulfonyl) methide acids.

In the compound represented by “M⁺ X⁻”, M⁺ represents an organic cation.

The organic cation is not particularly limited. For the valence, the organic cation may be mono-, di-, or higher valent.

In particular, the organic cation is preferably a cation represented by a formula (ZaI) (hereafter, also referred to as “cation (ZaI)”) or a cation represented by a formula (ZaII) (hereafter, also referred to as “cation (ZaII)”).

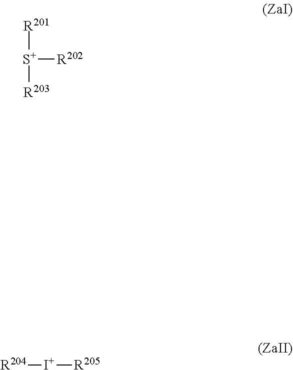

In the formula (ZaI), R²⁰¹, R²⁰², and R²⁰³ each independently represent an organic group.

For R²⁰¹, R²⁰², and R²⁰³, the organic group preferably has 1 to 30 carbon atoms, and more preferably 1 to 20 carbon atoms. Among R²⁰¹ to R²⁰³, two may be bonded together to form a ring structure and the ring may include an oxygen atom, a sulfur atom, an ester group, an amide group, or a carbonyl group. Examples of the group formed by bonding together two among R²⁰¹ to R²⁰³ include alkylene groups (such as a butylene group and a pentylene group), and -CH₂-CH₂-O-CH₂-CH₂-.

Preferred examples of the organic cation in the formula (ZaI) include a cation (ZaI-1) described later.

The cation (ZaI-1) will be described.

The cation (ZaI-1) is an aryl sulfonium cation represented by the above-described formula (ZaI) where at least one of R²⁰¹ to R²⁰³ is an aryl group.

In the aryl sulfonium cation, all of R²⁰¹ to R²⁰³ may be aryl groups, or a part of R²⁰¹ to R²⁰³ may be an aryl group and the other may be an alkyl group or a cycloalkyl group.

Alternatively, one among R²⁰¹ to R²⁰³ may be an aryl group and the other two among R²⁰¹ to R²⁰³ may be bonded together to form a ring structure in which the ring may include an oxygen atom, a sulfur atom, an ester group, an amide group, or a carbonyl group. Examples of the group formed by bonding together two among R²⁰¹ to R²⁰³ include alkylene groups in which one or more methylene groups may be substituted with an oxygen atom, a sulfur atom, an ester group, an amide group, and/or a carbonyl group (such as a butylene group, a pentylene group, and —CH₂-CH₂-O-CH₂-CH₂-).

Examples of the aryl sulfonium cation include triaryl sulfonium cations, diaryl alkyl sulfonium cations, aryl dialkyl sulfonium cations, diaryl cycloalkyl sulfonium cations, and aryl dicycloalkyl sulfonium cations.

The aryl group included in the aryl sulfonium cation is preferably a phenyl group or a naphthyl group, and more preferably a phenyl group. The aryl group may be an aryl group having a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. When the aryl sulfonium cation has two or more aryl groups, the two or more aryl groups may be the same or different.

The alkyl group or cycloalkyl group that the aryl sulfonium cation has as needed is preferably a linear alkyl group having 1 to 15 carbon atoms, a branched alkyl group having 3 to 15 carbon atoms, or a cycloalkyl group having 3 to 15 carbon atoms, and more preferably a methyl group, an ethyl group, a propyl group, an n-butyl group, a sec-butyl group, a t-butyl group, a cyclopropyl group, a cyclobutyl group, or a cyclohexyl group.

For R²⁰¹ to R²⁰³, a substituent that the aryl group, the alkyl group, and the cycloalkyl group may have is preferably an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a cycloalkylalkoxy group (having, for example, 1 to 15 carbon atoms), a halogen atom (for example, fluorine or iodine), a hydroxyl group, a carboxyl group, an ester group, a sulfinyl group, a sulfonyl group, an alkylthio group, or a phenylthio group.

The substituent may further have, when possible, a substituent; the alkyl group also preferably has, as a substituent, a halogen atom to serve as an alkyl halide group such as a trifluoromethyl group.

Such substituents are also preferably combined appropriately to form an acid-decomposable group.

Note that the acid-decomposable group means a group that is decomposed by the action of an acid to generate a polar group, and preferably has a structure in which a group that leaves by the action of an acid protects the polar group. The polar group and the leaving group are as described above.

Hereinafter, the formula (ZaII) will be described.

In the formula (ZaII), R²⁰⁴ and R²⁰⁵ each independently represent an aryl group, an alkyl group, or a cycloalkyl group.

For R²⁰⁴ and R²⁰⁵, the aryl group is preferably a phenyl group or a naphthyl group, and more preferably a phenyl group. For R²⁰⁴ and R²⁰⁵, the aryl group may be an aryl group having a heterocycle having an oxygen atom, a nitrogen atom, a sulfur atom, or the like. Examples of the skeleton of the aryl group having a heterocycle include pyrrole, furan, thiophene, indole, benzofuran, and benzothiophene.

For R²⁰⁴ and R²⁰⁵, the alkyl group and the cycloalkyl group are preferably a linear alkyl group having 1 to 10 carbon atoms, a branched alkyl group having 3 to 10 carbon atoms (for example, a methyl group, an ethyl group, a propyl group, a butyl group, or a pentyl group), or a cycloalkyl group having 3 to 10 carbon atoms (for example, a cyclopentyl group, a cyclohexyl group, or a norbornyl group).

For R²⁰⁴ and R²⁰⁵, the aryl group, the alkyl group, and the cycloalkyl group may each independently have a substituent. For R²⁰⁴ and R²⁰⁵, examples of the substituent that the aryl group, the alkyl group, and the cycloalkyl group may have include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms, a hydroxy group, and a phenylthio group. For R²⁰⁴ and R 205, substituents are also preferably provided independently as appropriate combinations of substituents to form acid-decomposable groups.

In the compound represented by “M⁺ X⁻”, X-represents an organic anion.

The organic anion is not particularly limited, but may be a mono-, di-, or higher valent organic anion.

The organic anion is preferably an anion that has a very low capability of causing a nucleophilic reaction, and more preferably a non-nucleophilic anion.

Examples of the non-nucleophilic anion include sulfonate anions (such as aliphatic sulfonate anions, aromatic sulfonate anions, and a camphorsulfonate anion), carboxylate anions (such as aliphatic carboxylate anions, aromatic carboxylate anions, and aralkyl carboxylate anions), a sulfonylimide anion, bis(alkylsulfonyl)imide anions, and tris(alkylsulfonyl) methide anions.

In such an aliphatic sulfonate anion or aliphatic carboxylate anion, the aliphatic moiety may be a linear or branched alkyl group or may be a cycloalkyl group, and is preferably a linear or branched alkyl group having 1 to 30 carbon atoms, or a cycloalkyl group having 3 to 30 carbon atoms.

The alkyl group may be, for example, a fluoroalkyl group (that may have a substituent other than a fluorine atom, or may be a perfluoroalkyl group).

In such an aromatic sulfonate anion or aromatic carboxylate anion, the aryl group is preferably an aryl group having 6 to 14 carbon atoms, and may be, for example, a phenyl group, a tolyl group, or a naphthyl group.

The above-described alkyl group, cycloalkyl group, and aryl group may have a substituent. The substituent is not particularly limited; examples include a nitro group, halogen atoms such as a fluorine atom and a chlorine atom, a carboxyl group, a hydroxyl group, an amino group, a cyano group, alkoxy groups (preferably having 1 to 15 carbon atoms), alkyl groups (preferably having 1 to 10 carbon atoms), cycloalkyl groups (preferably having 3 to 15 carbon atoms), aryl groups (preferably having 6 to 14 carbon atoms), alkoxycarbonyl groups (preferably having 2 to 7 carbon atoms), acyl groups (preferably having 2 to 12 carbon atoms), alkoxycarbonyloxy groups (preferably having 2 to 7 carbon atoms), alkylthio groups (preferably having 1 to 15 carbon atoms), alkylsulfonyl groups (preferably having 1 to 15 carbon atoms), alkyliminosulfonyl groups (preferably having 1 to 15 carbon atoms), and aryloxysulfonyl groups (preferably having 6 to 20 carbon atoms).

In such an aralkyl carboxylate anion, the aralkyl group is preferably an aralkyl group having 7 to 14 carbon atoms.

Examples of the aralkyl group having 7 to 14 carbon atoms include a benzyl group, a phenethyl group, a naphthylmethyl group, a naphthylethyl group, and a naphthylbutyl group.

The sulfonylimide anion may be, for example, a saccharin anion.

In such a bis(alkylsulfonyl)imide anion or a tris(alkylsulfonyl) methide anion, the alkyl groups are preferably an alkyl group having 1 to 5 carbon atoms. In the alkyl group, a substituent may be a halogen atom, an alkyl group substituted with a halogen atom, an alkoxy group, an alkylthio group, an alkyloxysulfonyl group, an aryloxysulfonyl group, or a cycloalkylaryloxysulfonyl group, and is preferably a fluorine atom or an alkyl group substituted with a fluorine atom.

In the bis(alkylsulfonyl)imide anion, the alkyl groups may be bonded together to form a ring structure. This results in an increase in the acid strength.

The photoacid generator is also preferably at least one selected from the group consisting of compounds (I) to (II).

### Compound (I)

The compound (I) is a compound having one or more structural moieties X described below and one or more structural moieties Y described below, and is a compound that generates, upon irradiation with an actinic ray or a radiation, an acid including a first acidic moiety described below derived from the structural moiety X described below and a second acidic moiety described below derived from the structural moiety Y described below.

Structural moiety X: a structural moiety that is constituted by an anionic moiety A₁⁻ and a cationic moiety M₁⁺ and that forms, upon irradiation with an actinic ray or a radiation, the first acidic moiety represented by HA₁

Structural moiety Y: a structural moiety that is constituted by an anionic moiety A₂⁻ and a cationic moiety M₂⁺ and that forms, upon irradiation with an actinic ray or a radiation, the second acidic moiety represented by HA₂

The compound (I) satisfies the following condition I.

Condition I: A compound PI in which the cationic moiety M₁⁺ in the structural moiety X and the cationic moiety M₂⁺ in the structural moiety Y in the compound (I) are replaced by H⁺ has an acid dissociation constant al derived from an acidic moiety represented by HA₁ in which the cationic moiety M₁⁺ in the structural moiety X is replaced by H⁺, and an acid dissociation constant a2 derived from an acidic moiety represented by HA₂ in which the cationic moiety M₂⁺ in the structural moiety Y is replaced by H⁺, and the acid dissociation constant a2 is larger than the acid dissociation constant al.

Hereinafter, the condition I will be more specifically described.

When the compound (I) is, for example, a compound that generates an acid having one first acidic moiety derived from the structural moiety X and one second acidic moiety derived from the structural moiety Y, the compound PI corresponds to a “compound having HA₁ and HA₂”.

The acid dissociation constant al and the acid dissociation constant a2 of the compound PI will be more specifically described as follows: in determination of the acid dissociation constants of the compound PI, the pKa at the time when the compound PI turns into a “compound having A₁⁻ and HA₂” is the acid dissociation constant a1, and the pKa at the time when the “compound having A₁⁻ and HA₂” turns into a “compound having A₁⁻ and A₂⁻” is the acid dissociation constant a2.

When the compound (I) is, for example, a compound that generates an acid having two first acidic moieties derived from the structural moieties X and one second acidic moiety derived from the structural moiety Y, the compound PI corresponds to a “compound having two HA₁ and one HA₂”.

In determination of the acid dissociation constants of the compound PI, the acid dissociation constant at the time when the compound PI turns into a “compound having one A₁⁻”, one HA₁, and one HA₂″ and the acid dissociation constant at the time when the “compound having one A₁⁻”, one HA₁, and one HA₂″ turns into a “compound having two A₁⁻ and one HA₂” correspond to the above-described acid dissociation constant al. The acid dissociation constant at the time when the “compound having two A₁⁻ and one HA₂” turns into a “compound having two A₁⁻ and A₂⁻” corresponds to the acid dissociation constant a2. In other words, when the compound PI has a plurality of acid dissociation constants derived from the acidic moieties represented by HA₁ in which the cationic moiety M₁⁺ in the structural moiety X is replaced by H⁺, the value of the acid dissociation constant a2 is larger than the largest value among the plurality of the acid dissociation constants al. Note that, in a case where the acid dissociation constant at the time when the compound PI turns into the “compound having one Ar, one HA₁, and one HA₂” is defined as aa, and the acid dissociation constant at the time when the “compound having one A₁⁻”, one HA₁, and one HA₂″ turns into the “compound having two A₁⁻” and one HA₂″ is defined as ab, the relationship between aa and ab satisfies aa<ab.

The acid dissociation constant al and the acid dissociation constant a2 can be determined by the above-described method of measuring an acid dissociation constant.

The compound PI corresponds to an acid generated upon irradiation of the compound (I) with an actinic ray or a radiation.

When the compound (I) has two or more structural moieties X, the structural moieties X may be the same or different. The two or more A₁⁻ and the two or more M₁⁺ may be individually the same or different.

In the compound (I), A₁⁻ above and A₂⁻ above, and M₁⁺ above and M₂⁺ above may be individually the same or different, but A₁⁻ above and A₂⁻ above are preferably different.

In the compound PI, the difference (absolute value) between the acid dissociation constant al (when a plurality of acid dissociation constants al are present, the maximum value thereof) and the acid dissociation constant a2 is preferably 0.1 or more, more preferably 0.5 or more, and still more preferably 1.0 or more. Note that the upper limit value of the difference (absolute value) between the acid dissociation constant al (when a plurality of acid dissociation constants al are present, the maximum value thereof) and the acid dissociation constant a2 is not particularly limited, but is, for example, 16 or less.

In the compound PI, the acid dissociation constant a2 is preferably 20 or less, and more preferably 15 or less. Note that the lower limit value of the acid dissociation constant a2 is preferably-4.0 or more.

In the compound PI, the acid dissociation constant al is preferably 2.0 or less, and more preferably 0 or less. Note that the lower limit value of the acid dissociation constant al is preferably-20.0 or more.

The anionic moiety A₁⁻ and the anionic moiety A₂⁻ are structural moieties including a negatively charged atom or atomic group and may be, for example, structural moieties selected from the group consisting of formulas (AA-1) to (AA-3) and formulas (BB-1) to (BB-6) below.

The anionic moiety A₁⁻ is preferably an anionic moiety that can form an acidic moiety having a small acid dissociation constant, in particular, more preferably any one of the formulas (AA-1) to (AA-3), and still more preferably any one of the formulas (AA-1) and (AA-3).

The anionic moiety A₂⁻ is preferably an anionic moiety that can form an acidic moiety having a larger acid dissociation constant than the anionic moiety A1″, more preferably any one of the formulas (BB-1) to (BB-6), and still more preferably any one of the formulas (BB-1) and (BB-4).

Note that, in the formulas (AA-1) to (AA-3) and the formulas (BB-1) to (BB-6) below,*represent a bonding site.

In the formula (AA-2), R^{A} represent a monovalent organic group. The monovalent organic groups represented by R^{A} are not particularly limited, but may be, for example, a cyano group, a trifluoromethyl group, or a methanesulfonyl group.

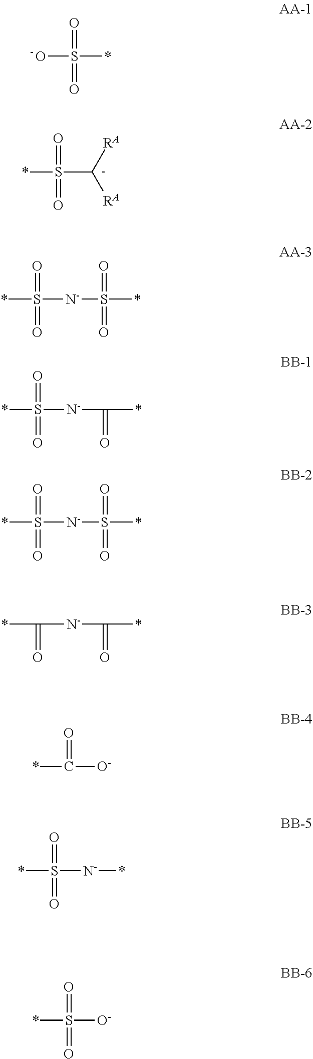

The cationic moiety M₁⁺ and the cationic moiety M₂⁺ are structural moieties including a positively charged atom or atomic group and may be, for example, singly charged organic cations. Note that such an organic cation may be, for example, the above-described organic cation represented by M⁺.

### Compound (II)

A compound (II) is a compound having two or more structural moieties X above and one or more structural moieties Z below, and is a compound that generates, upon irradiation with an actinic ray or a radiation, an acid including two or more first acidic moieties derived from the structural moieties X and the structural moiety Z.

Structural Moiety Z: A Nonionic Moiety that can Neutralize Acid

In the compound (II), the definition of the structural moiety X and the definitions of A₁⁻ and M₁⁺ are the same as the definition of the structural moiety X and the definitions of A₁⁻ and M₁⁺ in the above-described compound (I), and preferred examples are also the same.

In a compound PII in which the cationic moiety M₁⁺ in the structural moiety X in the compound (II) is replaced by H⁺, the preferred range of the acid dissociation constant al derived from the acidic moiety represented by HA₁ in which the cationic moiety M₁⁺ in the structural moiety X is replaced by H⁺ is the same as in the acid dissociation constant al in the compound PI.

Note that, when the compound (II) is, for example, a compound that generates an acid having two first acidic moieties derived from the structural moiety X and the structural moiety Z, the compound PII corresponds to a “compound having two HA₁”. In determination of the acid dissociation constants of this compound PII, the acid dissociation constant at the time when the compound PII turns into a “compound having one A” and one HA₁” and the acid dissociation constant at the time when the “compound having one A₁ and one HA₁” turns into a “compound having two A₁” correspond to the acid dissociation constant al.

The acid dissociation constant al can be determined by the above-described method of measuring an acid dissociation constant.

The compound PII corresponds to an acid generated upon irradiation of the compound (II) with an actinic ray or a radiation.

Note that the two or more structural moieties X may be the same or different. The two or more A₁⁻ and the two or more M₁⁺ may be individually the same or different.

The nonionic moiety that can neutralize acid in the structural moiety Z is not particularly limited, and is preferably, for example, a moiety including a group that can electrostatically interact with a proton or a functional group having an electron.

Examples of the group that can electrostatically interact with a proton or the functional group having an electron include a functional group having a macrocyclic structure such as cyclic polyether, and a functional group having a nitrogen atom having an unshared electron pair that does not contribute to x-conjugation. Examples of the nitrogen atom having an unshared electron pair that does not contribute to x-conjugation include nitrogen atoms having partial structures represented by the following formulas.

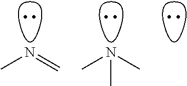

Unshared electron pair

The partial structure of the group that can electrostatically interact with a proton or the functional group having an electron may be, for example, a crown ether structure, an azacrown ether structure, a primary to tertiary amine structure, a pyridine structure, an imidazole structure, or a pyrazine structure; in particular, preferred are primary to tertiary amine structures.

The following are non-limiting specific examples of the photoacid generator (B).

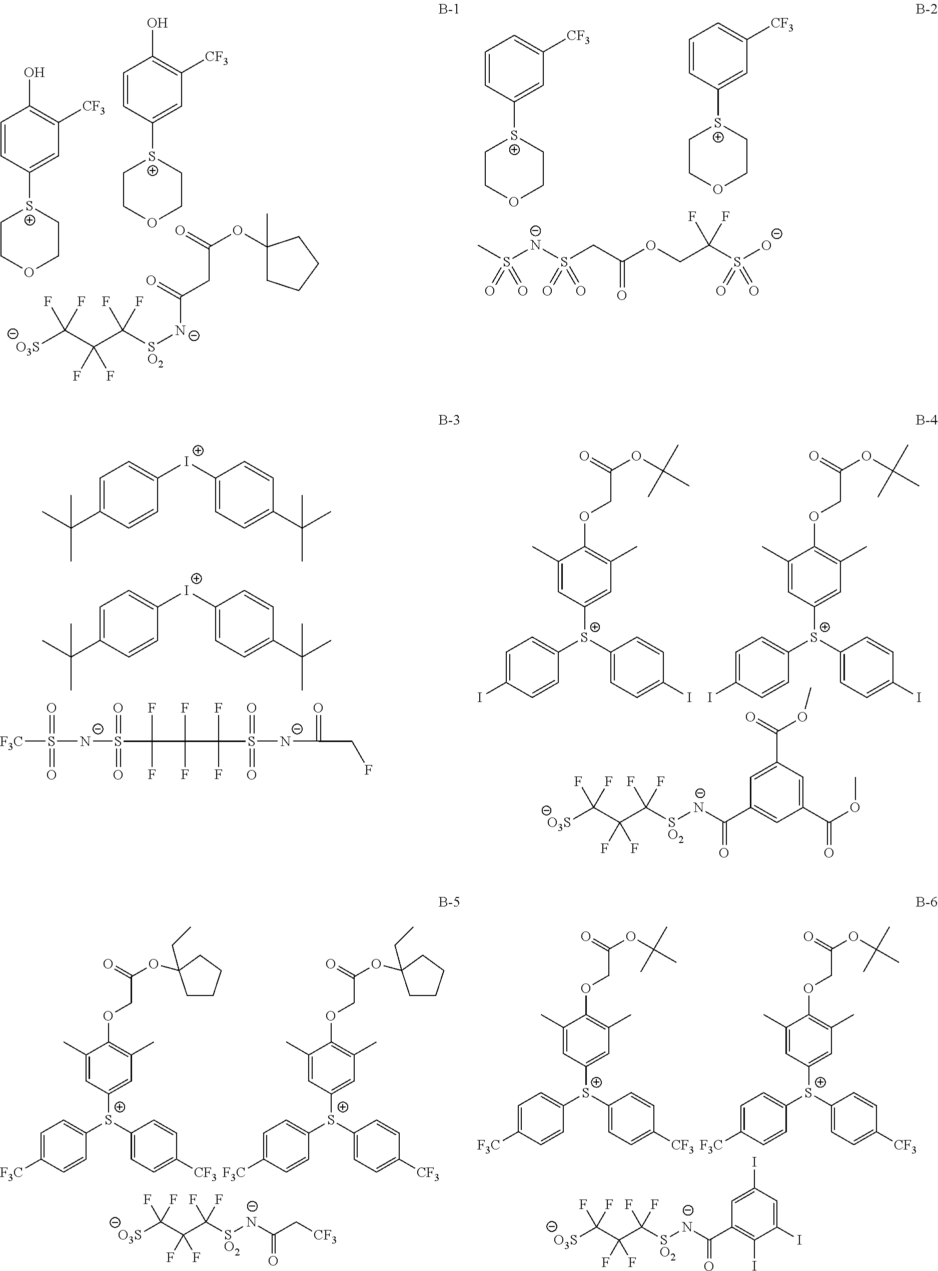

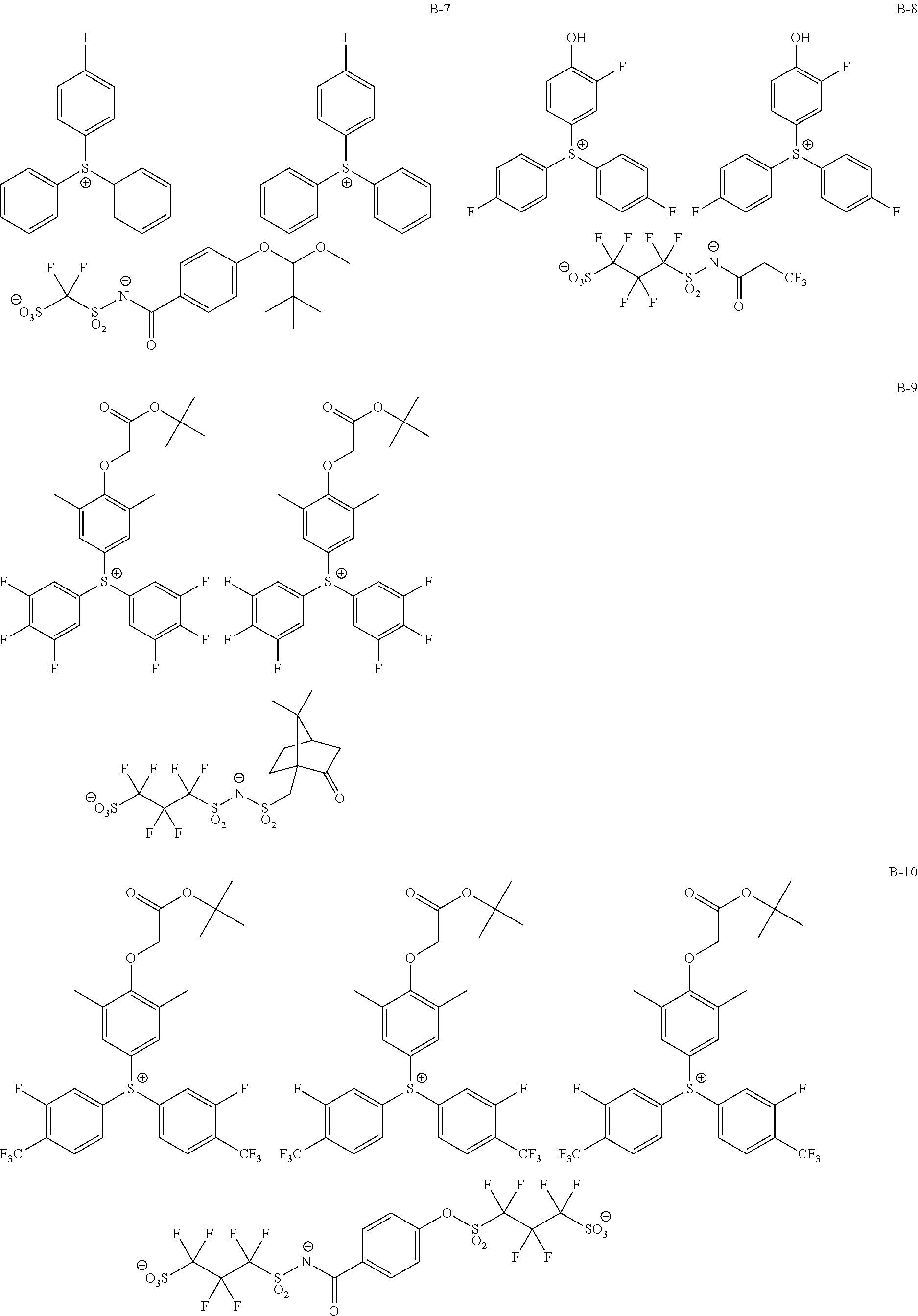

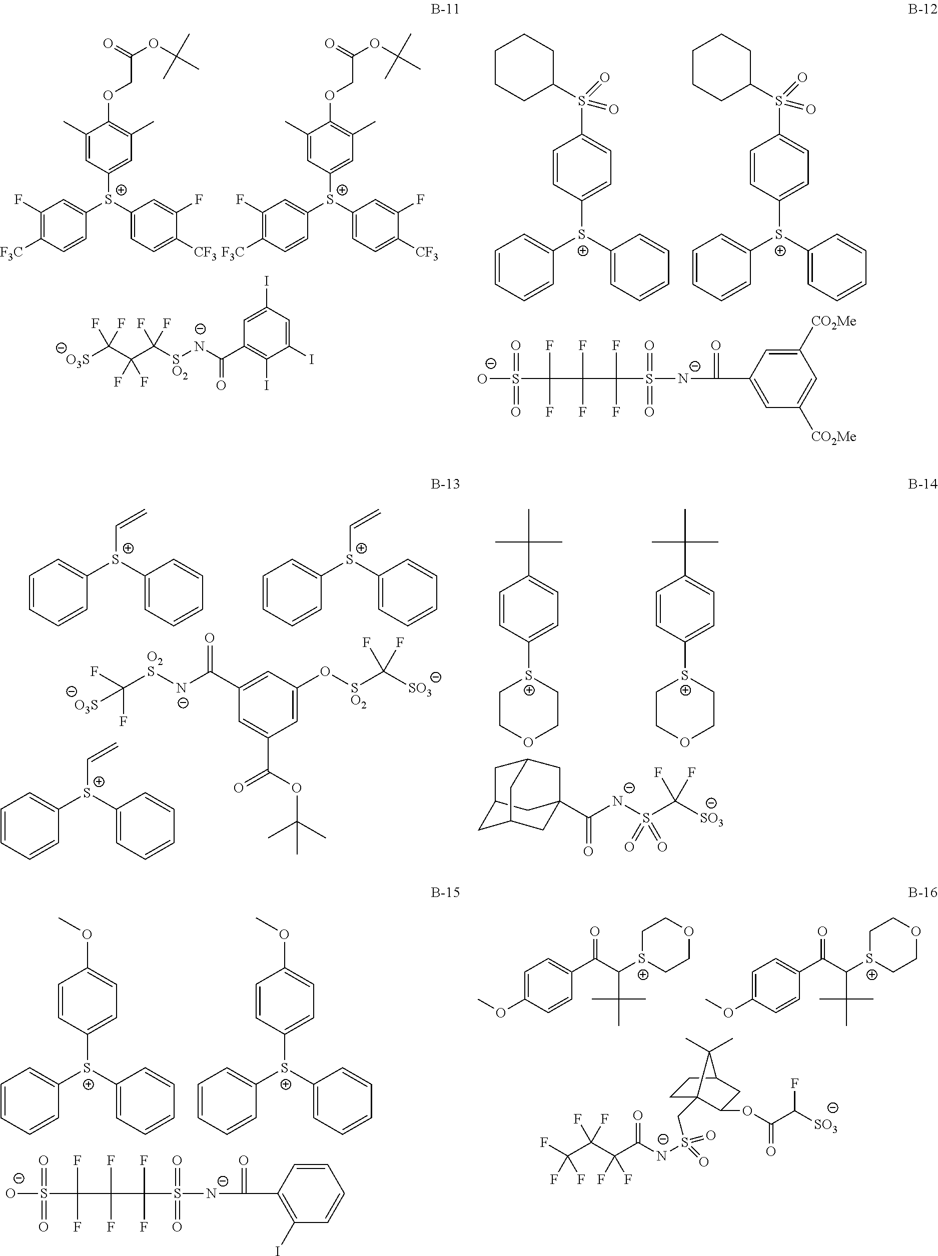

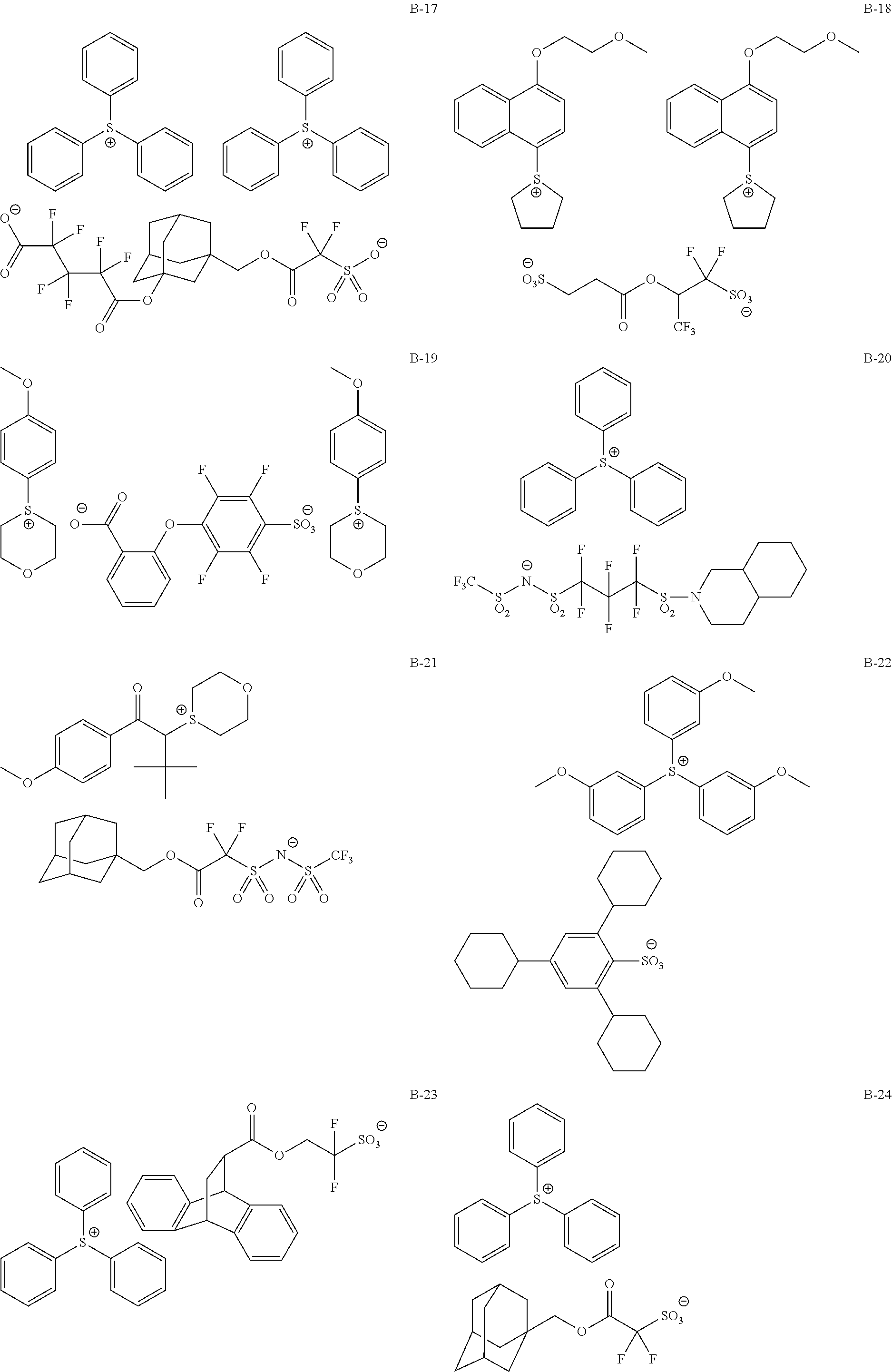

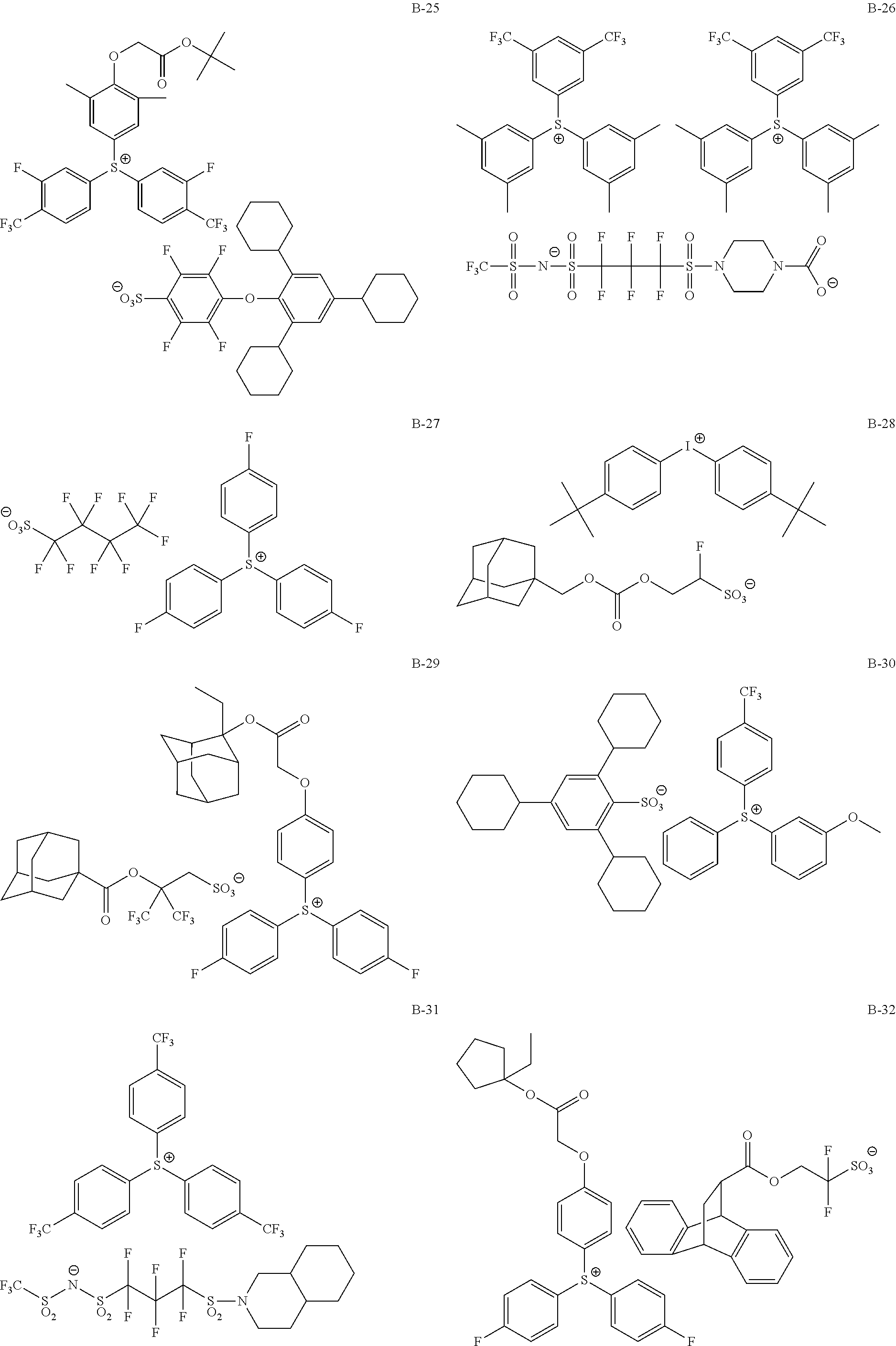

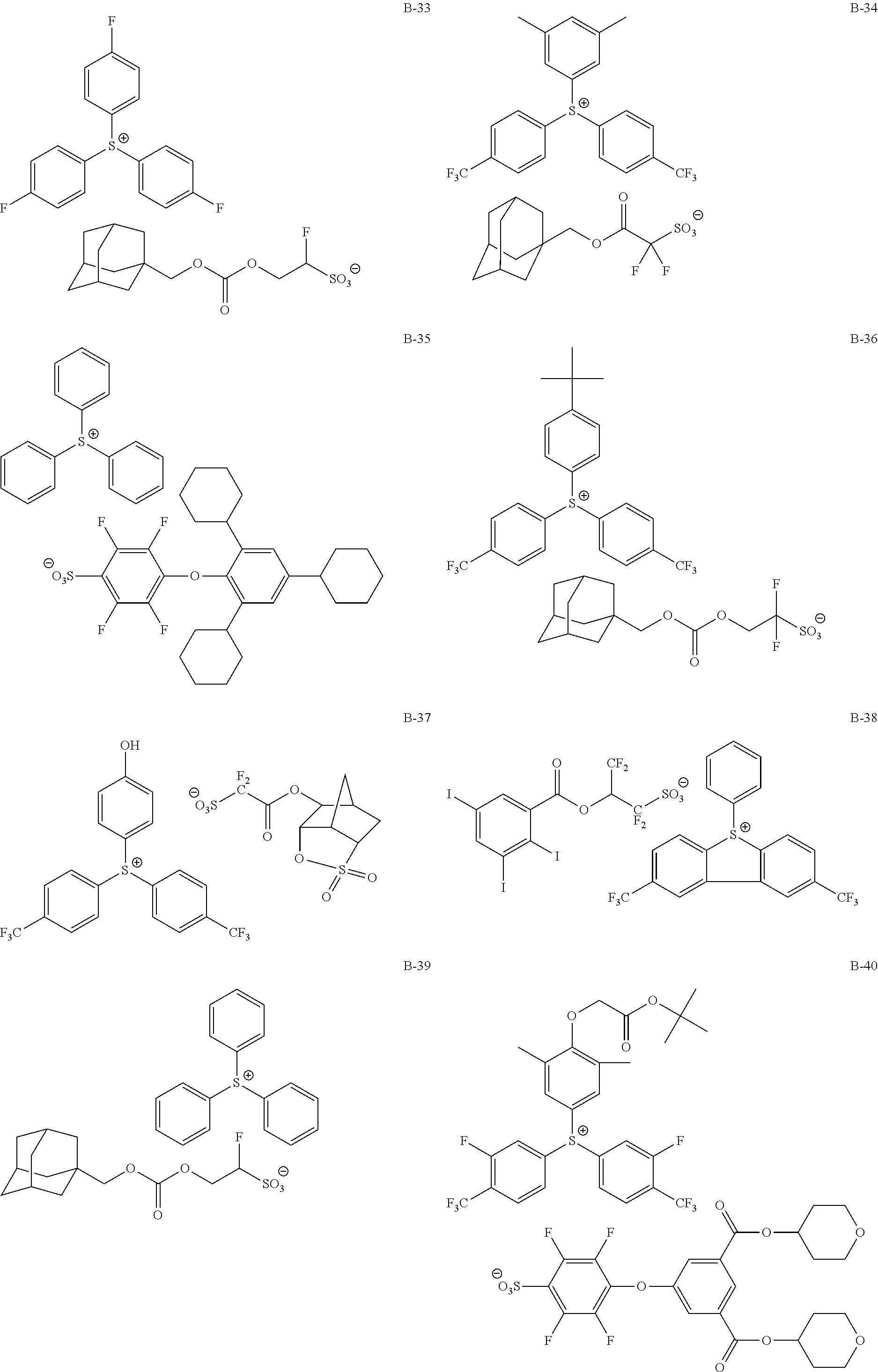

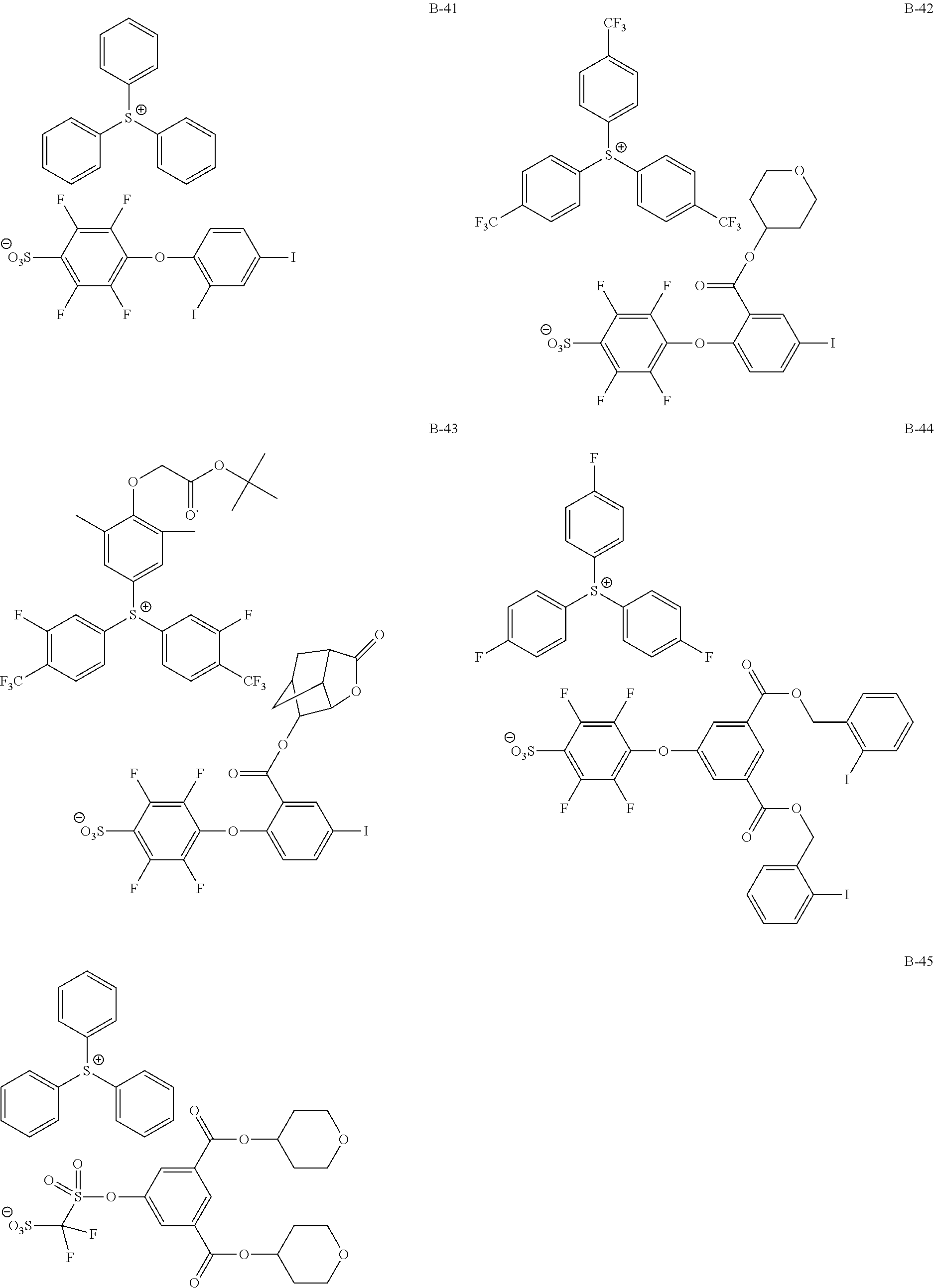

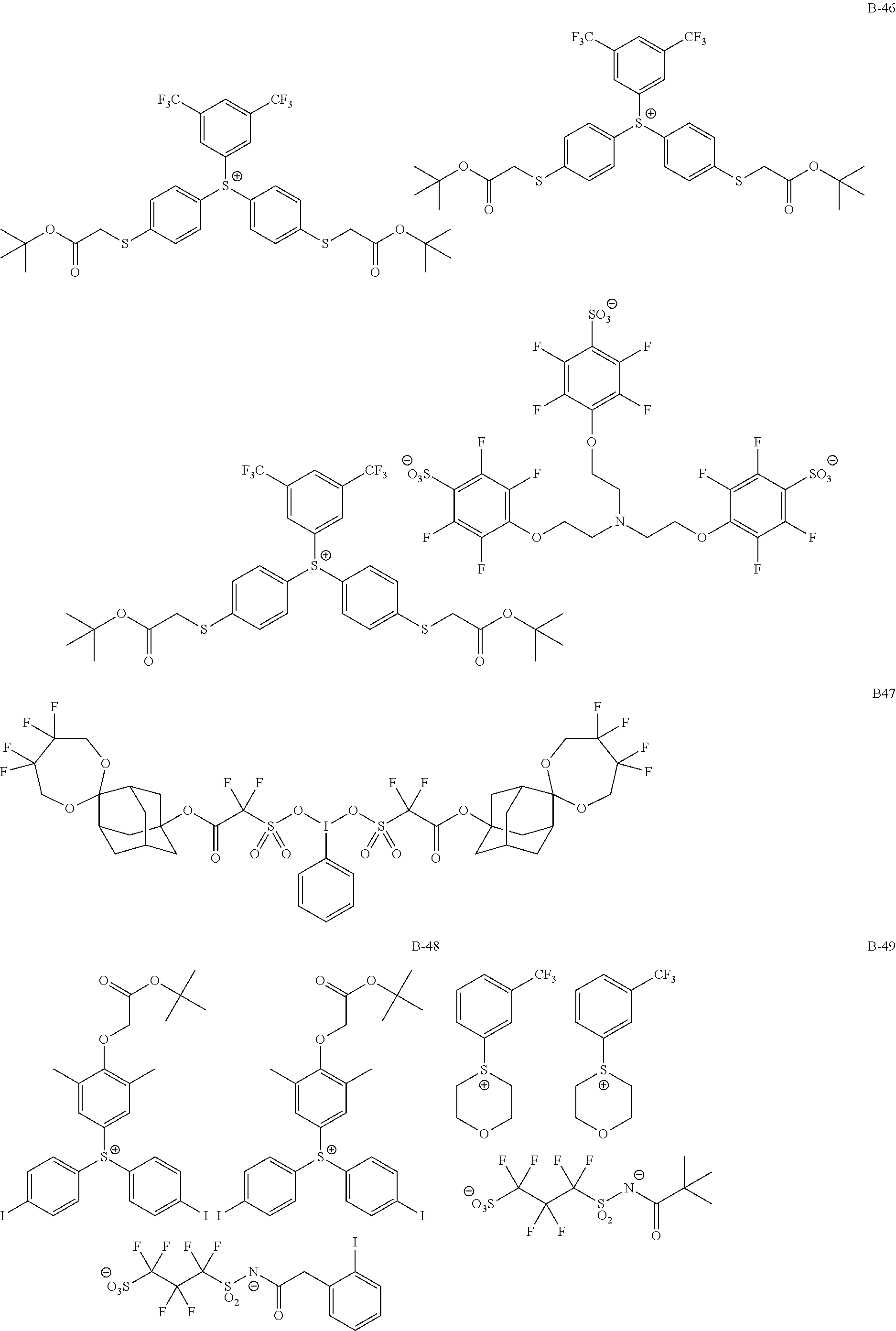

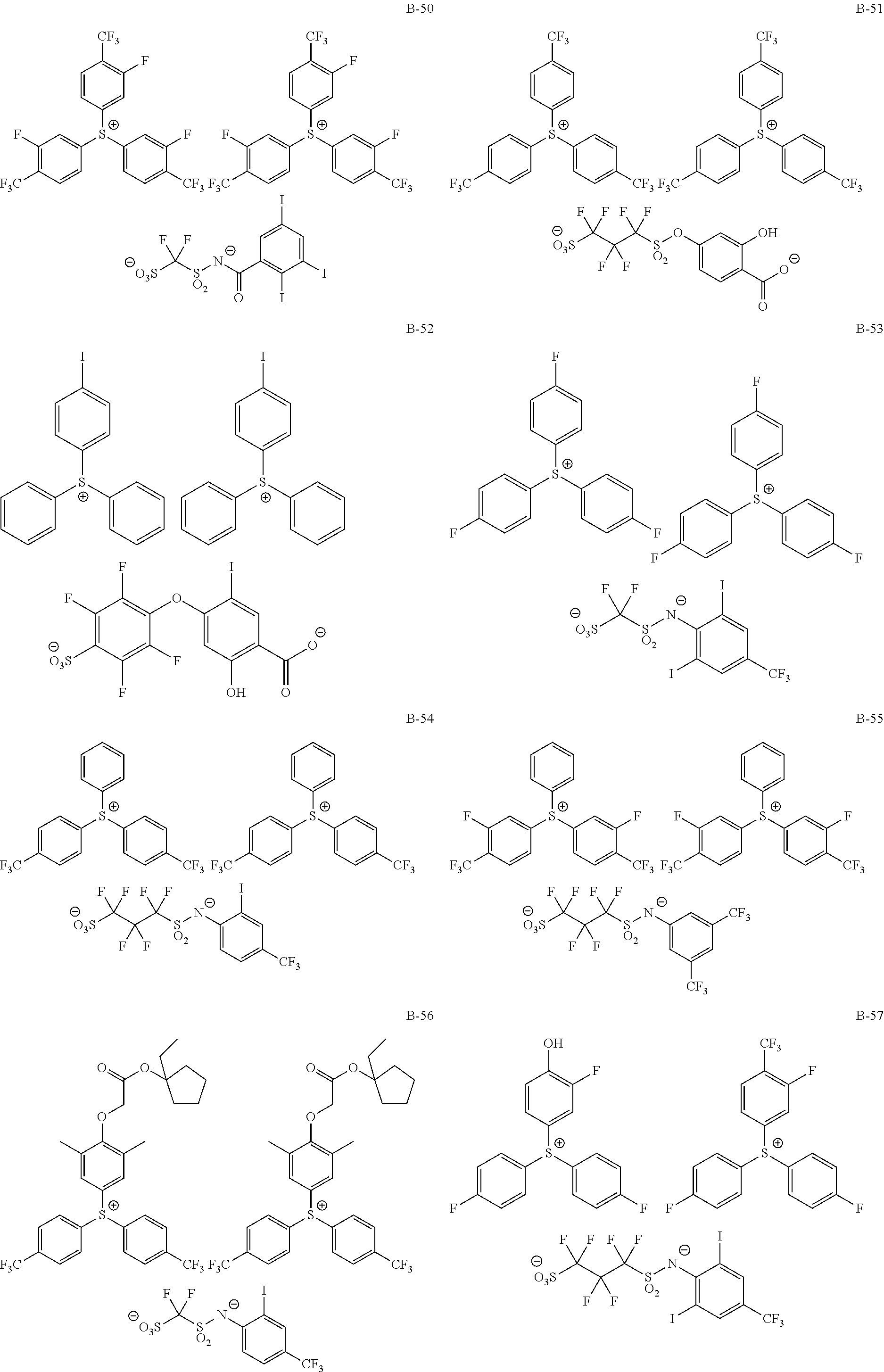

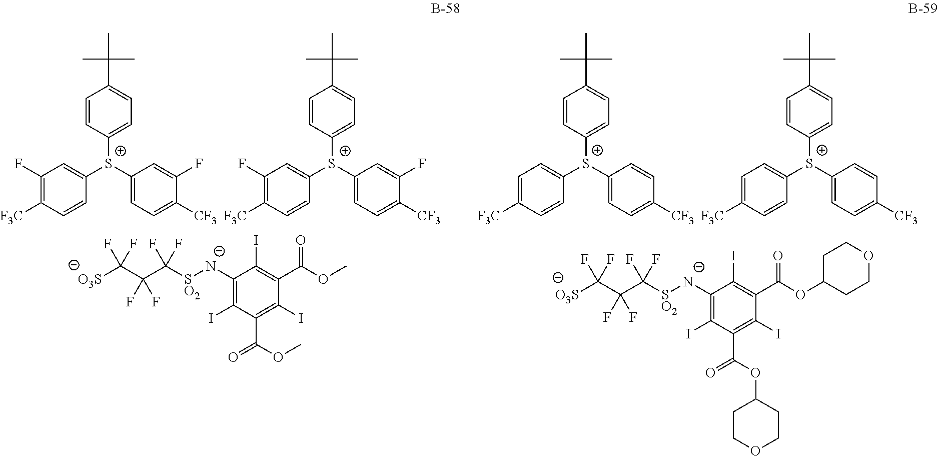

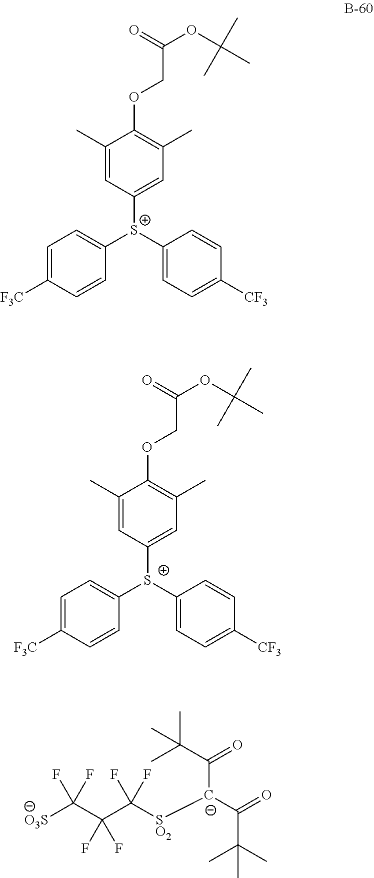

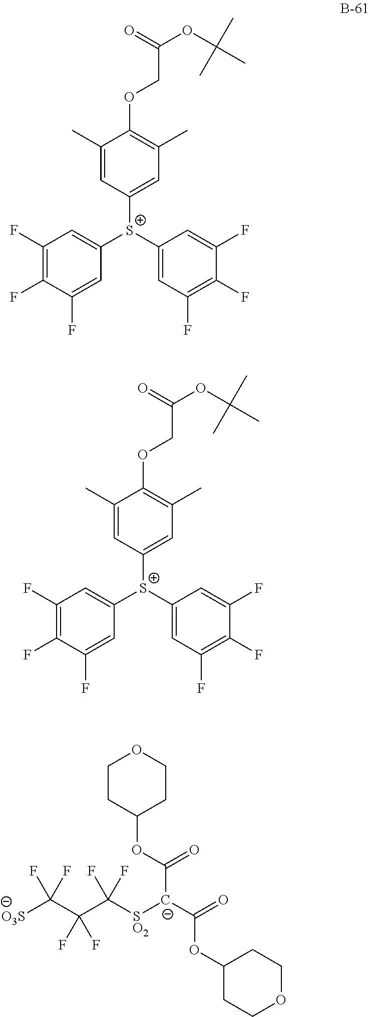

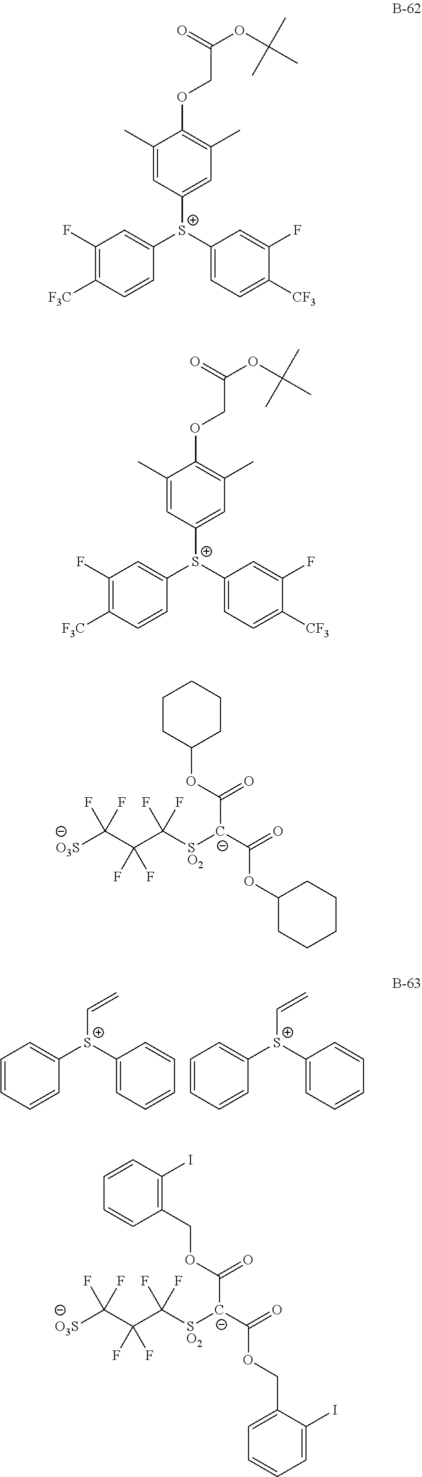

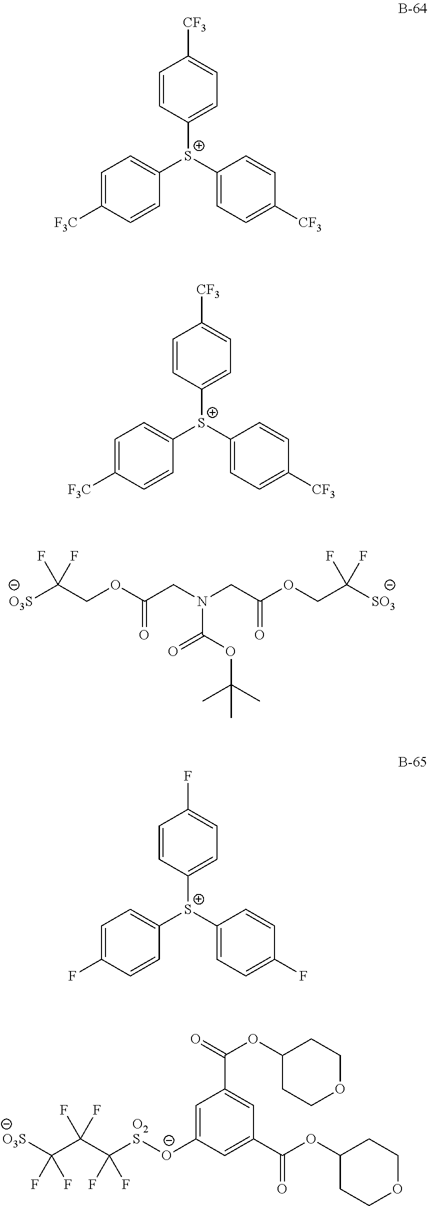

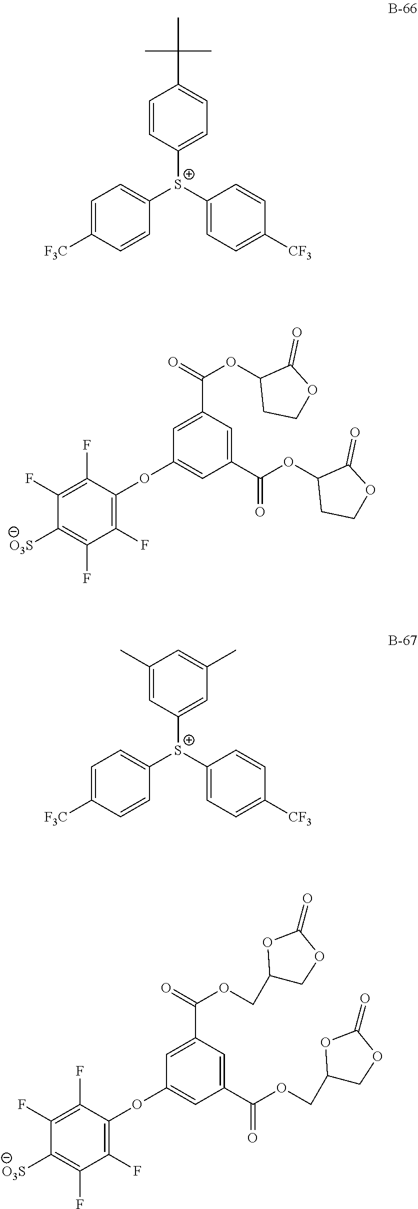

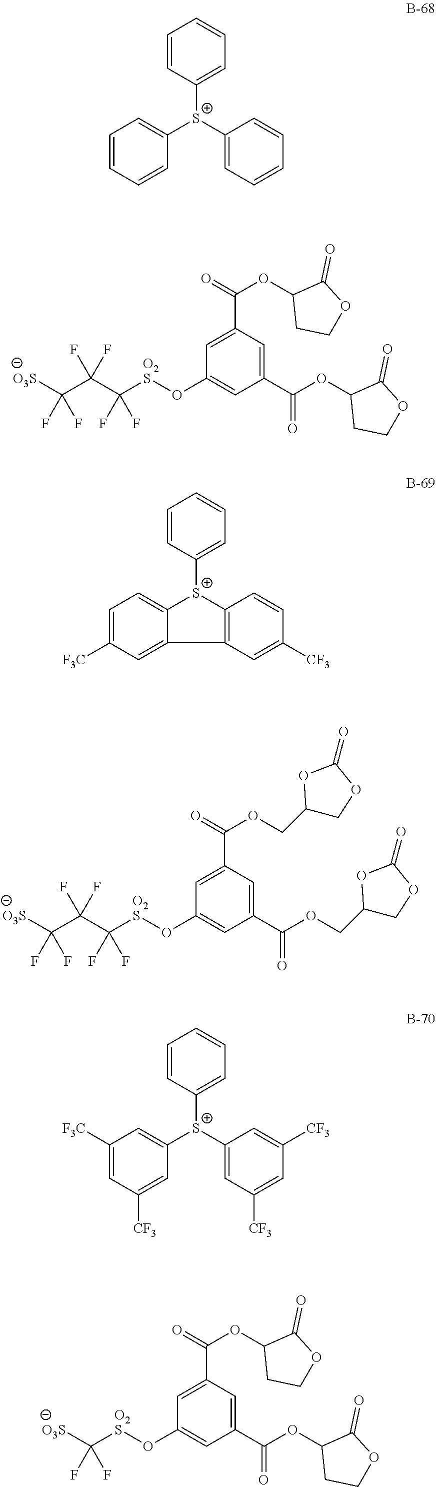

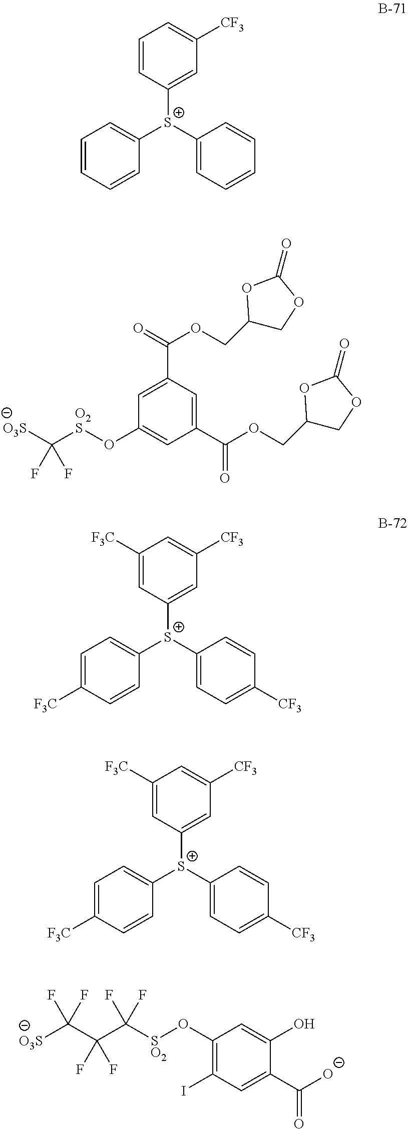

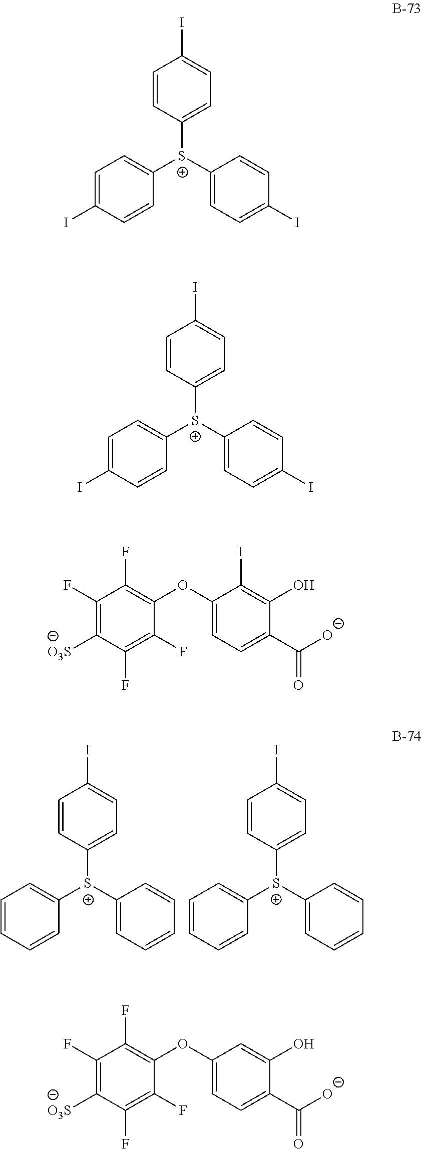

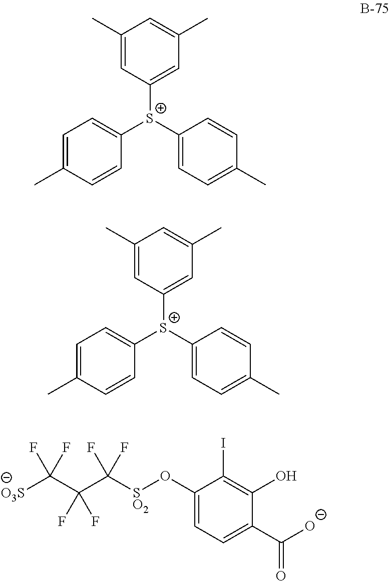

When a composition of the present invention includes the photoacid generator (B), the composition of the present invention may include one type of the photoacid generator (B) or two or more types of the photoacid generator (B).

When a composition of the present invention includes the photoacid generator (B), the content of the photoacid generator (B) is, from the viewpoint of forming a pattern having a more square profile, relative to the total solid content of the composition of the present invention, preferably 0.5 mass % or more, and more preferably 1.0 mass % or more. The content of the photoacid generator relative to the total solid content of a composition of the present invention is preferably 50.0 mass % or less, and more preferably 40 mass % or less.

### Acid Diffusion Control Agent

A composition of the present invention may contain an acid diffusion control agent (also referred to as “acid diffusion control agent (C)” or “compound (C)”).

The acid diffusion control agent may be an onium salt compound.

The acid diffusion control agent is preferably a compound different from the resin (A).

The acid diffusion control agent (C) may be the same compound as the above-described photoacid generator (B) or may be a compound different from the above-described photoacid generator (B).

The acid diffusion control agent (C) can serve as a quencher that traps the acid generated from the photoacid generator or the like upon exposure and that suppresses the reaction of the acid-decomposable resin, in the unexposed region, caused by an excess of generated acid.

The type of the acid diffusion control agent (C) is not particularly limited, and examples thereof include a basic compound (CA), a low-molecular-weight compound (CB) having a nitrogen atom and having a group that leaves by the action of an acid, and a compound (CC) whose acid diffusion control ability is reduced or lost upon irradiation with an actinic ray or a radiation.

Examples of the compound (CC) include an onium salt compound (CD) that becomes a weak acid relative to the photoacid generator, and a basic compound (CE) whose basicity is reduced or lost upon irradiation with an actinic ray or a radiation.

Specific examples of the basic compound (CA) include, for example, those described in Paragraphs to of WO2020/066824A; specific examples of the basic compound (CE) whose basicity is reduced or lost upon irradiation with an actinic ray or a radiation include those described in Paragraphs to of WO2020/066824A, and those described in Paragraph of WO2020/066824A; and, specific examples of the low-molecular-weight compound (CB) having a nitrogen atom and having a group that leaves by the action of an acid include those described in Paragraphs to of WO2020/066824A.

Specific examples of the onium salt compound (CD) that becomes a weak acid relative to the photoacid generator include, for example, those described in Paragraphs to of WO2020/158337A.

In addition to those described above, for example, the publicly known compounds disclosed in Paragraphs [0627] to [0664] in US2016/0070167A1, Paragraphs [0095] to [0187] in US2015/0004544A1, Paragraphs [0403] to [0423] in US2016/0237190A1, and Paragraphs [0259] to [0328] in US2016/0274458A₁⁻ can be suitably used as acid diffusion control agents.

Among the acid diffusion control agents, the compound (CC) is also referred to as a photodegradable quencher. The acid diffusion control agents other than the compound (CC) are also referred to as non-photodegradable quenchers.

The acid diffusion control agent (C) may be a photodegradable quencher or may be a non-photodegradable quencher. As the acid diffusion control agent (C), a photodegradable quencher and a non-photodegradable quencher may be used in combination.

When a composition of the present invention includes the acid diffusion control agent (C), the composition of the present invention may include one type of the acid diffusion control agent (C) or two or more types of the acid diffusion control agent (C).

When a composition of the present invention includes the acid diffusion control agent (C), the content of the acid diffusion control agent (C) relative to the total solid content of the composition of the present invention is preferably 0.1 to 15.0 mass %, and more preferably 1.0 to 15.0 mass %.

### Hydrophobic Resin

A composition of the present invention may further include a hydrophobic resin different from the resin (A).

The hydrophobic resin is preferably designed so as to be localized in the surface of the actinic ray-sensitive or radiation-sensitive film formed from a composition of the present invention (preferably a resist film); however, unlike surfactants, the hydrophobic resin does not necessarily need to have intramolecularly a hydrophilic group, and does not necessarily contribute to homogeneous mixing of a polar substance and a nonpolar substance.

Advantages due to addition of the hydrophobic resin may be control of static and dynamic contact angles (for water) at the surface of the resist film, and suppression of outgassing.

The hydrophobic resin, from the viewpoint of localization in the surface layer of the film, preferably has one or more species, more preferably two or more species, selected from the group consisting of a fluorine atom, a silicon atom, and a CH₃ moiety included in the side chain moiety of the resin. The hydrophobic resin preferably has a hydrocarbon group having 5 or more carbon atoms. The resin may have such a group in the main chain or, as a substituent, in a side chain.

Examples of the hydrophobic resin include the compounds described in Paragraphs to in WO2020/004306A.

Such hydrophobic resins may be used alone or in combination of two or more thereof.

When a composition of the present invention includes a hydrophobic resin, the content of the hydrophobic resin relative to the total solid content of the composition of the present invention is preferably 0.01 to 20.0 mass %, and more preferably 0.1 to 15.0 mass %.

### Surfactant

A composition of the present invention may include a surfactant. In the case of including a surfactant, a pattern having higher adhesiveness and a less number of development defects can be formed.

The surfactant is preferably a fluorine-based and/or silicone-based surfactant.

Examples of the fluorine-based and/or silicone-based surfactant include the surfactants disclosed in Paragraphs [0218] and [0219] of WO2018/193954A.

Such surfactants may be used alone or in combination of two or more thereof.

When a composition of the present invention includes a surfactant, the surfactant content relative to the total solid content of the composition of the present invention is preferably 0.0001 to 2.0 mass %, more preferably 0.0005 to 1.0 mass %, and still more preferably 0.1 to 1.0 mass %.

### Solvent

A composition of the present invention preferably includes a solvent.

The solvent preferably includes at least one of (M1) a propylene glycol monoalkyl ether carboxylate or (M2) at least one selected from the group consisting of a propylene glycol monoalkyl ether, a lactate, an acetate, an alkoxypropionate, a chain ketone, a cyclic ketone, a lactone, and an alkylene carbonate. Note that the solvent may further include a component other than the components (M1) and (M2).

Details of the component (M1) and the component (M2) are described in Paragraphs [0218] to [0226] in WO2020/004306A, and these contents are incorporated herein by reference.

When the solvent further includes a component other than the components (M1) and (M2), the content of the component other than the components (M1) and (M2) relative to the total amount of the solvent is preferably 5 to 30 mass %.

The content of the solvent in a composition of the present invention is determined such that the solid-content concentration is preferably 0.5 to 30 mass %, and more preferably 1 to 20 mass %. This further improves the coatability of the composition of the present invention.

Note that the solid content means all the components other than the solvent, and, as described above, means components that form the actinic ray-sensitive or radiation-sensitive film.

The solid-content concentration is a mass percentage of the mass of other components excluding the solvent relative to the total mass of a composition of the present invention.

The “total solid content” refers to the total mass of the components excluding the solvent from all the components of the composition of the present invention. As described above, the “solid content” is components excluding the solvent, and may be a solid or a liquid at 25° C., for example.

### Other Additives

A composition of the present invention may further include a dissolution-inhibiting compound, a dye, a plasticizer, a photosensitizer, a light absorbent, and/or a compound that promotes solubility in a developer (for example, a phenol compound having a molecular weight of 1000 or less, or an alicyclic or aliphatic compound including a carboxyl group).

The “dissolution-inhibiting compound” is a compound that is decomposed by the action of an acid to cause a decrease in the degree of solubility in organic-based developers, and has a molecular weight of 3000 or less.

A composition of the present invention is suitably used as a photosensitive composition for EUV exposure.

The EUV has a wavelength of 13.5 nm, which is a shorter wavelength than in the ArF (having a wavelength of 193 nm) light and the like, and hence provides, upon exposure at the same sensitivity, a smaller number of incident photons. Thus, “photon shot noise”, which is random variations in the number of photons, exerts a strong effect, which leads to degradation of LER and bridge defects. In order to reduce the photon shot noise, a method of increasing the exposure dose to increase the number of incident photons may be employed; however, there is a tradeoff between this method and the demand for an increase in the sensitivity. Actinic ray-sensitive or radiation-sensitive film and pattern forming method

The procedures of the pattern forming method using a composition of the present invention are not particularly limited, but preferably have the following steps:
Step 1: a step of using the actinic ray-sensitive or radiation-sensitive resin composition to form an actinic ray-sensitive or radiation-sensitive film on a substrate
Step 2: a step of exposing the actinic ray-sensitive or radiation-sensitive film
Step 3: a step of developing the exposed actinic ray-sensitive or radiation-sensitive film using a developer

Hereinafter, procedures of the steps will be individually described in detail.

### Step 1: Actinic Ray-Sensitive or Radiation-Sensitive Film Formation Step

The step 1 is a step of using the actinic ray-sensitive or radiation-sensitive resin composition to form an actinic ray-sensitive or radiation-sensitive film on a substrate.

Examples of the method of using the actinic ray-sensitive or radiation-sensitive resin composition to form an actinic ray-sensitive or radiation-sensitive film (preferably, a resist film) on a substrate include a method of applying a composition of the present invention onto a substrate.

Note that a composition of the present invention is preferably filtered through a filter before application as needed. The filter preferably has a pore size of 0.1 μm or less, more preferably 0.05 μm or less, and still more preferably 0.03 μm or less. The filter is preferably formed of polytetrafluoroethylene, polyethylene, or nylon.

A composition of the present invention can be applied onto a substrate (such as a silicon, silicon dioxide-coated substrate) used in the production of an integrated circuit element, by an appropriate application process using a spinner, a coater, or the like. The application process is preferably spin-coating using a spinner. The spin-coating using a spinner is preferably performed at a rotation rate of 1000 to 3000 rpm (rotations per minute).

After application of a composition of the present invention, the substrate may be dried to form an actinic ray-sensitive or radiation-sensitive film. Note that, as needed, as underlayers of the actinic ray-sensitive or radiation-sensitive film, various underlying films (an inorganic film, an organic film, or an antireflection film) may be formed.

The drying process may be, for example, a process of performing heating to achieve drying. The heating can be performed using means included in an ordinary exposure device and/or an ordinary development device, or may alternatively be performed using a hot plate, for example. The heating temperature is preferably 80 to 150° C., more preferably 80 to 140° C., and still more preferably 80 to 130° C. The heating time is preferably 30 to 1000 seconds, more preferably 60 to 800 seconds, and still more preferably 60 to 600 seconds.

The film thickness of the actinic ray-sensitive or radiation-sensitive film is not particularly limited, but is, from the viewpoint of enabling formation of more precise fine patterns, preferably 10 to 120 nm. In particular, in the case of employing EUV exposure, the film thickness of the actinic ray-sensitive or radiation-sensitive film is more preferably 10 to 65 nm, and still more preferably 15 to 50 nm. In the case of employing ArF liquid immersion exposure, the film thickness of the actinic ray-sensitive or radiation-sensitive film is more preferably 10 to 120 nm, and still more preferably 15 to 90 nm.

Note that, for an overlying layer of the actinic ray-sensitive or radiation-sensitive film, a topcoat composition may be used to form a topcoat.

The topcoat composition preferably does not mix with the actinic ray-sensitive or radiation-sensitive film, and can be uniformly applied for an overlying layer of the actinic ray-sensitive or radiation-sensitive film. The topcoat is not particularly limited; a publicly known topcoat can be formed by a publicly known process; for example, on the basis of descriptions of Paragraphs to in JP2014-059543A, a topcoat can be formed.

For example, a topcoat including a basic compound and described in JP2013-61648A is preferably formed on the actinic ray-sensitive or radiation-sensitive film. Specific examples of the basic compound that can be included in the topcoat include the above-described basic compounds that may be included in a composition of the present invention.

The topcoat also preferably includes a compound including at least one group or bond selected from the group consisting of an ether bond, a thioether bond, a hydroxy group, a thiol group, a carbonyl bond, and an ester bond.

### Step 2: Exposure Step

The step 2 is a step of exposing the actinic ray-sensitive or radiation-sensitive film.

The exposure process may be a process of irradiating the formed actinic ray-sensitive or radiation-sensitive film, through a predetermined mask, with an actinic ray or a radiation.

Examples of the actinic ray or the radiation include infrared light, visible light, ultraviolet light, far-ultraviolet light, extreme ultraviolet light, X-rays, and an electron beam; preferred is 250 nm or less, more preferred is 220 nm or less, and particularly preferred are far-ultraviolet light having a wavelength of 1 to 200 nm and specifically KrF excimer laser (248 nm), ArF excimer laser (193 nm), F2 excimer laser (157 nm), EUV (13.5 nm), X-rays, and an electron beam.

After the exposure, before development, baking (heating) is preferably performed. The baking accelerates the reaction in the exposed regions, to provide higher sensitivity and a better pattern profile.

The heating temperature is preferably 80 to 150° C., more preferably 80 to 140° C., and still more preferably 80 to 130° C.

The heating time is preferably 10 to 1000 seconds, more preferably 10 to 180 seconds, and still more preferably 30 to 120 seconds.

The heating can be performed using means included in an ordinary exposure device and/or an ordinary development device, and may alternatively be performed using a hot plate, for example.

This step is also referred to as post-exposure baking.

### Step 3: Development Step

The step 3 is a step of using a developer to develop the exposed actinic ray-sensitive or radiation-sensitive film, to form a pattern.

The developer may be an alkali developer or may be a developer containing an organic solvent (hereafter, also referred to as organic-based developer).

Examples of the development process include a process of immersing, for a predetermined time, the substrate in a tank filled with the developer (dipping process), a process of puddling, with the developer, the surface of the substrate using surface tension and leaving the developer at rest for a predetermined time to achieve development (puddling process), a process of spraying the developer to the surface of the substrate (spraying process), and a process of scanning, at a constant rate, over the substrate rotated at a constant rate, a developer ejection nozzle to continuously eject the developer (dynamic dispensing process).

After the step of performing development, a step of performing exchange with another solvent to stop the development may be performed.

The development time is not particularly limited as long as the resin in the unexposed regions is sufficiently dissolved in the time, and is preferably 10 to 300 seconds, and more preferably 20 to 120 seconds.

The temperature of the developer is preferably 0 to 50° C., and more preferably 15 to 35° C.

The alkali developer employed is preferably an alkali aqueous solution including an alkali. The type of the alkali aqueous solution is not particularly limited, but may be, for example, an alkali aqueous solution including a quaternary ammonium salt represented by tetramethylammonium hydroxide, an inorganic alkali, a primary amine, a secondary amine, a tertiary amine, an alcoholamine, a cyclic amine, or the like. In particular, the alkali developer is preferably an aqueous solution of a quaternary ammonium salt represented by tetramethylammonium hydroxide (TMAH). To the alkali developer, an appropriate amount of an alcohol, a surfactant, or the like may be added. The alkali developer ordinarily preferably has an alkali concentration of 0.1 to 20 mass %. The alkali developer ordinarily preferably has a pH of 10.0 to 15.0.

The organic-based developer is preferably a developer containing at least one organic solvent selected from the group consisting of ketone-based solvents, ester-based solvents, alcohol-based solvents, amide-based solvents, ether-based solvents, and hydrocarbon-based solvents.

A plurality of such solvents may be mixed together, or such a solvent may be mixed with a solvent other than those described above or water. The developer as a whole has a moisture content of preferably less than 50 mass %, more preferably less than 20 mass %, still more preferably less than 10 mass %, and particularly preferably contains substantially no moisture.

In the organic-based developer, the content of the organic solvent relative to the total amount of the developer is preferably 50 mass % or more and 100 mass % or less, more preferably 80 mass % or more and 100 mass % or less, still more preferably 90 mass % or more and 100 mass % or less, and particularly preferably 95 mass % or more and 100 mass % or less.

### Other Step

The pattern forming method preferably includes a step of, after the step 3, using a rinse liquid to perform rinsing.

After the development step using an alkali developer, in the rinsing step, the rinse liquid employed may be, for example, pure water. Note that, to the pure water, an appropriate amount of surfactant may be added.

To the rinse liquid, an appropriate amount of surfactant may be added.

After the development step using an organic-based developer, in the rinsing step, the rinse liquid employed is not particularly limited as long as it does not dissolve the pattern, and may be a solution including an ordinary organic solvent. The rinse liquid employed is preferably a rinse liquid containing at least one organic solvent selected from the group consisting of hydrocarbon-based solvents, ketone-based solvents, ester-based solvents, alcohol-based solvents, amide-based solvents, and ether-based solvents.

The process of performing the rinsing step is not particularly limited; examples include a process of continuously ejecting, onto the substrate rotated at a constant rate, the rinse liquid (spin-coating process), a process of immersing, in a tank filled with the rinse liquid, the substrate for a predetermined time (dipping process), and a process of spraying, to the surface of the substrate, the rinse liquid (spraying process).

The pattern forming method may include a heating step (Post Bake) performed after the rinsing step. In this step, baking removes the developer and the rinse liquid remaining between and within the patterns. In addition, this step also provides an effect of annealing the resist pattern to address the rough surface of the pattern. The heating step after the rinsing step is performed ordinarily at 40 to 250° C. (preferably 90 to 200° C.) for ordinarily 10 seconds to 3 minutes (preferably 30 seconds to 120 seconds).

The formed pattern may be used as a mask for subjecting the substrate to etching treatment. Specifically, the pattern formed in the step 3 may be used as a mask for processing the substrate (or the underlayer film and the substrate), to form a pattern in the substrate.

The process of processing the substrate (or the underlayer film and the substrate) is not particularly limited, but is preferably a process of using the pattern formed in the step 3 as a mask for subjecting the substrate (or the underlayer film and the substrate) to dry etching, to thereby form a pattern in the substrate. The dry etching is preferably oxygen plasma etching.

Various materials used in the composition of this Specification and the pattern forming method of this Specification (for example, a solvent, a developer, a rinse liquid, an antireflection film-forming composition, and a topcoat-forming composition) preferably do not include impurities such as metals. The content of impurities included in such materials is preferably 1 mass ppm (parts per million) or less, more preferably 10 mass ppb (parts per billion) or less, still more preferably 100 mass ppt (parts per trillion) or less, particularly preferably 10 mass ppt or less, and most preferably 1 mass ppt or less. The lower limit is not particularly limited, but is preferably 0 mass ppt or more. Examples of the metallic impurities include Na, K, Ca, Fe, Cu, Mg, Al, Li, Cr, Ni, Sn, Ag, As, Au, Ba, Cd, Co, Pb, Ti, V, W, and Zn.

The process of removing, from the various materials, impurities such as metals may be, for example, filtration using a filter. The details of filtration using a filter are described in Paragraph in WO2020/004306A.

Examples of the process of reducing the amount of impurities such as metals included in the various materials include a process of selecting, as raw materials constituting the various materials, raw materials having lower metal content, a process of subjecting raw materials constituting the various materials to filtration using a filter, and a process of performing distillation under conditions under which contamination is minimized by, for example, lining the interior of the apparatuses with TEFLON (registered trademark).

Instead of the filtration using a filter, an adsorption material may be used to remove impurities; alternatively, the filtration using a filter may be used in combination with an adsorption material. Such adsorption materials can be publicly known adsorption materials, and examples include inorganic-based adsorption materials such as silica gel and zeolite, and organic-based adsorption materials such as active carbon. In order to reduce the amount of impurities such as metals included in the various materials, ingress of metallic impurities in the production steps needs to be prevented. Whether or not metallic impurities are sufficiently removed from the production apparatuses can be determined by measuring the content of metallic components included in the washing liquid having been used for washing the production apparatuses. The content of metallic components included in the washing liquid having been used is preferably 100 mass ppt or less, more preferably 10 mass ppt or less, and still more preferably 1 mass ppt or less. The lower limit is not particularly limited, but is preferably 0 mass ppt or more.

To organic-based treatment liquids such as the rinse liquid, in order to prevent electrostatic buildup and the subsequent electrostatic discharge causing failure of the chemical solution pipe and various parts (such as a filter, an O-ring, and a tube), a conductive compound may be added. The conductive compound is not particularly limited, but may be, for example, methanol. The amount of addition is not particularly limited, but is, from the viewpoint of maintaining preferred development performance or rinsing performance, preferably 10 mass % or less, and more preferably 5 mass % or less. The lower limit is not particularly limited, but is preferably 0.01 mass % or more.

Examples of the chemical solution pipe include various pipes formed of SUS (stainless steel), or coated with polyethylene, polypropylene, or a fluororesin (such as polytetrafluoroethylene or a perfluoroalkoxy resin) treated so as to be antistatic. Similarly for the filter and the O-ring, polyethylene, polypropylene, or a fluororesin (such as polytetrafluoroethylene or a perfluoroalkoxy resin) treated so as to be antistatic can be used.

### Method for Producing Electronic Device

This Specification also relates to a method for producing an electronic device, the method including the above-described pattern forming method, and an electronic device produced by the production method.

The electronic device in this Specification is, in a preferred embodiment, mounted on electric or electronic devices (such as household appliances, OA (Office Automation), media-related devices, optical devices, and communication devices).

### EXAMPLES

Hereinafter, the present invention will be described further in detail with reference to Examples. In the following Examples, materials, usage amounts, ratios, details of treatments, orders of treatments, and the like can be appropriately changed without departing from the spirit and scope of the present invention. Thus, the scope of the present invention should not be construed as being limited to the following Examples.

### Components of Resist Compositions

The components included in resist compositions used in Examples and Comparative Examples will be described below.

### Resin (A)

The resins A-1 to A-71 (acid-decomposable resins) used in the preparation of the resist compositions will be described in Tables 1 to 3 below.

As the resin A-1, a resin synthesized by a synthesis method (Synthesis Example 1) described later was used.

As the resins A-2 to A-4, resins synthesized by synthesis methods (Synthesis Examples 2 to 4) described below were used.

As the other resins (A), resins synthesized in accordance with Synthesis Example 1 were used. Note that, as the resins (A) including a part of repeating units having a phenolic hydroxy group (M-b-2 to M-b-7, M-b-12 to M-b-15, and M-b-17), resins synthesized in accordance with the synthesis methods (Synthesis Examples 2 to 4) of the resins A-2 to A-4 using a precursor in which a phenolic hydroxy group was protected were used. As the precursors of M-b-3 to M-b-7, M-b-12 to M-b-15, and M-b-17, M-b-3-i to M-b-7-i, M-b-12-i to M-b-15-i, and M-b-17-i were used. As the precursor of M-b-2, M-b-2-i or M-b-2-ii was used.

In addition, resins A-1R to A-8R (acid-decomposable resins) used in the preparation of resist compositions of Comparative Examples will also be described in Table 3 below. Resins A-1R to A-8R, which are not the resins (A), are described for convenience in the column of Resin (A) in Table 7 below.

In Tables 1 to 3, the molar ratio of each repeating unit represents the content (mol %) of the repeating unit relative to all the repeating units. Each repeating unit is described using the structure of a monomer corresponding to the repeating unit.

In Tables 1 to 3, the column “Mw” describes weight-average molecular weight.

In Tables 1 to 3, the column “Mw/Mn” describes molecular-weight dispersity.

The weight-average molecular weight (Mw) and the molecular-weight dispersity (Mw/Mn) of the resins were measured by GPC (carrier: tetrahydrofuran (THF))(polystyrene-equivalent amounts). The compositional ratios (molar ratios) of the resins were measured by ¹³C-NMR (Nuclear Magnetic Resonance).

In Tables 1 to 3, the column of “Total molar ratio of acid-decomposable group (mol %)” describes the content of the repeating unit having an acid-decomposable group (the total content of the repeating unit (i) and the repeating unit (iv)) in each resin.

TABLE 1

| | Repeating unit 1 | | Repeating unit 2 | | Repeating unit 3 | | Repeating unit 4 | | Repeating unit 5 | |
|---|---|---|---|---|---|---|---|---|---|---|
| | | Molar ratio | | Molar ratio | | Molar ratio | | Molar ratio | | Molar ratio |
| | Type | (mol %) | Type | (mol %) | Type | (mol %) | Type | (mol %) | Type | (mol %) |
| A-1 | M-1 | 30 | M-a-1 | 25 | M-b-1 | 15 | M-c-1 | 30 | — | — |
| A-2 | M-1 | 18 | M-a-1 | 13 | M-b-2 | 40 | M-c-1 | 29 | — | — |
| A-3 | M-1 | 18 | M-a-1 | 9 | M-b-2 | 45 | M-c-3 | 28 | — | — |
| A-4 | M-1 | 20 | M-a-1 | 35 | M-b-6 | 15 | M-c-2 | 30 | — | — |
| A-5 | M-2 | 10 | M-a-1 | 21 | M-b-3 | 30 | M-c-4 | 29 | — | — |
| A-6 | M-3 | 20 | M-a-2 | 10 | M-b-4 | 35 | M-c-5 | 25 | — | — |
| A-7 | M-4 | 15 | M-a-2 | 15 | M-b-5 | 30 | M-c-6 | 30 | — | — |
| A-8 | M-5 | 20 | M-a-2 | 15 | M-b-6 | 30 | M-c-7 | 20 | — | — |
| A-9 | M-6 | 25 | M-a-2 | 20 | M-b-7 | 28 | M-c-8 | 15 | — | — |
| A-10 | M-7 | 30 | M-a-2 | 25 | M-b-8 | 23 | M-c-9 | 10 | — | — |
| A-11 | M-8 | 25 | M-a-2 | 30 | M-b-9 | 23 | M-c-10 | 10 | — | — |
| A-12 | M-9 | 25 | M-a-3 | 35 | M-b-10 | 13 | M-c-11 | 12 | — | — |
| A-13 | M-10 | 30 | M-a-3 | 20 | M-b-11 | 32 | M-c-12 | 8 | — | — |
| A-14 | M-11 | 40 | M-a-3 | 15 | M-b-12 | 20 | M-c-13 | 15 | — | — |
| A-15 | M-12 | 10 | M-a-3 | 10 | M-b-13 | 45 | M-c-14 | 25 | — | — |
| A-16 | M-13 | 15 | M-a-3 | 40 | M-b-14 | 10 | M-c-15 | 30 | — | — |
| A-17 | M-1 | 20 | M-a-1 | 10 | M-b-15 | 45 | M-c-16 | 20 | — | — |
| A-18 | M-1 | 45 | M-a-1 | 15 | M-b-16 | 20 | M-c-17 | 10 | — | — |
| A-19 | M-1 | 25 | M-a-1 | 15 | M-b-17 | 30 | M-c-18 | 20 | — | — |
| A-20 | M-1 | 20 | M-a-1 | 15 | M-b-1 | 30 | M-c-19 | 25 | — | — |
| A-21 | M-2 | 10 | M-a-1 | 20 | M-b-2 | 30 | M-c-20 | 30 | — | — |
| A-22 | M-3 | 20 | M-a-2 | 45 | M-b-3 | 14 | M-c-21 | 16 | — | — |
| A-23 | M-4 | 15 | M-a-2 | 5 | M-b-4 | 36 | M-c-22 | 39 | — | — |
| A-24 | M-5 | 20 | M-a-2 | 5 | M-b-5 | 50 | M-c-23 | 20 | — | — |
| A-25 | M-6 | 25 | M-a-2 | 5 | M-b-6 | 54 | M-c-24 | 11 | — | — |
| A-26 | M-7 | 30 | M-a-2 | 50 | M-b-7 | 9 | M-c-25 | 6 | — | — |

| | Repeating unit 6 | | Repeating unit 7 | | | | Total molar ratio of |
|---|---|---|---|---|---|---|---|
| | | Molar ratio | | Molar ratio | | | acid-decomposable group |
| | Type | (mol %) | Type | (mol %) | Mw | Mw/Mn | (mol %) |
| A-1 | — | — | — | — | 6500 | 1.60 | 60 |
| A-2 | — | — | — | — | 7200 | 1.59 | 47 |
| A-3 | — | — | — | — | 7000 | 1.58 | 46 |
| A-4 | — | — | — | — | 7500 | 1.55 | 50 |
| A-5 | M-d-1 | 10 | — | — | 8500 | 1.59 | 39 |
| A-6 | M-d-2 | 10 | — | — | 5500 | 1.68 | 45 |
| A-7 | M-d-3 | 10 | — | — | 4500 | 1.77 | 45 |
| A-8 | M-d-4 | 15 | — | — | 12000 | 1.84 | 40 |
| A-9 | M-d-5 | 12 | — | — | 14000 | 1.65 | 40 |
| A-10 | M-d-6 | 12 | — | — | 8800 | 1.55 | 40 |
| A-11 | M-d-7 | 12 | — | — | 22000 | 1.56 | 35 |
| A-12 | M-d-8 | 15 | — | — | 14000 | 1.65 | 37 |
| A-13 | M-d-9 | 10 | — | — | 6500 | 1.40 | 38 |
| A-14 | M-d-10 | 10 | — | — | 6700 | 1.50 | 55 |
| A-15 | M-d-11 | 10 | — | — | 7200 | 1.54 | 35 |
| A-16 | M-d-12 | 5 | — | — | 8000 | 1.29 | 45 |
| A-17 | M-d-13 | 5 | — | — | 4500 | 1.35 | 40 |
| A-18 | M-d-14 | 10 | — | — | 5000 | 1.25 | 55 |
| A-19 | M-d-15 | 10 | — | — | 5500 | 1.50 | 45 |
| A-20 | M-d-16 | 10 | — | — | 5600 | 1.60 | 45 |
| A-21 | M-d-17 | 10 | — | — | 7800 | 1.56 | 40 |
| A-22 | M-d-18 | 5 | — | — | 9000 | 1.54 | 36 |
| A-23 | M-d-19 | 5 | — | — | 8000 | 1.74 | 54 |
| A-24 | M-d-20 | 5 | — | — | 7500 | 1.55 | 40 |
| A-25 | M-d-21 | 5 | — | — | 8600 | 1.72 | 36 |
| A-26 | M-d-22 | 5 | — | — | 12500 | 1.80 | 36 |

TABLE 2

| | Repeating unit 1 | | Repeating unit 2 | | Repeating unit 3 | | Repeating unit 4 | | Repeating unit 5 | |
|---|---|---|---|---|---|---|---|---|---|---|
| | | Molar ratio | | Molar ratio | | Molar ratio | | Molar ratio | | Molar ratio |
| | Type | (mol %) | Type | (mo1%) | Type | (mo1%) | Type | (mo1%) | Type | (mol %) |
| A-27 | M-8 | 20 | M-a-2 | 10 | M-b-8 | 45 | M-c-26 | 20 | — | — |
| A-28 | M-9 | 25 | M-a-3 | 20 | M-b-9 | 20 | M-c-27 | 20 | M-c-1 | 10 |
| A-29 | M-10 | 30 | M-a-3 | 15 | M-b-10 | 30 | M-c-28 | 15 | M-c-2 | 5 |
| A-30 | M-11 | 40 | M-a-3 | 15 | M-b-11 | 25 | M-c-29 | 5 | M-c-3 | 10 |
| A-31 | M-12 | 10 | M-a-3 | 50 | M-b-12 | 5 | M-c-30 | 10 | M-c-4 | 20 |
| A-32 | M-13 | 15 | M-a-3 | 12 | M-b-1 | 38 | M-c-31 | 10 | M-c-5 | 20 |
| A-33 | M-1 | 20 | M-a-1 | 18 | M-b-2 | 32 | M-c-32 | 10 | M-c-6 | 20 |
| A-34 | M-2 | 45 | M-a-1 | 17 | M-b-3 | 18 | M-c-33 | 20 | — | — |
| A-35 | M-4 | 25 | M-a-1 | 16 | M-b-5 | 39 | M-c-34 | 10 | M-c-8 | 10 |
| A-36 | M-5 | 20 | M-a-1 | 15 | M-b-6 | 45 | M-c-35 | 10 | M-c-9 | 10 |
| A-37 | M-1 | 22 | M-a-1 | 14 | M-b-9 | 44 | M-c-36 | 10 | M-c-10 | 10 |
| A-38 | M-2 | 55 | M-a-1 | 10 | M-b-3 | 20 | M-c-9 | 10 | M-c-10 | 5 |
| A-39 | M-4 | 57 | M-a-1 | 8 | M-b-3 | 15 | M-c-9 | 15 | M-c-10 | 5 |
| A-40 | M-5 | 44 | M-a-1 | 12 | M-b-3 | 25 | M-c-9 | 10 | M-c-10 | 9 |
| A-41 | M-1 | 44 | M-a-1 | 15 | M-b-3 | 20 | M-c-9 | 10 | M-c-11 | 11 |
| A-42 | M-2 | 42 | M-a-1 | 20 | M-b-3 | 15 | M-c-9 | 15 | M-c-11 | 8 |
| A-43 | M-4 | 24 | M-a-1 | 15 | M-b-3 | 30 | M-c-9 | 25 | M-c-11 | 6 |
| A-44 | M-5 | 40 | M-a-1 | 10 | M-b-3 | 15 | M-c-9 | 30 | M-c-11 | 5 |
| A-45 | M-1 | 35 | M-a-1 | 10 | M-b-3 | 20 | M-c-9 | 25 | M-c-27 | 10 |
| A-46 | M-2 | 17 | M-a-1 | 25 | M-b-3 | 18 | M-c-9 | 35 | M-c-27 | 5 |
| A-47 | M-4 | 40 | M-a-1 | 10 | M-b-3 | 22 | M-c-9 | 16 | M-c-27 | 12 |
| A-48 | M-5 | 10 | M-a-1 | 15 | M-b-3 | 18 | M-c-9 | 15 | M-c-27 | 12 |
| A-49 | M-1 | 44 | M-a-1 | 16 | M-b-2 | 40 | — | — | — | — |
| A-50 | M-1 | 19 | M-a-1 | 13 | M-b-2 | 42 | M-c-1 | 20 | M-c-10 | 6 |
| A-51 | M-1 | 16 | M-a-1 | 14 | M-b-2 | 45 | M-c-3 | 25 | — | — |
| A-52 | M-1 | 20 | M-a-1 | 10 | M-b-2 | 40 | M-c-1 | 30 | — | — |

| | Repeating unit 6 | | Repeating unit 7 | | | | Total molar ratio of |
|---|---|---|---|---|---|---|---|
| | | Molar ratio | | Molar ratio | | | acid-decomposable group |
| | Type | (mol %) | Type | (mol %) | Mw | Mw/Mn | (mol %) |
| A-27 | M-d-23 | 5 | — | — | 5500 | 1.33 | 40 |
| A-28 | M-d-24 | 5 | — | — | 4500 | 1.40 | 55 |
| A-29 | M-d-25 | 5 | — | — | 6500 | 1.55 | 50 |
| A-30 | M-d-26 | 5 | — | — | 6000 | 1.65 | 55 |
| A-31 | M-d-27 | 5 | — | — | 5900 | 1.56 | 40 |
| A-32 | M-d-28 | 5 | — | — | 8900 | 1.55 | 45 |
| A-33 | — | — | — | — | 12000 | 1.65 | 50 |
| A-34 | — | — | — | — | 8000 | 1.55 | 65 |
| A-35 | — | — | — | — | 14000 | 1.56 | 45 |
| A-36 | — | — | — | — | 12000 | 1.65 | 40 |
| A-37 | — | — | — | — | 8000 | 1.40 | 42 |
| A-38 | — | — | — | — | 6500 | 1.54 | 70 |
| A-39 | — | — | — | — | 5500 | 1.29 | 77 |
| A-40 | — | — | — | — | 4000 | 1.35 | 63 |
| A-41 | — | — | — | — | 8800 | 1.25 | 65 |
| A-42 | — | — | — | — | 10000 | 1.50 | 65 |
| A-43 | — | — | — | — | 7100 | 1.67 | 55 |
| A-44 | — | — | — | — | 6600 | 1.65 | 75 |
| A-45 | — | — | — | — | 12200 | 1.55 | 70 |
| A-46 | — | — | — | — | 7700 | 1.56 | 57 |
| A-47 | — | — | — | — | 6700 | 1.65 | 68 |
| A-48 | — | — | — | — | 5400 | 1.40 | 67 |
| A-49 | — | — | — | — | 4300 | 1.54 | 44 |
| A-50 | — | — | — | — | 7500 | 1.59 | 45 |
| A-51 | — | — | — | — | 5800 | 1.53 | 41 |
| A-52 | — | — | — | — | 5800 | 1.55 | 50 |

TABLE 3

| | Repeating unit 1 | | Repeating unit 2 | | Repeating unit 3 | | Repeating unit 4 | | Repeating unit 5 | |
|---|---|---|---|---|---|---|---|---|---|---|
| | | Molar ratio | | Molar ratio | | Molar ratio | | Molar ratio | | Molar ratio |
| | Type | (mol %) | Type | (mol %) | Type | (mol %) | Type | (mol %) | Type | (mol %) |
| A-53 | M-1 | 5 | M-a-1 | 15 | M-b-2 | 40 | M-c-9 | 40 | — | — |
| A-54 | M-1 | 20 | M-a-1 | 5 | M-b-3 | 45 | M-c-1 | 30 | — | — |
| A-55 | M-1 | 25 | M-a-1 | 15 | M-b-3 | 25 | M-c-3 | 35 | — | — |
| A-56 | M-1 | 15 | M-a-1 | 10 | M-b-2 | 35 | M-c-2 | 30 | — | — |
| A-57 | M-2 | 20 | M-a-1 | 10 | M-b-9 | 50 | M-c-3 | 20 | — | — |
| A-58 | M-2 | 18 | M-a-1 | 15 | M-b-9 | 30 | M-c-3 | 30 | M-c-27 | 7 |
| A-59 | M-2 | 16 | M-a-1 | 4 | M-b-2 | 45 | M-c-1 | 25 | — | — |
| A-60 | M-2 | 50 | M-a-1 | 20 | M-b-2 | 20 | — | — | — | — |
| A-61 | M-2 | 48 | M-a-1 | 12 | M-b-11 | 16 | — | — | — | — |
| A-62 | M-2 | 20 | M-a-1 | 35 | M-b-16 | 25 | M-c-2 | 20 | — | — |
| A-63 | M-1 | 20 | M-a-1 | 25 | M-b-2 | 40 | M-c-1 | 10 | M-c-10 | 5 |
| A-64 | M-1 | 20 | M-a-1 | 20 | M-b-2 | 40 | M-c-1 | 15 | M-c-10 | 5 |
| A-65 | M-1 | 20 | M-a-1 | 15 | M-b-2 | 40 | M-c-1 | 20 | M-c-10 | 5 |
| A-66 | M-1 | 25 | M-a-1 | 10 | M-b-2 | 40 | M-c-1 | 20 | M-c-10 | 5 |
| A-67 | M-1 | 30 | M-a-1 | 10 | M-b-2 | 30 | M-c-1 | 25 | M-c-10 | 5 |
| A-68 | M-1 | 40 | M-a-1 | 10 | M-b-2 | 20 | M-c-1 | 25 | M-c-10 | 5 |
| A-1R | M-1 | 15 | M-a-1 | 30 | M-b-2 | 40 | M-c-1 | 10 | M-c-10 | 5 |
| A-2R | M-1 | 20 | M-a-1 | 40 | M-b-2 | 30 | M-c-1 | 5 | M-c-10 | 5 |
| A-3R | M-1 | 30 | M-a-1 | 40 | M-b-2 | 30 | — | — | — | — |
| A-4R | M-1 | 15 | M-a-1 | 10 | M-b-2 | 50 | M-e-2 | 15 | — | — |
| A-5R | M-1 | 30 | M-a-1 | 40 | — | — | M-e-1 | 20 | — | — |
| A-6R | — | — | M-a-3 | 25 | M-b-1 | 40 | M-c-13 | 35 | — | — |
| A-7R | M-6 | 15 | — | — | M-b-1 | 35 | M-c-13 | 20 | — | — |
| A-8R | M-1 | 20 | M-a-1 | 40 | — | — | M-c-2 | 30 | — | — |
| A-69 | M-1 | 10 | M-a-1 | 10 | M-b-3 | 20 | M-c-1 | 50 | — | — |
| A-70 | M-1 | 10 | M-a-1 | 10 | M-b-3 | 25 | M-c-1 | 40 | M-c-10 | 10 |
| A-71 | M-1 | 10 | M-a-1 | 10 | M-b-3 | 25 | M-c-1 | 40 | M-c-10 | 10 |

| | Repeating unit 6 | | Repeating unit 7 | | | | Total molar ratio of |
|---|---|---|---|---|---|---|---|
| | | Molar ratio | | Molar ratio | | | acid-decomposable group |
| | Type | (mol %) | Type | (mol %) | Mw | Mw/Mn | (mol %) |
| A-53 | — | — | — | — | 7400 | 1.50 | 45 |
| A-54 | — | — | — | — | 6900 | 1.60 | 50 |
| A-55 | — | — | — | — | 8500 | 1.55 | 60 |
| A-56 | M-b-7 | 10 | — | — | 6500 | 1.55 | 45 |
| A-57 | — | — | — | — | 5500 | 1.55 | 40 |
| A-58 | — | — | — | — | 4000 | 1.55 | 55 |
| A-59 | M-b-15 | 10 | — | — | 8800 | 1.55 | 41 |
| A-60 | M-b-3 | 10 | — | — | 10000 | 1.55 | 50 |
| A-61 | M-b-2 | 24 | — | — | 7100 | 1.55 | 48 |
| A-62 | — | — | — | — | 6600 | 1.55 | 40 |
| A-63 | — | — | — | — | 6500 | 1.60 | 35 |
| A-64 | — | — | — | — | 6500 | 1.60 | 40 |
| A-65 | — | — | — | — | 6500 | 1.60 | 45 |
| A-66 | — | — | — | — | 6500 | 1.60 | 50 |
| A-67 | — | — | — | — | 6500 | 1.60 | 60 |
| A-68 | — | — | — | — | 6500 | 1.60 | 70 |
| A-1R | — | — | — | — | 6500 | 1.60 | 30 |
| A-2R | — | — | — | — | 6500 | 1.60 | 30 |
| A-3R | — | — | — | — | 6500 | 1.60 | 30 |
| A-4R | M-e-3 | 10 | — | — | 6300 | 1.74 | 30 |
| A-5R | M-d-15 | 10 | — | — | 7500 | 1.70 | 50 |
| A-6R | — | — | — | — | 6500 | 1.60 | 35 |
| A-7R | M-d-3 | 30 | — | — | 6500 | 1.60 | 35 |
| A-8R | M-e-4 | 10 | — | — | 7200 | 1.52 | 50 |
| A-69 | M-d-3 | 5 | M-d-10 | 5 | 6500 | 1.60 | 60 |
| A-70 | M-d-3 | 5 | — | — | 7000 | 1.58 | 60 |
| A-71 | M-d-10 | 5 | — | — | 7000 | 1.65 | 60 |

M-1 to M-13 are those described above as specific examples of the monomer that provides the repeating unit (i).

M-a-1 to M-a-3 are those described above as specific examples of the monomer that provides the repeating unit (ii).

M-b-1 to M-b-17 are those described above as specific examples of the monomer that provides the repeating unit (iii).

M-c-1 to M-c-36 are those described above as specific examples of the monomer that provides the repeating unit (iv).

The structures of M-d-1 to M-d-28 and M-e-1 to M-e-4 are as follows.

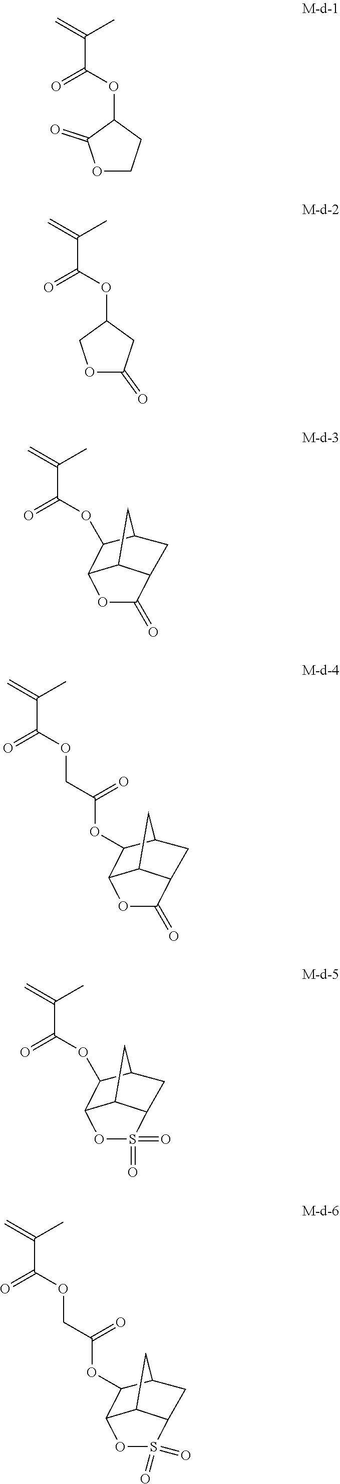 [SMILES: C=C(C)C(=O)OC1CCOC1=O ; C=C(C)C(=O)OC1COC(=O)C1 ; C=C(C)C(=O)OC1C2CC3C(=O)OC1C3C2 ; C=C(C)C(=O)OCC(=O)OC1C2CC3C(=O)OC1C3C2 ; C=C(C)C(=O)OC1C2CC3C1OS(=O)(=O)C3C2 ; C=C(C)C(=O)OCC(=O)OC1C2CC3C1OS(=O)(=O)C3C2]

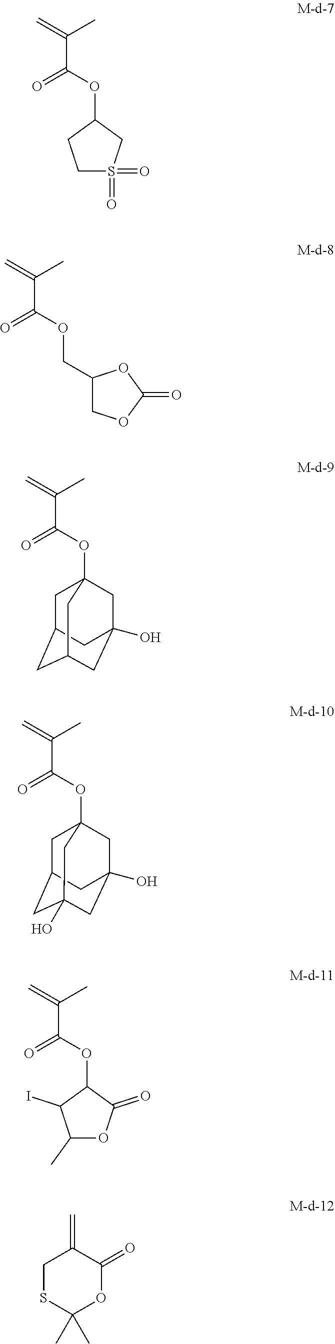

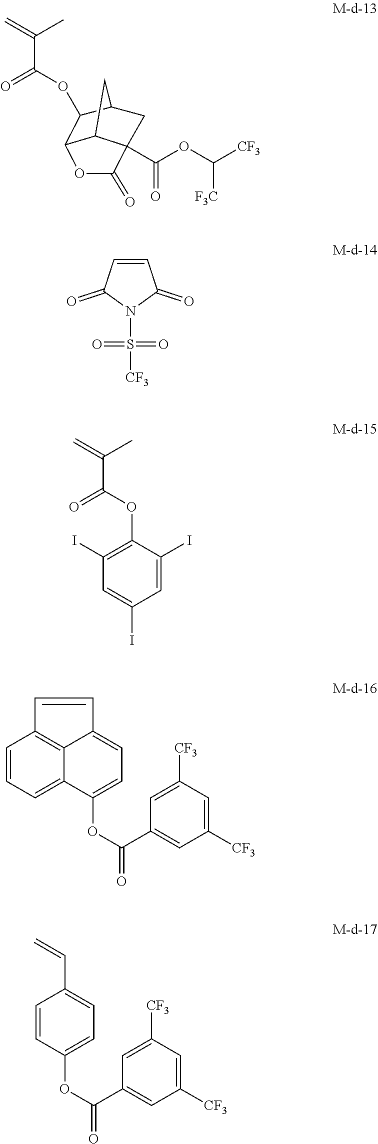 [SMILES: C=C(C)C(=O)OC1C2CC3C1OC(=O)C3(C(=O)OC(C(F)(F)F)C(F)(F)F)C2 ; O=C1C=CC(=O)N1S(=O)(=O)C(F)(F)F ; C=C(C)C(=O)Oc1c(I)cc(I)cc1I ; O=C(Oc1ccc2c3c(cccc13)C=C2)c1cc(C(F)(F)F)cc(C(F)(F)F)c1 ; C=Cc1ccc(OC(=O)c2cc(C(F)(F)F)cc(C(F)(F)F)c2)cc1]

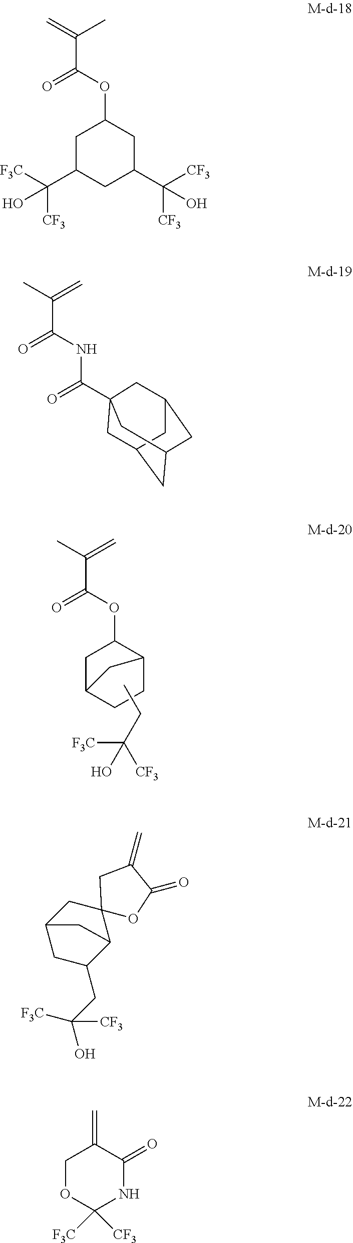

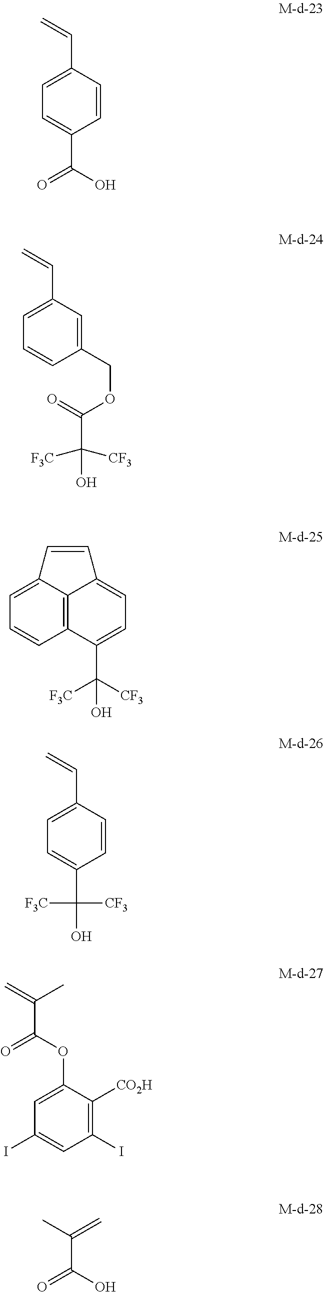

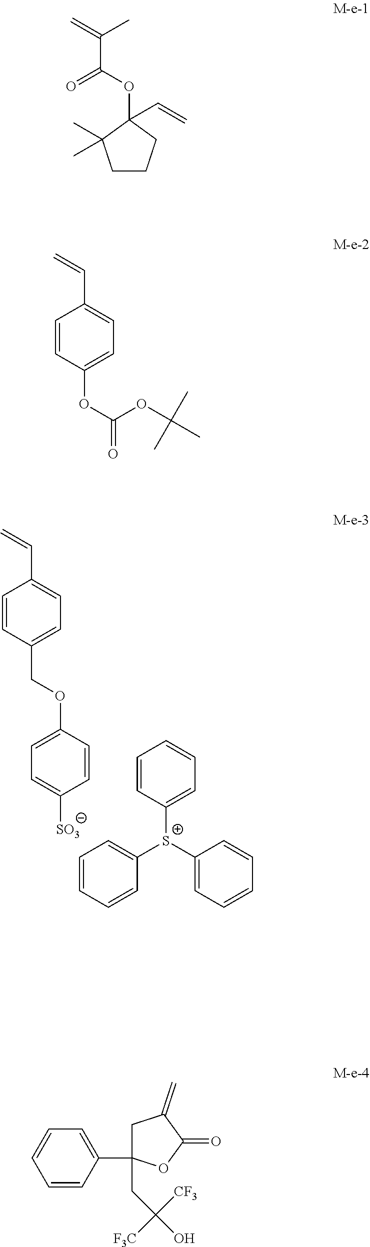

The structures of M-b-2-i, M-b-2-ii, M-b-3-i to M-b-7-i, M-b-12-i to M-b-15-i, and M-b-17-i are as follows.

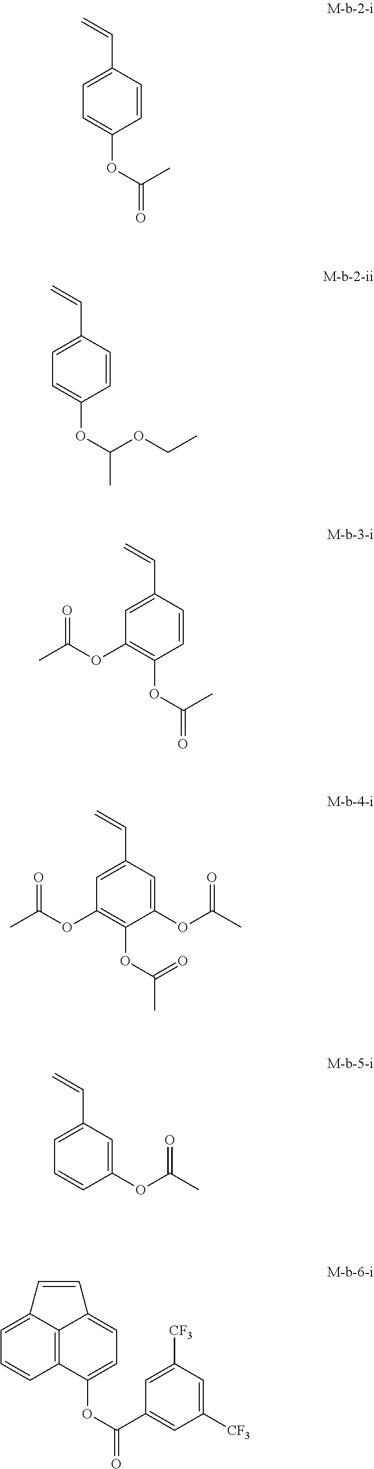

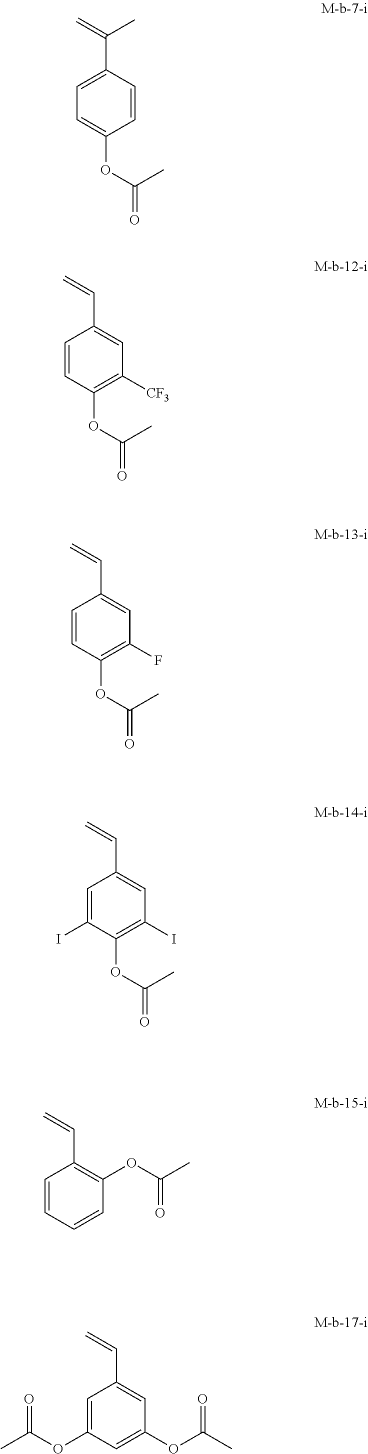

### Synthesis Example 1: Synthesis of Resin a-1

Cyclohexanone (39 g) was heated to 85° C. under a nitrogen stream. To this liquid, a mixed solution of cyclohexanone (7.5 g) and dimethyl 2,2′-azobisisobutyrate [V-601, manufactured by FUJIFILM Wako Pure Chemical Industries, Ltd.] (0.84 g) was added, and stirred for 5 minutes. To this liquid under stirring, a mixed solution of a monomer (27.5 g) represented by a formula M-1 below, a monomer (32.2 g) represented by a formula M-a-1 below, a monomer (14 g) represented by a formula M-b-1 below, a monomer (26.3 g) represented by a formula M-c-1 below, cyclohexanone (187 g), and dimethyl 2,2′-azobisisobutyrate [V-601, manufactured by FUJIFILM Wako Pure Chemical Industries, Ltd.] (8.4 g) was added dropwise over 6 hours to obtain a reaction solution. After completion of the dropwise addition, the reaction solution was further stirred at 85° C. for 2 hours. The obtained reaction solution was left to cool, subsequently diluted with 167 g of ethyl acetate, reprecipitated with a large amount of n-heptane, and subsequently filtered; the obtained solid was vacuum-dried to thereby obtain 75 g of a resin A-1.

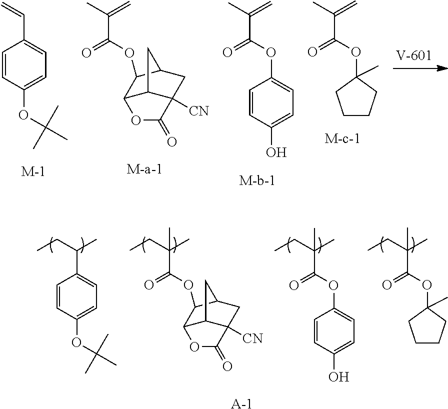

The obtained resin A-1 was subjected to GPC (carrier: tetrahydrofuran (THF)) and found to have a weight-average molecular weight (Mw: polystyrene-equivalent) of 6500 and a dispersity (Mw/Mn) of 1.60. The compositional ratio measured by ¹³C-NMR was 30/25/15/30 in terms of a molar ratio (content ratio of the repeating units; sequentially described from the left).

### Synthesis Example 2: Synthesis of Resin a-2

Cyclohexanone (44 g) was heated to 85° C. under a nitrogen stream. To this liquid, a mixed solution of cyclohexanone (3.1 g) and dimethyl 2,2′-azobisisobutyrate [V-601, manufactured by FUJIFILM Wako Pure Chemical Industries, Ltd.] (0.8 g) was added, and stirred for 5 minutes. To this liquid under stirring, a mixed solution of a monomer (17 g) represented by a formula M-1 below, a monomer (17 g) represented by a formula M-a-1 below, a monomer (41 g) represented by a formula M-b-2-ii below, a monomer (25 g) represented by a formula M-c-1 below, cyclohexanone (187 g), and dimethyl 2,2′-azobisisobutyrate [V-601, manufactured by FUJIFILM Wako Pure Chemical Industries, Ltd.] (7.9 g) was added dropwise over 6 hours, to obtain a reaction solution. After completion of the dropwise addition, the reaction solution was further stirred at 85° C. for 2 hours to thereby obtain a resin A-2′ solution.

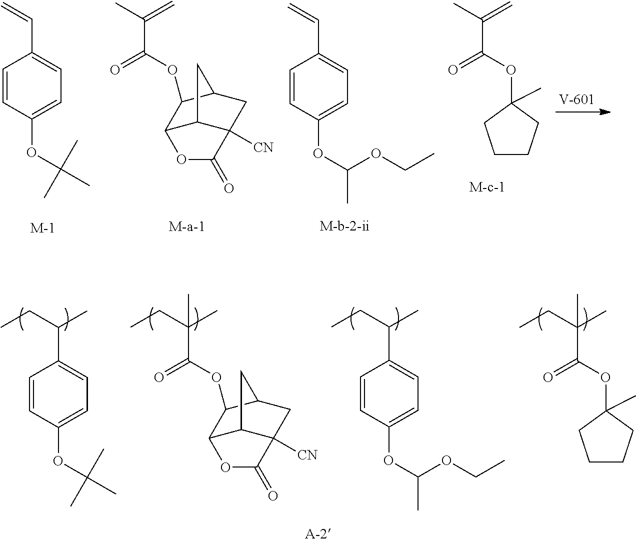

To the resin A-2′ solution, a 0.3 mol/L aqueous hydrochloric acid solution (HClaq)(3.6 g) was added and stirred at 40° C. for 1 hour. To the resultant reaction solution, ethyl acetate (1560 g) was added, and subjected to liquid-liquid separation and purification five times using 1 L of distilled water. The organic layer was reprecipitated with a large amount of a mixed solution of n-heptane/ethyl acetate (mass ratio of 9/1) and subsequently filtered; the obtained solid was vacuum-dried to thereby obtain 78 g of a resin A-2.

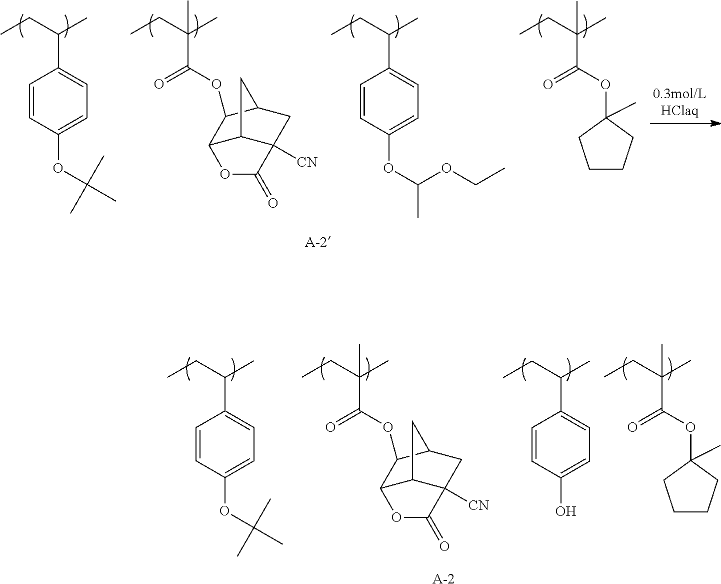

The obtained resin A-2 was subjected to GPC (carrier: tetrahydrofuran (THF)) and found to have a weight-average molecular weight (Mw: polystyrene-equivalent) of 7200 and a dispersity (Mw/Mn) of 1.59. The compositional ratio measured by ¹³C-NMR was 18/13/40/29 in terms of a molar ratio (content ratio of the repeating units; sequentially described from the left).

### Synthesis Example 3: Synthesis of Resin a-3

Cyclohexanone (43 g) was heated to 85° C. under a nitrogen stream. To this liquid, a mixed solution of cyclohexanone (4.0 g) and dimethyl 2,2′-azobisisobutyrate [V-601, manufactured by FUJIFILM Wako Pure Chemical Industries, Ltd.] (0.4 g) was added, and was stirred for 5 minutes. To this liquid under stirring, a mixed solution of a monomer (17 g) represented by a formula M-1 below, a monomer (12.5 g) represented by a formula M-a-1 below, a monomer (40 g) represented by a formula M-b-2-i below, a monomer (30.5 g) represented by a formula M-c-3 below, cyclohexanone (187 g), and dimethyl 2,2′-azobisisobutyrate [V-601, manufactured by FUJIFILM Wako Pure Chemical Industries, Ltd.] (8.8 g) was added dropwise over 6 hours, to obtain a reaction solution. After completion of the dropwise addition, the reaction solution was further stirred at 85° C. for 2 hours to thereby obtain a resin A-3′ solution.

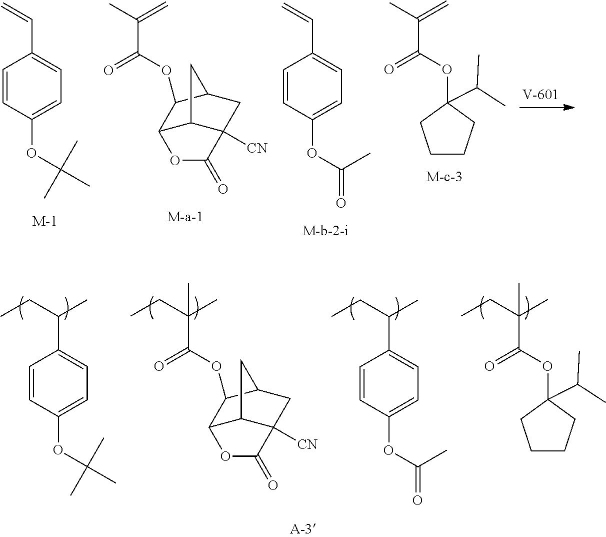

To the resin A-3′ solution, triethylamine (N Et)₃)(67 g) and methanol (MeOH)(158 g) were added and stirred at 80° C. for 15 hours under a nitrogen stream. The obtained reaction solution was left to cool; subsequently a 0.2 mol/L aqueous hydrochloric acid solution (4 L) was added and stirred, and ethyl acetate (1570 g) was further added and stirred. The organic layer was extracted and subsequently subjected to liquid-liquid separation and purification once with a 0.2 mol/L aqueous hydrochloric acid solution (0.5 L) and five times with distilled water (1 L). The obtained organic layer was reprecipitated with a large amount of a mixed solution of n-heptane/ethyl acetate (mass ratio of 9/1), and subsequently filtered; the obtained solid was vacuum-dried, to thereby obtain 82 g of a resin A-3.

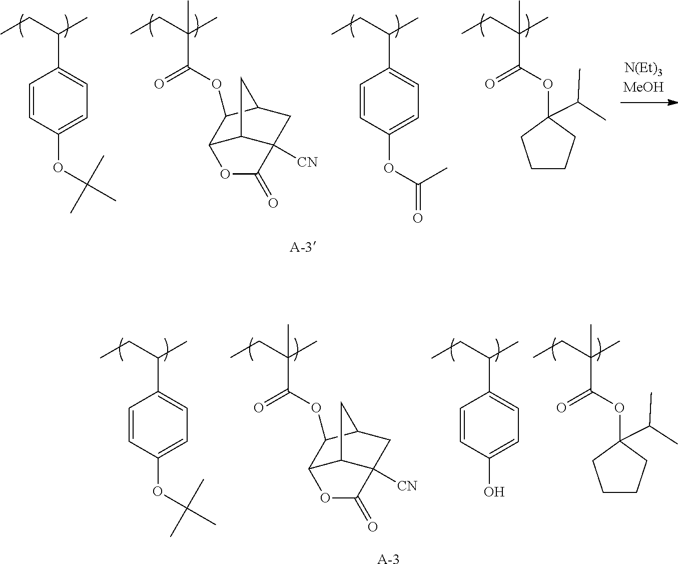

The obtained resin A-3 was subjected to GPC (carrier: tetrahydrofuran (THF)) and found to have a weight-average molecular weight (Mw: polystyrene-equivalent) of 7000 and a dispersity (Mw/Mn) of 1.58. The compositional ratio measured by ¹³C-NMR was 18/9/45/28 in terms of a molar ratio (content ratio of the repeating units; sequentially described from the left).

### Synthesis Example 4: Synthesis of Resin a-4

Cyclohexanone (44 g) was heated to 85° C. under a nitrogen stream. To this liquid, a mixed solution of cyclohexanone (2.4 g) and dimethyl 2,2′-azobisisobutyrate [V-601, manufactured by FUJIFILM Wako Pure Chemical Industries, Ltd.] (0.58 g) was added, and stirred for 5 minutes. To this liquid under stirring, a mixed solution of a monomer (14.9 g) represented by a formula M-1 below, a monomer (36.5 g) represented by a formula M-a-1 below, a monomer (25.8 g) represented by a formula M-b-6-i below, a monomer (22.9 g) represented by a formula M-c-2 below, cyclohexanone (187 g), and dimethyl 2,2′-azobisisobutyrate [V-601, manufactured by FUJIFILM Wako Pure Chemical Industries, Ltd.] (5.8 g) was added dropwise over 6 hours, to obtain a reaction solution. After completion of the dropwise addition, the reaction solution was further stirred at 85° C. for 2 hours to thereby obtain a resin A-4′ solution.

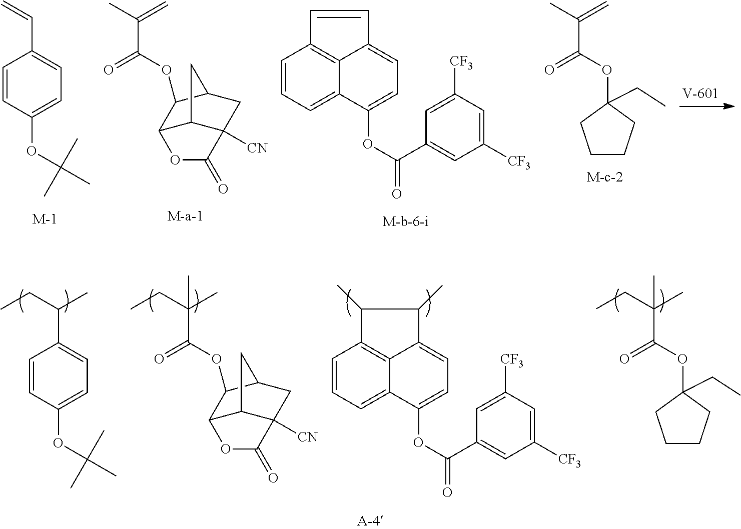

To the resin A-4′ solution, triethylamine (60 g) and methanol (94.5 g) were added and stirred at 80° C. for 3 hours under a nitrogen stream. The obtained reaction solution was left to cool; subsequently a 0.2 mol/L aqueous hydrochloric acid solution (3.6 L) was added and stirred, and ethyl acetate (1570 g) was further added and stirred. The organic layer was extracted, and subsequently subjected to liquid-liquid separation and purification once with a 0.2 mol/L aqueous hydrochloric acid solution (0.5 L) and five times with distilled water (1 L). The obtained organic layer was reprecipitated with a large amount of a mixed solution of n-heptane/ethyl acetate (mass ratio of 9/1) and subsequently filtered; the obtained solid was vacuum-dried to thereby obtain 75 g of a resin A-4.

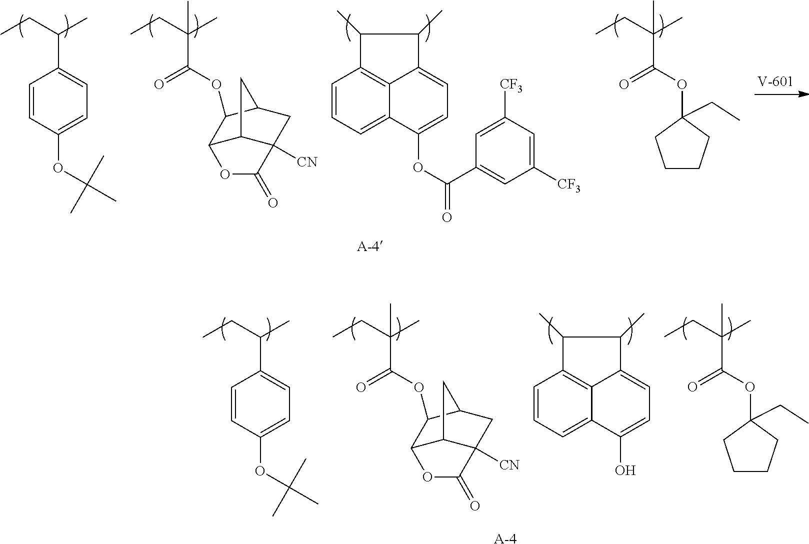

The obtained resin A-4 was subjected to GPC (carrier: tetrahydrofuran (THF)) and found to have a weight-average molecular weight (Mw: polystyrene-equivalent) of 7500 and a dispersity (Mw/Mn) of 1.55. The compositional ratio measured by 13C-NMR was 20/35/15/30 in terms of a molar ratio (content ratio of the repeating units; sequentially described from the left).

### Photoacid Generator (B)

As the photoacid generator (B), the above-described compounds B-1 to B-75 were used.

### Photodegradable Quencher

As the photodegradable quencher, the following compounds C-1 to C-26 were used.

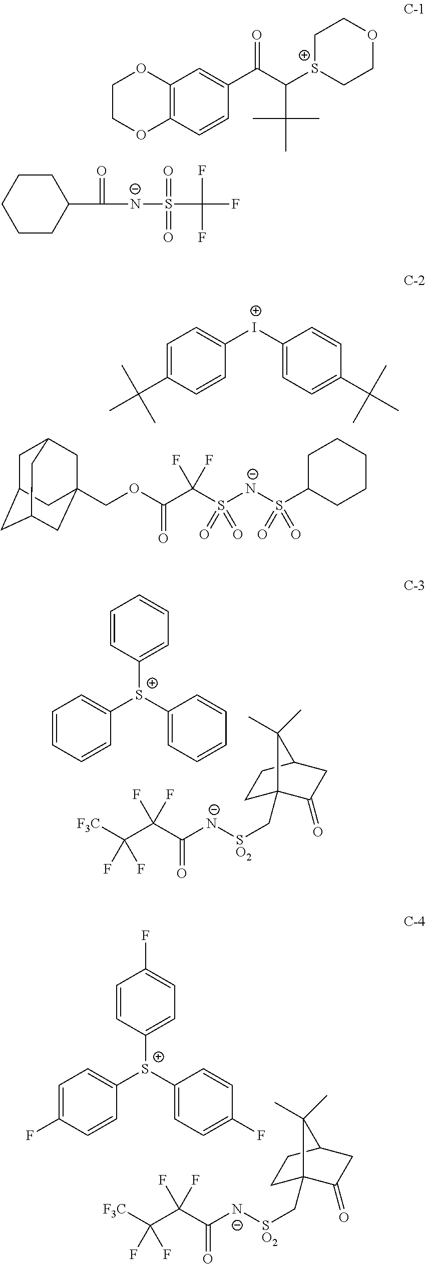

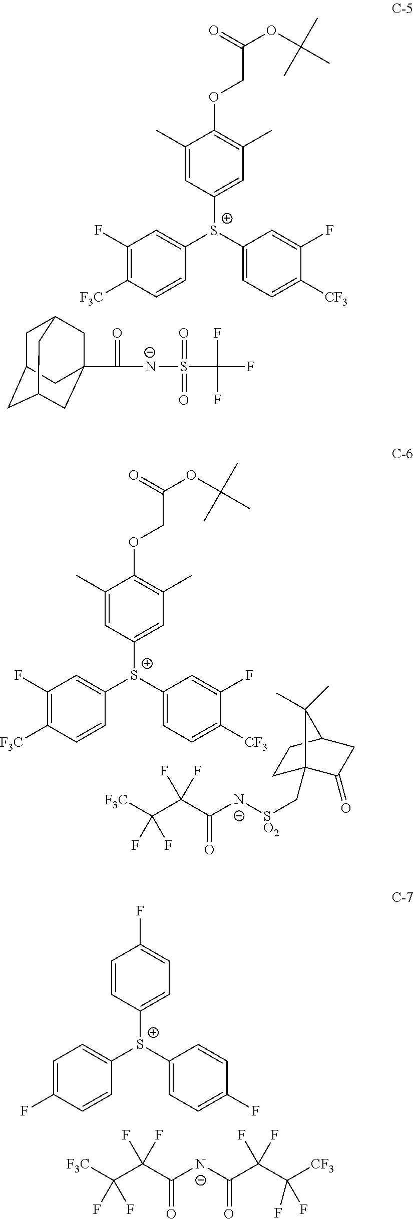 [SMILES: Cc1cc([S+](c2ccc(C(F)(F)F)c(F)c2)c2ccc(C(F)(F)F)c(F)c2)cc(C)c1OCC(=O)OC(C)(C)C ; O=C([N-]S(=O)(=O)C(F)(F)F)C12CC3CC(CC(C3)C1)C2 ; Cc1cc([S+](c2ccc(C(F)(F)F)c(F)c2)c2ccc(C(F)(F)F)c(F)c2)cc(C)c1OCC(=O)OC(C)(C)C ; CC1(C)C2CCC1(CS(=O)(=O)[N-]C(=O)C(F)(F)C(F)(F)C(F)(F)F)C(=O)C2 ; Fc1ccc([S+](c2ccc(F)cc2)c2ccc(F)cc2)cc1 ; O=C([N-]C(=O)C(F)(F)C(F)(F)C(F)(F)F)C(F)(F)C(F)(F)C(F)(F)F]

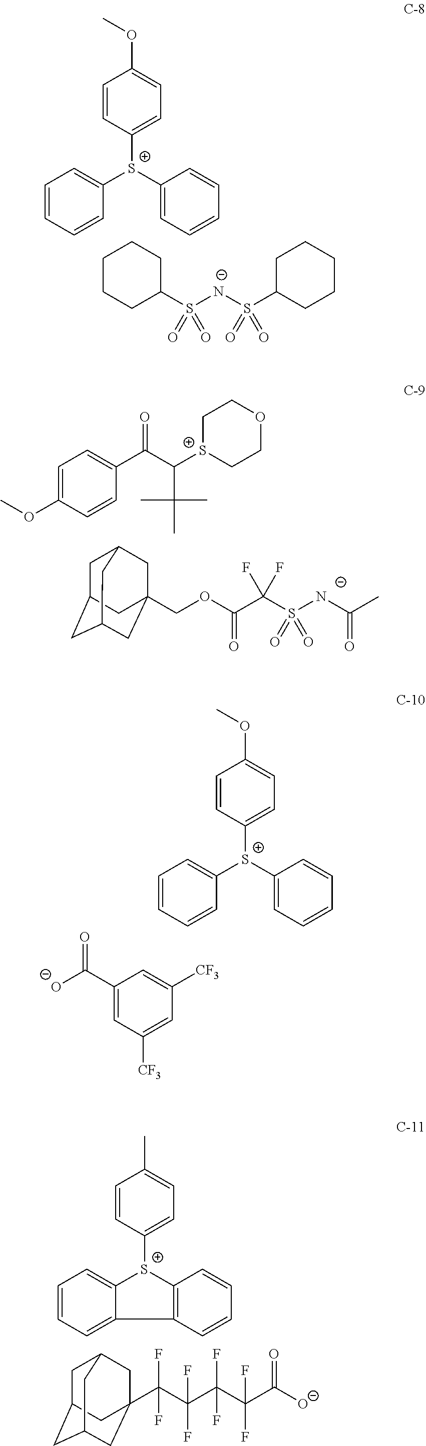

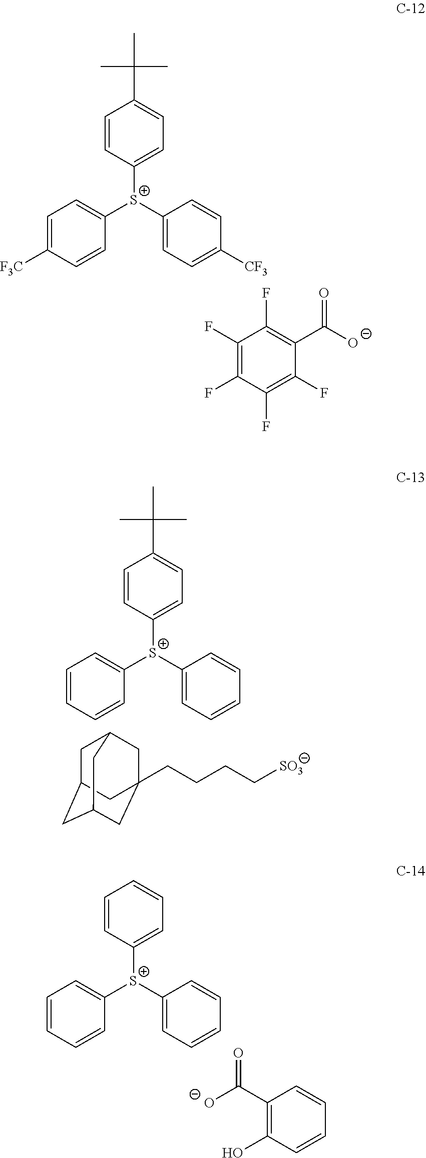

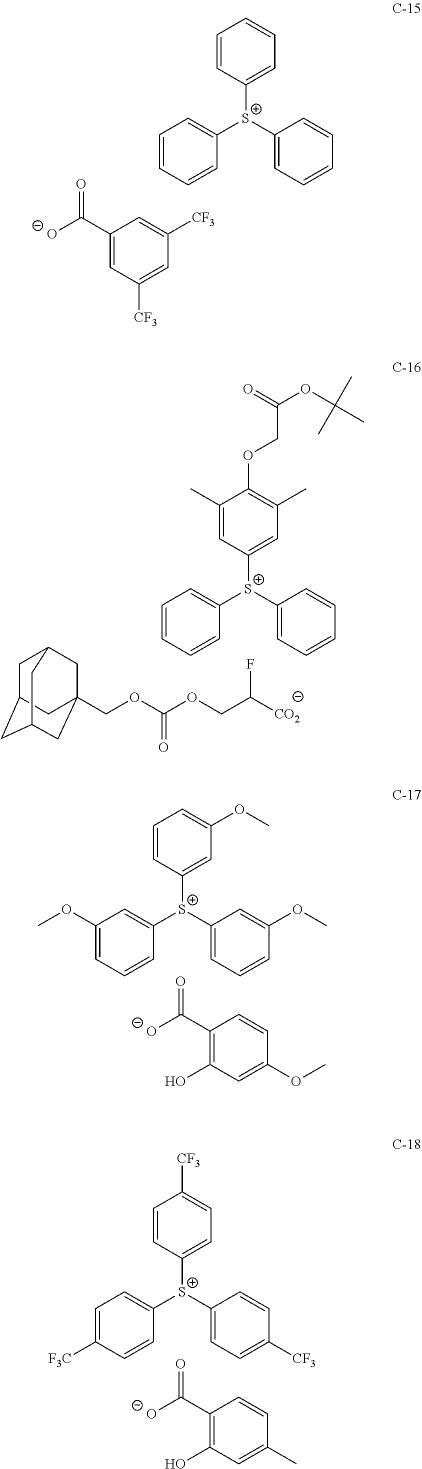

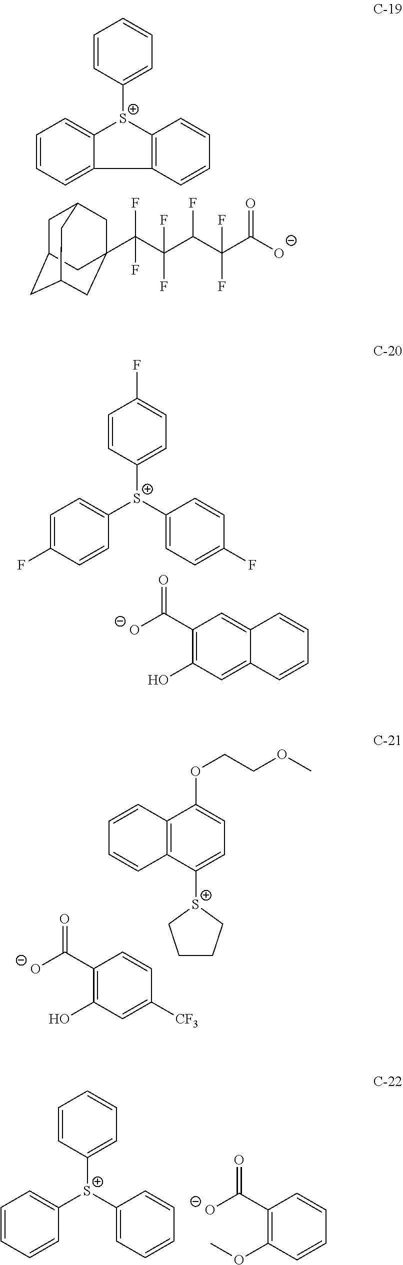

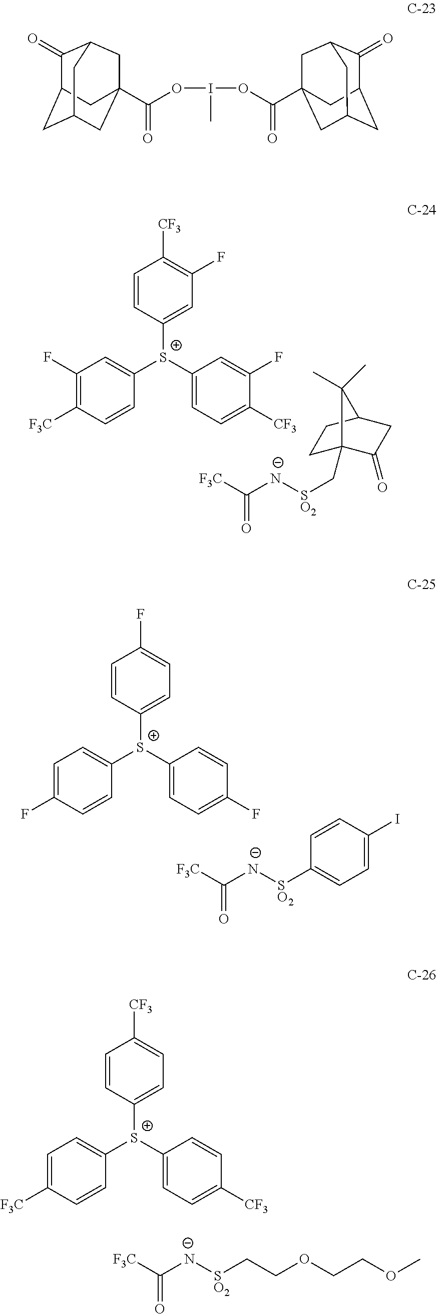

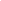

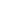

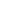

### Non-Photodegradable Quencher

As the non-photodegradable quencher, the following compounds G-1 to G-5 were used.

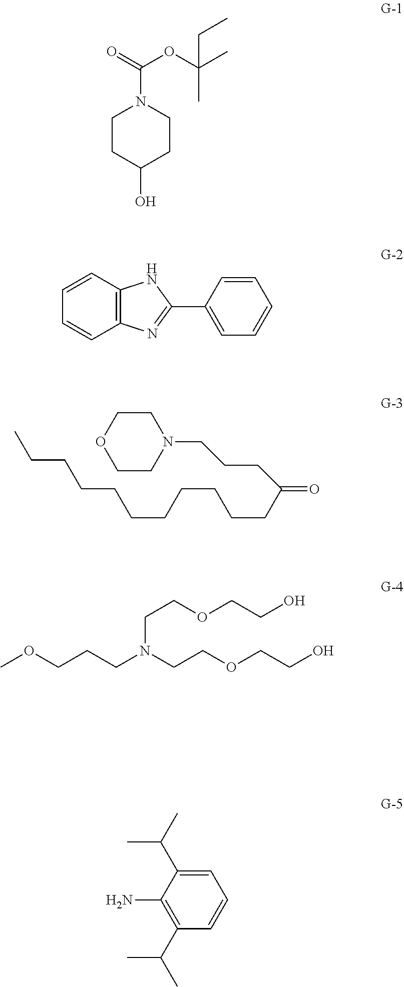 [SMILES: CCC(C)(C)OC(=O)N1CCC(O)CC1 ; c1ccc(-c2nc3ccccc3[nH]2)cc1 ; CCCCCCCCCCCC(=O)CCCN1CCOCC1 ; COCCCN(CCOCCO)CCOCCO ; CC(C)c1cccc(C(C)C)c1N]

### Hydrophobic Resin

The structures of resins I-1 to I-8 used as the hydrophobic resin are as follows.

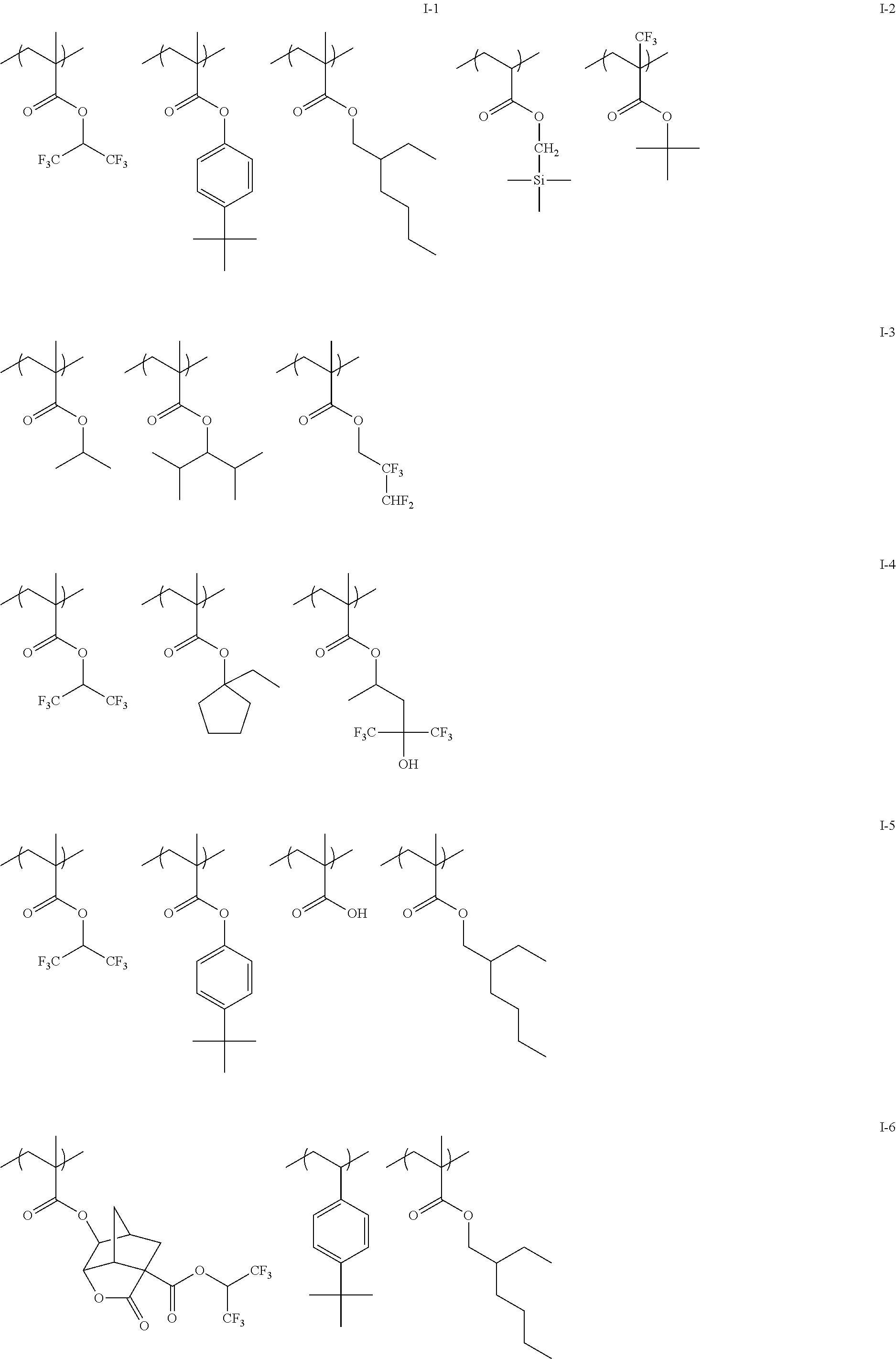

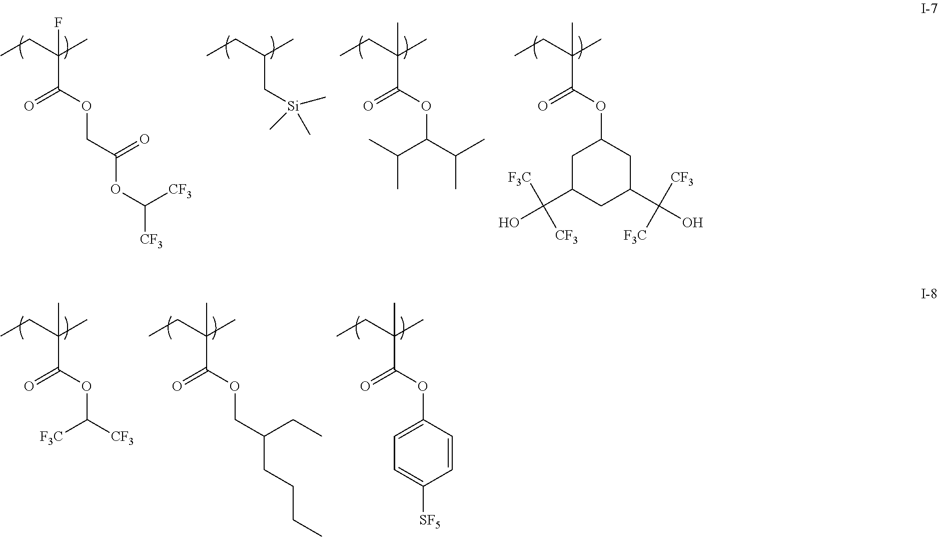

As the resins I-1 to I-8, resins synthesized in accordance with the above-described method for synthesizing the resin A-1 (Synthesis Example 1) were used.

Table 4 describes the compositional ratio (mass ratio; sequentially described from the left) of each repeating unit, weight-average molecular weight (Mw), and molecular-weight dispersity (Mw/Mn).

Note that, for the resins I-1 to I-8, the weight-average molecular weight (Mw) and the molecular-weight dispersity (Mw/Mn) were measured by GPC (carrier: tetrahydrofuran (THF)) (polystyrene-equivalent amounts). The compositional ratios (mass ratios) of the resins were measured by ¹³C-NMR.

TABLE 4

| | Mass ratio of repeating units (mass %) | | | | Mw | Mw/Mn |
|---|---|---|---|---|---|---|
| Resin I-1 | 50 | 45 | 5 | — | 6500 | 1.52 |
| Resin I-2 | 50 | 50 | — | — | 25000 | 1.65 |
| Resin I-3 | 30 | 65 | 5 | — | 22000 | 1.55 |
| Resin I-4 | 40 | 40 | 20 | — | 12000 | 1.68 |
| Resin I-5 | 40 | 50 | 5 | 5 | 5500 | 1.49 |
| Resin I-6 | 90 | 8 | 2 | — | 12000 | 1.63 |
| Resin I-7 | 20 | 30 | 40 | 10 | 13000 | 1.55 |
| Resin I-8 | 50 | 10 | 40 | — | 9000 | 1.51 |

### Surfactant

The surfactants (H-1 to H-3) used are as follows.
H-1: MEGAFACE F176 (manufactured by DIC Corporation, fluorine-based surfactant)
H-2: MEGAFACE R08 (manufactured by DIC Corporation, fluorine-based and silicone-based surfactant)
H-3: PF656 (manufactured by OMNOVA SOLUTIONS INC., fluorine-based surfactant)

### Solvent

The solvents (F-1 to F-9) used are as follows.
F-1: propylene glycol monomethyl ether acetate (PGMEA)
F-2: propylene glycol monomethyl ether (PGME)
F-3: propylene glycol monoethyl ether (PGEE)
F-4: cyclohexanone
F-5: cyclopentanone
F-6:2-heptanone
F-7: ethyl lactate
F-8: y-butyrolactone
F-9: propylene carbonate

### Preparation of Resist Compositions

Components described in Tables 5 to 8 below were mixed together so as to provide a solid-content concentration of 2.0 mass %. Subsequently, the obtained mixed solution was filtered by being passed first through a polyethylene filter having a pore size of 50 nm, subsequently through a nylon filter having a pore size of 10 nm, and finally through a polyethylene filter having a pore size of 5 nm in this order; in this way, resist compositions (Re-1 to Re-96 and Re-1R to Re-8R) were prepared.

The solid content means all the components other than the solvent.

The obtained resist compositions were used in Examples and Comparative Examples.

In Tables, the columns “Amount” describe the content (mass %) of each component relative to the total solid content of the resist composition.

TABLE 5

| | Solid content | | | | | | | | | | | | | |
|---|---|---|---|---|---|---|---|---|---|---|---|---|---|---|
| | | | | | | | Non- | | | | | | | |
| | | | Photoacid | | Photodegradable | | photodegradable | | Hydrophobic | | | | Solvent | |
| | Resin (A) | | generator (B) | | quencher | | quencher | | resin | | Surfactant | | | Mixing |
| Resist | | Amount | | Amount | | Amount | | Amount | | Amount | | Amount | | ratio |
| compo- | | (mass | | (mass | | (mass | | (mass | | (mass | | (mass | | (mass |
| sition | Type | %) | Type | %) | Type | %) | Type | %) | Type | %) | Type | %) | Type | ratio) |
| Re-1 | A-1 | 65.0 | B-1 | 32.0 | C-1 | 3.0 | — | — | — | — | — | — | F-1/F-2 | 80/20 |
| Re-2 | A-2 | 60.0 | B-2 | 38.0 | C-2 | 2.0 | — | — | — | — | — | — | F-1/F-5 | 85/15 |
| Re-3 | A-3 | 52.0 | B-3 | 44.0 | C-3 | 4.0 | — | — | — | — | — | — | F-1/F-2 | 80/20 |
| Re-4 | A-4 | 55.0 | B-4 | 40.0 | C-4 | 5.0 | — | — | — | — | — | — | F-1/F-2/F-8 | 40/20/40 |
| Re-5 | A-5 | 60.0 | B-5 | 38.0 | C-5 | 2.0 | — | — | — | — | — | — | F-1/F-2 | 80/20 |
| Re-6 | A-6 | 65.0 | B-6 | 29.0 | C-6 | 6.0 | — | — | — | — | — | — | F-1/F-9 | 85/15 |
| Re-7 | A-7 | 54.0 | B-7 | 33.9 | C-7 | 12.0 | — | — | — | — | H-1 | 0.1 | F-1/F-7 | 90/10 |
| Re-8 | A-8 | 38.0 | B-8 | 55.0 | C-8 | 7.0 | — | — | — | — | — | — | F-1/F-2 | 80/20 |
| Re-9 | A-9 | 50.0 | B-9 | 35.0 | C-9 | 15.0 | — | — | — | — | — | — | F-1/F-2 | 80/20 |
| Re-10 | A-10 | 50.0 | B-10 | 40.0 | C-10 | 10.0 | — | — | — | — | — | — | F-1/F-2/F-6 | 70/20/10 |
| Re-11 | A-11 | 55.0 | B-11 | 30.0 | C-11 | 15.0 | — | — | — | — | — | — | F-1/F-2 | 80/20 |
| Re-12 | A-12 | 90.0 | B-12 | 8.0 | C-12 | 2.0 | — | — | — | — | — | — | F-1/F-4 | 80/20 |
| Re-13 | A-13 | 60.0 | B-13 | 30.0 | C-13 | 8.0 | — | — | I-1 | 2.0 | — | — | F-1/F-2 | 80/20 |
| Re-14 | A-14 | 70.0 | B-14 | 20.0 | C-14 | 7.0 | — | — | I-2 | 2.9 | H-2 | 0.1 | F-4 | 100 |
| Re-15 | A-15 | 65.0 | B-15 | 24.0 | C-15 | 8.0 | G-1 | 3.0 | — | — | — | — | F-1/F-2/F-8 | 85/12/3 |
| Re-16 | A-16 | 80.0 | B-16 | 11.0 | C-16 | 4.0 | G-2 | 5.0 | — | — | — | — | F-1/F-5 | 80/20 |
| Re-17 | A-17 | 63.5 | B-17 | 26.0 | C-17 | 6.5 | — | — | I-3 | 4.0 | — | — | F-1/F-2 | 75/25 |
| Re-18 | A-18 | 88.0 | B-18 | 8.0 | C-18 | 2.0 | G-3 | 2.0 | — | — | — | — | F-1/F-2/F-8 | 34/33/33 |
| Re-19 | A-19 | 65.5 | B-19 | 20.0 | C-19 | 12.5 | — | — | I-4 | 2.0 | — | — | F-1/F-2 | 80/20 |
| Re-20 | A-20 | 68.0 | B-20/B-3 | 20.0/5.0 | C-20 | 2.0 | G-4 | 5.0 | — | — | — | — | F-1/F-9 | 80/20 |
| Re-21 | A-21 | 55.0 | B-21/B-4 | 22.0/15.0 | C-21 | 4.0 | G-5 | 4.0 | — | — | — | — | F-1/F-2/F-8 | 85/12/3 |
| Re-22 | A-22 | 57.0 | B-22/B-9 | 22.0/8.0 | C-22 | 4.0 | — | — | I-5 | 8.9 | H-3 | 0.1 | F-1/F-2 | 85/15 |
| Re-23 | A-23 | 80.0 | B-23 | 12.0 | C-23 | 5.0 | — | — | I-6 | 3.0 | — | — | F-1/F-2 | 80/20 |
| Re-24 | A-24 | 85.0 | B-24 | 8.0 | C-14 | 2.0 | — | — | I-7 | 5.0 | — | — | F-1/F-2/F-6 | 80/15/5 |
| Re-25 | A-25 | 70.0 | B-25 | 18.0 | C-8 | 8.0 | — | — | I-8 | 4.0 | — | — | F-1/F-2 | 90/10 |
| Re-26 | A-26 | 65.0 | B-26 | 25.0 | C-9 | 10.0 | — | — | — | — | — | — | F-1/F-4 | 80/20 |

TABLE 6

| | Solid content | | | | | | | | | | | | | |
|---|---|---|---|---|---|---|---|---|---|---|---|---|---|---|
| | | | | | | | Non- | | | | | | | |
| | | | Photoacid | | Photodegradable | | photodegradable | | Hydrophobic | | | | Solvent | |
| | Resin (A) | | generator (B) | | quencher | | quencher | | resin | | Surfactant | | | Mixing |
| Resist | | Amount | | Amount | | Amount | | Amount | | Amount | | Amount | | ratio |
| compo- | | (mass | | (mass | | (mass | | (mass | | (mass | | (mass | | (mass |
| sition | Type | %) | Type | %) | Type | %) | Type | %) | Type | %) | Type | %) | Type | ratio) |
| Re-27 | A-27 | 55.0 | B-27 | 30.0 | C-4 | 15.0 | — | — | — | — | — | — | F-1/F-2 | 80/20 |
| Re-28 | A-28 | 60.9 | B-28 | 35.0 | C-7 | 4.0 | — | — | — | — | H-3 | 0.1 | F-4 | 100 |
| Re-29 | A-29 | 31.1 | B-29 | 45.0 | C-6 | 15.0 | — | — | I-5 | 8.9 | — | — | F-1/F-3 | 85/15 |
| Re-30 | A-30 | 72.0 | B-30 | 20.0 | C-7 | 5.0 | — | — | I-6 | 3.0 | — | — | F-1/F-5 | 80/20 |
| Re-31 | A-31 | 70.0 | B-31 | 15.0 | C-8 | 9.9 | — | — | I-7 | 5.0 | H-1 | 0.1 | F-1/F-2 | 75/25 |
| Re-32 | A-32 | 71.0 | B-32 | 15.0 | C-9 | 10.0 | — | — | I-8 | 4.0 | — | — | F-1/F-2/F-8 | 40/20/40 |
| Re-33 | A-33 | 70.0 | B-33/B-6 | 10.0/20.0 | — | — | — | — | — | — | — | — | F-1/F-2 | 80/20 |
| Re-34 | A-34 | 75.0 | B-34/B-5 | 20.0/5.0 | — | — | — | — | — | — | — | — | F-1/F-9 | 80/20 |
| Re-35 | A-35 | 60.0 | B-35 | 28.0 | C-12 | 10.0 | — | — | I-1 | 2.0 | — | — | F-1/F-7 | 80/20 |
| Re-36 | A-36 | 65.0 | B-36 | 31.0 | C-13 | 2.0 | — | — | I-1 | 2.0 | — | — | F-1/F-2 | 85/15 |
| Re-37 | A-37 | 67.0 | B-37 | 30.0 | C-14 | 3.0 | — | — | — | — | — | — | F-1/F-2 | 90/10 |
| Re-38 | A-38 | 55.0 | B-38 | 40.0 | C-15 | 5.0 | — | — | — | — | — | — | F-1/F-2/F-6 | 60/20/20 |
| Re-39 | A-39 | 55.0 | B-39 | 40.0 | C-16 | 5.0 | — | — | — | — | — | — | F-1/F-2 | 90/10 |
| Re-40 | A-40 | 46.0 | B-40/B-2 | 30.0/14.0 | C-17 | 4.0 | — | — | I-5 | 6.0 | — | — | F-1/F-4 | 80/20 |
| Re-41 | A-41 | 60.0 | B-41 | 27.0 | C-18 | 10.0 | — | — | I-6 | 3.0 | — | — | F-1/F-2 | 80/20 |
| Re-42 | A-42 | 53.0 | B-42 | 35.0 | C-16 | 7.0 | — | — | I-7 | 5.0 | — | — | F-4 | 100 |
| Re-43 | A-43 | 46.0 | B-43 | 40.0 | C-20 | 10.0 | — | — | I-8 | 4.0 | — | — | F-1/F-2/F-6 | 34/33/33 |
| Re-44 | A-44 | 67.0 | B-44 | 28.0 | C-21 | 5.0 | — | — | — | — | — | — | F-1/F-5 | 80/20 |
| Re-45 | A-45 | 61.0 | B-45 | 35.0 | C-5 | 4.0 | — | — | — | — | — | — | F-1/F-2 | 85/15 |
| Re-46 | A-46 | 65.0 | B-46 | 33.0 | C-23 | 2.0 | — | — | — | — | — | — | F-1/F-2/F-8 | 50/40/10 |
| Re-47 | A-47 | 60.0 | B-47/B-4 | 20.0/20.0 | — | — | — | — | — | — | — | — | F-1/F-2 | 80/20 |
| Re-48 | A-48 | 55.0 | B-9/B-24 | 30.0/15.0 | — | — | — | — | — | — | — | — | F-1/F-9 | 80/20 |
| Re-49 | A-49 | 45.0 | B-44 | 55.0 | — | — | — | — | — | — | — | — | F-1/F-7 | 60/40 |
| Re-50 | A-50 | 57.0 | B-11/B-25 | 30.0/10.0 | — | — | — | — | I-6 | 3.0 | — | — | F-1/F-2 | 90/10 |
| Re-51 | A-51 | 61.0 | B-10/B-40 | 32.0/5.0 | C-6 | 2.0 | — | — | — | — | — | — | F-1/F-2 | 80/20 |
| Re-52 | A-52 | 74.0 | B-10 | 26.0 | — | — | — | — | — | — | — | — | F-1/F-2/F-8 | 85/12/3 |

TABLE 7

| | Solid content | | | | | | | | | | | | | |
|---|---|---|---|---|---|---|---|---|---|---|---|---|---|---|
| | | | | | | | Non- | | | | | | | |
| | | | Photoacid | | Photodegradable | | photodegradable | | Hydrophobic | | | | Solvent | |
| | Resin (A) | | generator (B) | | quencher | | quencher | | resin | | Surfactant | | | Mixing |
| Resist | | Amount | | Amount | | Amount | | Amount | | Amount | | Amount | | ratio |
| compo- | | (mass | | (mass | | (mass | | (mass | | (mass | | (mass | | (mass |
| sition | Type | %) | Type | %) | Type | %) | Type | %) | Type | %) | Type | %) | Type | ratio) |
| Re-53 | A-53 | 80.0 | B-45/B-14 | 8.0/2.0 | C-11 | 10.0 | — | — | — | — | — | — | F-1/F-2 | 80/20 |
| Re-54 | A-54 | 55.0 | B-42 | 35.0 | C-12 | 10.0 | — | — | — | — | — | — | F-1/F-4 | 80/20 |
| Re-55 | A-55 | 60.0 | B-41 | 30.0 | C-13 | 10.0 | — | — | — | — | — | — | F-1/F-2 | 60/40 |
| Re-56 | A-56 | 60.0 | B-41/B-35 | 25.0/10.0 | C-14 | 5.0 | — | — | — | — | — | — | F-4 | 100 |
| Re-57 | A-57 | 53.0 | B-44/B-33 | 25.0/12.0 | C-15 | 10.0 | — | — | — | — | — | — | F-1/F-2 | 80/20 |
| Re-58 | A-58 | 65.0 | B-14 | 30.0 | C-16 | 5.0 | — | — | — | — | — | — | F-1/F-5 | 80/20 |
| Re-59 | A-59 | 80.0 | B-11 | 15.0 | C-7 | 5.0 | — | — | — | — | — | — | F-1/F-2 | 80/20 |
| Re-60 | A-60 | 56.1 | B-28 | 25.0 | C-8 | 10.0 | — | — | I-5 | 8.9 | — | — | F-1/F-2/F-8 | 34/33/33 |
| Re-61 | A-61 | 45.0 | B-34 | 45.0 | C-1 | 10.0 | — | — | — | — | — | — | F-1/F-2 | 80/20 |
| Re-62 | A-62 | 65.0 | B-29 | 30.0 | C-2 | 5.0 | — | — | — | — | — | — | F-1/F-2 | 85/15 |
| Re-63 | A-63 | 65.0 | B-24 | 25.0 | C-14 | 10.0 | — | — | — | — | — | — | F-1/F-7 | 90/10 |
| Re-64 | A-64 | 65.0 | B-24 | 25.0 | C-14 | 10.0 | — | — | — | — | — | — | F-1/F-2 | 80/20 |
| Re-65 | A-65 | 65.0 | B-24 | 25.0 | C-14 | 10.0 | — | — | — | — | — | — | F-1/F-2 | 80/20 |
| Re-66 | A-66 | 65.0 | B-24 | 25.0 | C-14 | 10.0 | — | — | — | — | — | — | F-1/F-7 | 90/10 |
| Re-67 | A-67 | 65.0 | B-24 | 25.0 | C-14 | 10.0 | — | — | — | — | — | — | F-1/F-2 | 80/20 |
| Re-68 | A-68 | 65.0 | B-24 | 25.0 | C-14 | 10.0 | — | — | — | — | — | — | F-1/F-2 | 80/20 |
| Re-1R | A-1R | 65.0 | B-24 | 25.0 | C-14 | 10.0 | — | — | — | — | — | — | F-1/F-2 | 80/20 |
| Re-2R | A-2R | 65.0 | B-24 | 25.0 | C-14 | 10.0 | — | — | — | — | — | — | F-1/F-2 | 80/20 |
| Re-3R | A-3R | 65.0 | B-24 | 25.0 | C-14 | 10.0 | — | — | — | — | — | — | F-1/F-2 | 80/20 |
| Re-4R | A-4R | 65.0 | B-24 | 25.0 | C-14 | 10.0 | — | — | — | — | — | — | F-1/F-2 | 80/20 |
| Re-5R | A-5R | 65.0 | B-24 | 25.0 | C-14 | 10.0 | — | — | — | — | — | — | F-1/F-2 | 80/20 |
| Re-6R | A-6R | 65.0 | B-24 | 25.0 | C-14 | 10.0 | — | — | — | — | — | — | F-1/F-2 | 80/20 |
| Re-7R | A-7R | 65.0 | B-24 | 25.0 | C-14 | 10.0 | — | — | — | — | — | — | F-1/F-2 | 80/20 |
| Re-8R | A-8R | 65.0 | B-24 | 25.0 | C-14 | 10.0 | — | — | — | — | — | — | F-1/F-2 | 80/20 |

TABLE 8

| | Solid content | | | | | | | | | | | | | |
|---|---|---|---|---|---|---|---|---|---|---|---|---|---|---|
| | | | | | | | Non- | | | | | | | |
| | | | Photoacid | | Photodegradable | | photodegradable | | Hydrophobic | | | | Solvent | |
| | Resin (A) | | generator (B) | | quencher | | quencher | | resin | | Surfactant | | | Mixing |
| Resist | | Amount | | Amount | | Amount | | Amount | | Amount | | Amount | | ratio |
| compo- | | (mass | | (mass | | (mass | | (mass | | (mass | | (mass | | (mass |
| sition | Type | %) | Type | %) | Type | %) | Type | %) | Type | %) | Type | %) | Type | ratio) |
| Re-69 | A-69 | 65.0 | B-48 | 32.0 | C-1 | 3.0 | — | — | — | — | — | — | F-1/F-2 | 80/20 |
| Re-70 | A-70 | 60.0 | B-49 | 38.0 | C-2 | 2.0 | — | — | — | — | — | — | F-1/F-5 | 85/15 |
| Re-71 | A-71 | 60.0 | B-50 | 38.0 | C-3 | 2.0 | — | — | — | — | — | — | F-1/F-2 | 80/20 |
| Re-72 | A-1 | 65.0 | B-51 | 30.0 | C-1 | 5.0 | — | — | — | — | — | — | F-1/F-2 | 80/20 |
| Re-73 | A-2 | 65.0 | B-52 | 33.0 | C-2 | 2.0 | — | — | — | — | — | — | F-1/F-5 | 85/15 |
| Re-74 | A-3 | 52.0 | B-53 | 44.0 | C-3 | 4.0 | — | — | — | — | — | — | F-1/F-2 | 80/20 |
| Re-75 | A-4 | 55.0 | B-54 | 40.0 | C-4 | 5.0 | — | — | — | — | — | — | F-1/F-2/F-8 | 40/20/40 |
| Re-76 | A-1 | 55.0 | B-55 | 35.0 | C-1 | 10.0 | — | — | — | — | — | — | F-1/F-2 | 80/20 |
| Re-77 | A-2 | 60.0 | B-56 | 37.0 | C-2 | 3.0 | — | — | — | — | — | — | F-1/F-5 | 85/15 |
| Re-78 | A-3 | 60.0 | B-57 | 38.0 | C-3 | 2.0 | — | — | — | — | — | — | F-1/F-2 | 80/20 |
| Re-79 | A-4 | 60.0 | B-58 | 35.0 | C-4 | 5.0 | — | — | — | — | — | — | F-1/F-2/F-8 | 40/20/40 |
| Re-80 | A-1 | 68.0 | B-59 | 30.0 | C-1 | 2.0 | — | — | — | — | — | — | F-1/F-2 | 80/20 |
| Re-81 | A-2 | 65.0 | B-60 | 30.0 | C-2 | 5.0 | — | — | — | — | — | — | F-1/F-5 | 85/15 |
| Re-82 | A-3 | 60.0 | B-61 | 38.0 | C-3 | 2.0 | — | — | — | — | — | — | F-1/F-2 | 80/20 |
| Re-83 | A-4 | 58.0 | B-62 | 37.0 | C-4 | 5.0 | — | — | — | — | — | — | F-1/F-2/F-8 | 40/20/40 |
| Re-84 | A-1 | 65.0 | B-63 | 33.0 | C-1 | 2.0 | — | — | — | — | — | — | F-1/F-2 | 80/20 |
| Re-85 | A-2 | 60.0 | B-64 | 35.0 | C-2 | 5.0 | — | — | — | — | — | — | F-1/F-5 | 85/15 |
| Re-86 | A-3 | 75.0 | B-65 | 23.0 | C-3 | 2.0 | — | — | — | — | — | — | F-1/F-2 | 80/20 |
| Re-87 | A-4 | 70.0 | B-66 | 27.0 | C-4 | 3.0 | — | — | — | — | — | — | F-1/F-2/F-8 | 40/20/40 |
| Re-88 | A-69 | 69.0 | B-67 | 28.0 | C-24 | 3.0 | — | — | — | — | — | — | F-1/F-2 | 80/20 |
| Re-89 | A-70 | 65.0 | B-68 | 33.0 | C-25 | 2.0 | — | — | — | — | — | — | F-1/F-5 | 85/15 |
| Re-90 | A-71 | 60.0 | B-69 | 38.0 | C-26 | 2.0 | — | — | — | — | — | — | F-1/F-2 | 80/20 |
| Re-91 | A-1 | 68.0 | B-70 | 30.0 | C-1 | 2.0 | — | — | — | — | — | — | F-1/F-2 | 80/20 |
| Re-92 | A-2 | 70.0 | B-71 | 25.0 | C-2 | 5.0 | — | — | — | — | — | — | F-1/F-5 | 85/15 |
| Re-93 | A-3 | 72.0 | B-72 | 26.0 | C-3 | 2.0 | — | — | — | — | — | — | F-1/F-2 | 80/20 |
| Re-94 | A-4 | 65.0 | B-73 | 32.0 | C-4 | 3.0 | — | — | — | — | — | — | F-1/F-2/F-8 | 40/20/40 |
| Re-95 | A-69 | 70.0 | B-74 | 27.0 | C-24 | 3.0 | — | — | — | — | — | — | F-1/F-2 | 80/20 |
| Re-96 | A-70 | 67.0 | B-75 | 31.0 | C-25 | 2.0 | — | — | — | — | — | — | F-1/F-5 | 85/15 |

### Examples 1-1 to 1-96 and Comparative Examples 1-1 to 1-8 Pattern Forming Method (1): EUV Exposure and Organic-Solvent Development

An underlayer film-forming composition AL412 (manufactured by Brewer Science, Inc.) was applied onto a silicon wafer having a diameter of 12 inches and baked at 205° C. for 60 seconds to form an underlayer film having a film thickness of 20 nm. A resist composition described in Tables 9 to 10 below was applied onto the underlayer film and baked at 100° C. for 60 seconds to form a resist film having a film thickness of 30 nm.

An EUV exposure apparatus (manufactured by Exitech Ltd., Micro Exposure Tool, NA: 0.3, Quadrupole, outer sigma: 0.68, inner sigma: 0.36) was used to subject the obtained silicon wafer having the resist film to pattern irradiation such that the resultant pattern would have an average line width of 14 nm. Note that the reticle employed was a mask having a line size=14 nm and a line: space=1:1.

The exposed resist film was baked at 90° C. for 60 seconds, and subsequently developed with n-butyl acetate for 30 seconds; and this was spin-dried to obtain a negative pattern. Evaluation item 1: defect evaluation (defect suppression performance)

For the patterns obtained by the above-described method, UVision5 (manufactured by AMAT Inc.) and SEMVisionG4 (manufactured by AMAT Inc.) were used to count the number of defects per silicon wafer and evaluation was performed in accordance with the following evaluation grades. The smaller the number of defects, the better the defect suppression performance; “F” or higher grades can be regarded as passes.
A: The number of defects is 50 or less.
B: The number of defects is more than 50 and 100 or less.
C: The number of defects is more than 100 and 200 or less.
D: The number of defects is more than 200 and 300 or less.
E: The number of defects is more than 300 and 400 or less.
F: The number of defects is more than 400 and 500 or less.
G: The number of defects is more than 500.

### Evaluation Item 2: Line Width Roughness Performance (LWR Performance, Nm)

The patterns obtained by the above-described method were observed from above using a critical dimension-scanning electron microscope (SEM, Hitachi, Ltd., S-9380II)). The line widths of such a pattern were observed at 250 points, and the standard deviation (σ) thereof was determined. The measurement variation of the line widths was evaluated on the basis of 36, and the value of 30 was defined as LWR (nm). The smaller the value of LWR, the better the LWR performance.

The LWR performance (nm) is preferably 4.5 nm or less, more preferably 4.2 nm or less, even more preferably 3.9 nm or less, still more preferably 3.6 nm or less, particularly preferably 3.3 nm or less, and most preferably 3.0 nm or less.

The results will be described in the following Tables 9 and 10.

TABLE 9

| | | Evaluation | Evaluation |
|---|---|---|---|
| | | item 1 Defect | item 2 LWR |
| | Resist | suppression | performance |
| | composition | performance | (nm) |
| Example 1-1 | Re-1 | A | 3.0 |
| Example 1-2 | Re-2 | A | 2.9 |
| Example 1-3 | Re-3 | A | 3.0 |
| Example 1-4 | Re-4 | A | 2.9 |
| Example 1-5 | Re-5 | C | 3.5 |
| Example 1-6 | Re-6 | B | 3.2 |
| Example 1-7 | Re-7 | C | 3.4 |
| Example 1-8 | Re-8 | D | 3.9 |
| Example 1-9 | Re-9 | C | 3.6 |
| Example 1-10 | Re-10 | B | 3.3 |
| Example 1-11 | Re-11 | E | 4.1 |
| Example 1-12 | Re-12 | E | 4.2 |
| Example 1-13 | Re-13 | E | 4.0 |
| Example 1-14 | Re-14 | D | 3.8 |
| Example 1-15 | Re-15 | F | 4.5 |
| Example 1-16 | Re-16 | C | 3.5 |
| Example 1-17 | Re-17 | D | 3.9 |
| Example 1-18 | Re-18 | C | 3.5 |
| Example 1-19 | Re-19 | C | 3.6 |
| Example 1-20 | Re-20 | B | 3.2 |
| Example 1-21 | Re-21 | C | 3.4 |
| Example 1-22 | Re-22 | F | 4.3 |
| Example 1-23 | Re-23 | E | 4.1 |
| Example 1-24 | Re-24 | E | 4.0 |
| Example 1-25 | Re-25 | F | 4.3 |
| Example 1-26 | Re-26 | E | 4.2 |
| Example 1-27 | Re-27 | D | 3.7 |
| Example 1-28 | Re-28 | B | 3.3 |
| Example 1-29 | Re-29 | B | 3.2 |
| Example 1-30 | Re-30 | C | 3.5 |
| Example 1-31 | Re-31 | C | 3.6 |
| Example 1-32 | Re-32 | B | 3.1 |
| Example 1-33 | Re-33 | A | 2.8 |
| Example 1-34 | Re-34 | C | 3.4 |
| Example 1-35 | Re-35 | C | 3.5 |
| Example 1-36 | Re-36 | D | 3.9 |
| Example 1-37 | Re-37 | C | 3.5 |
| Example 1-38 | Re-38 | B | 3.2 |
| Example 1-39 | Re-39 | C | 3.4 |
| Example 1-40 | Re-40 | B | 3.3 |
| Example 1-41 | Re-41 | B | 3.1 |
| Example 1-42 | Re-42 | B | 3.2 |
| Example 1-43 | Re-43 | C | 3.5 |
| Example 1-44 | Re-44 | C | 3.4 |
| Example 1-45 | Re-45 | A | 3.0 |
| Example 1-46 | Re-46 | B | 3.3 |
| Example 1-47 | Re-47 | B | 3.2 |
| Example 1-48 | Re-48 | B | 3.1 |
| Example 1-49 | Re-49 | E | 4.1 |
| Example 1-50 | Re-50 | A | 2.8 |
| Example 1-51 | Re-51 | A | 2.9 |
| Example 1-52 | Re-52 | A | 2.9 |
| Example 1-53 | Re-53 | A | 2.9 |
| Example 1-54 | Re-54 | B | 3.2 |
| Example 1-55 | Re-55 | B | 3.3 |
| Example 1-56 | Re-56 | B | 3.2 |
| Example 1-57 | Re-57 | C | 3.5 |
| Example 1-58 | Re-58 | A | 3.0 |
| Example 1-59 | Re-59 | B | 3.1 |
| Example 1-60 | Re-60 | C | 3.6 |
| Example 1-61 | Re-61 | C | 3.5 |
| Example 1-62 | Re-62 | C | 3.4 |
| Example 1-63 | Re-63 | D | 3.7 |
| Example 1-64 | Re-64 | C | 3.4 |
| Example 1-65 | Re-65 | B | 3.2 |
| Example 1-66 | Re-66 | B | 3.2 |
| Example 1-67 | Re-67 | B | 3.1 |
| Example 1-68 | Re-68 | B | 3.1 |

TABLE 10

| | | Evaluation | Evaluation |
|---|---|---|---|
| | | item 1 Defect | item 2 LWR |
| | Resist | suppression | performance |
| | composition | performance | (nm) |
| Comparative Example 1-1 | Re-1R | G | 5.0 |
| Comparative Example 1-2 | Re-2R | G | 5.2 |
| Comparative Example 1-3 | Re-3R | G | 5.4 |
| Comparative Example 1-4 | Re-4R | G | 5.6 |
| Comparative Example 1-5 | Re-5R | G | 5.7 |
| Comparative Example 1-6 | Re-6R | G | 5.7 |
| Comparative Example 1-7 | Re-7R | G | 5.8 |
| Comparative Example 1-8 | Re-8R | G | 5.0 |
| Example 1-69 | Re-69 | A | 2.9 |
| Example 1-70 | Re-70 | A | 2.9 |
| Example 1-71 | Re-71 | A | 2.9 |
| Example 1-72 | Re-72 | B | 3.2 |
| Example 1-73 | Re-73 | B | 3.1 |
| Example 1-74 | Re-74 | A | 3.0 |
| Example 1-75 | Re-75 | A | 2.9 |
| Example 1-76 | Re-76 | A | 3.0 |
| Example 1-77 | Re-77 | A | 3.0 |
| Example 1-78 | Re-78 | A | 2.9 |
| Example 1-79 | Re-79 | A | 2.9 |
| Example 1-80 | Re-80 | A | 3.0 |
| Example 1-81 | Re-81 | B | 3.3 |
| Example 1-82 | Re-82 | B | 3.2 |
| Example 1-83 | Re-83 | B | 3.1 |
| Example 1-84 | Re-84 | B | 3.3 |
| Example 1-85 | Re-85 | B | 3.3 |
| Example 1-86 | Re-86 | B | 3.2 |
| Example 1-87 | Re-87 | B | 3.2 |
| Example 1-88 | Re-88 | B | 3.1 |
| Example 1-89 | Re-89 | B | 3.3 |
| Example 1-90 | Re-90 | B | 3.3 |
| Example 1-91 | Re-91 | B | 3.2 |
| Example 1-92 | Re-92 | B | 3.1 |
| Example 1-93 | Re-93 | B | 3.3 |
| Example 1-94 | Re-94 | B | 3.2 |
| Example 1-95 | Re-95 | B | 3.2 |
| Example 1-96 | Re-96 | B | 3.1 |

Tables 9 and 10 above have demonstrated that resist compositions of the present invention exhibit high defect performance (defect suppression performance) and high LWR performance in the case of forming an ultrafine pattern by organic-solvent development. On the other hand, the resist compositions of Comparative Examples were insufficient in terms of these performances.

### Examples 2-1 to 2-96 and Comparative Examples 2-1 to 2-8

### Pattern Forming Method (2): EUV Exposure and Alkaline Aqueous Solution Development

An underlayer film-forming composition AL412 (manufactured by Brewer Science, Inc.) was applied onto a silicon wafer having a diameter of 12 inches and baked at 205° C. for 60 seconds to form an underlayer film having a film thickness of 20 nm. A resist composition described in Tables 11 to 12 below was applied onto the underlayer film and baked at 100° C. for 60 seconds to form a resist film having a film thickness of 30 nm.

An EUV exposure apparatus (manufactured by Exitech Ltd., Micro Exposure Tool, NA: 0.3, Quadrupole, outer sigma: 0.68, inner sigma: 0.36) was used to subject the obtained silicon wafer having the resist film to pattern irradiation such that the resultant pattern would have an average line width of 14 nm. Note that the reticle employed was a mask having a line size=14 nm and a line: space=1:1.

The exposed resist film was baked at 90° C. for 60 seconds, subsequently developed with an aqueous tetramethylammonium hydroxide solution (2.38 mass %) for 30 seconds, and subsequently rinsed with pure water for 30 seconds. Subsequently, this was spin-dried to obtain a positive pattern.

The obtained positive pattern was subjected to evaluation of the defect suppression performance and the LWR performance in the same manner as in the above-described Examples 1-1 to 1-96 and Comparative Examples 1-1 to 1-8.

The evaluation results will be described in the following Tables 11 and 12.

TABLE 11

| | | Evaluation | Evaluation |
|---|---|---|---|
| | | item 1 Defect | item 2 LWR |
| | Resist | suppression | performance |
| | composition | performance | (nm) |
| Example 2-1 | Re-1 | A | 3.0 |
| Example 2-2 | Re-2 | A | 2.9 |
| Example 2-3 | Re-3 | A | 2.8 |
| Example 2-4 | Re-4 | A | 3.0 |
| Example 2-5 | Re-5 | C | 3.4 |
| Example 2-6 | Re-6 | B | 3.2 |
| Example 2-7 | Re-7 | C | 3.5 |
| Example 2-8 | Re-8 | D | 3.9 |
| Example 2-9 | Re-9 | C | 3.6 |
| Example 2-10 | Re-10 | B | 3.3 |
| Example 2-11 | Re-11 | E | 4.1 |
| Example 2-12 | Re-12 | E | 4.1 |
| Example 2-13 | Re-13 | E | 4.0 |
| Example 2-14 | Re-14 | D | 3.8 |
| Example 2-15 | Re-15 | F | 4.5 |
| Example 2-16 | Re-16 | C | 3.5 |
| Example 2-17 | Re-17 | D | 3.9 |
| Example 2-18 | Re-18 | C | 3.5 |
| Example 2-19 | Re-19 | C | 3.6 |
| Example 2-20 | Re-20 | B | 3.2 |
| Example 2-21 | Re-21 | C | 3.4 |
| Example 2-22 | Re-22 | F | 4.3 |
| Example 2-23 | Re-23 | E | 4.0 |
| Example 2-24 | Re-24 | E | 4.1 |
| Example 2-25 | Re-25 | F | 4.3 |
| Example 2-26 | Re-26 | E | 4.2 |
| Example 2-27 | Re-27 | D | 3.7 |
| Example 2-28 | Re-28 | B | 3.3 |
| Example 2-29 | Re-29 | B | 3.2 |
| Example 2-30 | Re-30 | C | 3.5 |
| Example 2-31 | Re-31 | C | 3.6 |
| Example 2-32 | Re-32 | B | 3.1 |
| Example 2-33 | Re-33 | A | 2.9 |
| Example 2-34 | Re-34 | C | 3.4 |
| Example 2-35 | Re-35 | C | 3.5 |
| Example 2-36 | Re-36 | D | 3.9 |
| Example 2-37 | Re-37 | C | 3.5 |
| Example 2-38 | Re-38 | B | 3.2 |
| Example 2-39 | Re-39 | C | 3.4 |
| Example 2-40 | Re-40 | B | 3.3 |
| Example 2-41 | Re-41 | B | 3.1 |
| Example 2-42 | Re-42 | B | 3.2 |
| Example 2-43 | Re-43 | C | 3.5 |
| Example 2-44 | Re-44 | C | 3.4 |
| Example 2-45 | Re-45 | A | 2.8 |
| Example 2-46 | Re-46 | B | 3.3 |
| Example 2-47 | Re-47 | B | 3.2 |
| Example 2-48 | Re-48 | B | 3.1 |
| Example 2-49 | Re-49 | E | 4.1 |
| Example 2-50 | Re-50 | A | 2.8 |
| Example 2-51 | Re-51 | A | 2.8 |
| Example 2-52 | Re-52 | A | 2.9 |
| Example 2-53 | Re-53 | A | 2.9 |
| Example 2-54 | Re-54 | B | 3.2 |
| Example 2-55 | Re-55 | B | 3.3 |
| Example 2-56 | Re-56 | B | 3.2 |
| Example 2-57 | Re-57 | C | 3.5 |
| Example 2-58 | Re-58 | A | 3.0 |
| Example 2-59 | Re-59 | B | 3.1 |
| Example 2-60 | Re-60 | C | 3.6 |
| Example 2-61 | Re-61 | C | 3.4 |
| Example 2-62 | Re-62 | C | 3.5 |
| Example 2-63 | Re-63 | D | 3.7 |
| Example 2-64 | Re-64 | C | 3.4 |
| Example 2-65 | Re-65 | B | 3.2 |
| Example 2-66 | Re-66 | B | 3.2 |
| Example 2-67 | Re-67 | B | 3.1 |
| Example 2-68 | Re-68 | B | 3.1 |

TABLE 12

| | | Evaluation | Evaluation |
|---|---|---|---|
| | | item 1 Defect | item 2 LWR |
| | Resist | suppression | performance |
| | composition | performance | (nm) |
| Comparative Example 2-1 | Re-1R | G | 5.0 |
| Comparative Example 2-2 | Re-2R | G | 5.1 |
| Comparative Example 2-3 | Re-3R | G | 5.4 |
| Comparative Example 2-4 | Re-4R | G | 5.6 |
| Comparative Example 2-5 | Re-5R | G | 5.7 |
| Comparative Example 2-6 | Re-6R | G | 5.7 |
| Comparative Example 2-7 | Re-7R | G | 5.8 |
| Comparative Example 2-8 | Re-8R | G | 5.1 |
| Example 2-69 | Re-69 | A | 3.0 |
| Example 2-70 | Re-70 | A | 2.9 |
| Example 2-71 | Re-71 | A | 2.9 |
| Example 2-72 | Re-72 | B | 3.2 |
| Example 2-73 | Re-73 | B | 3.3 |
| Example 2-74 | Re-74 | A | 2.9 |
| Example 2-75 | Re-75 | A | 3.0 |
| Example 2-76 | Re-76 | A | 3.0 |
| Example 2-77 | Re-77 | A | 2.9 |
| Example 2-78 | Re-78 | A | 3.0 |
| Example 2-79 | Re-79 | A | 2.9 |
| Example 2-80 | Re-80 | A | 2.9 |
| Example 2-81 | Re-81 | B | 3.2 |
| Example 2-82 | Re-82 | B | 3.3 |
| Example 2-83 | Re-83 | B | 3.1 |
| Example 2-84 | Re-84 | B | 3.2 |
| Example 2-85 | Re-85 | B | 3.3 |
| Example 2-86 | Re-86 | B | 3.3 |
| Example 2-87 | Re-87 | B | 3.1 |
| Example 2-88 | Re-88 | B | 3.2 |
| Example 2-89 | Re-89 | B | 3.3 |
| Example 2-90 | Re-90 | B | 3.1 |
| Example 2-91 | Re-91 | B | 3.3 |
| Example 2-92 | Re-92 | B | 3.2 |
| Example 2-93 | Re-93 | B | 3.2 |
| Example 2-94 | Re-94 | B | 3.3 |
| Example 2-95 | Re-95 | B | 3.1 |
| Example 2-96 | Re-96 | B | 3.1 |

Tables 11 and 12 above have demonstrated that resist compositions of the present invention exhibit high defect performance (defect suppression performance) and high LWR performance even in the case of forming an ultrafine pattern by alkaline aqueous solution development. On the other hand, the resist compositions of Comparative Examples were insufficient in terms of these performances.

Note that, even in the case of using an electron beam as the exposure light source, resist compositions of the present invention exhibit high defect performance (defect suppression performance) and high LWR performance in the case of forming an ultrafine pattern as in Examples 1-1 to 1-96 and Examples 2-1 to 2-96.

The present invention can provide an actinic ray-sensitive or radiation-sensitive resin composition that can suppress generation of defects and has high roughness performance in formation of an ultrafine pattern (for example, a line-and-space pattern having a line width of 35 nm or less, or a hole pattern having a hole diameter of 35 nm or less); an actinic ray-sensitive or radiation-sensitive resin film formed from the actinic ray-sensitive or radiation-sensitive resin composition; and a pattern forming method and a method for producing an electronic device that use the actinic ray-sensitive or radiation-sensitive resin composition.

The present invention has been described in detail and with reference to specific embodiments thereof; however, it would be apparent to those skilled in the art that various changes and modifications can be made therein without departing from the spirit and scope of the present invention.

What is claimed is:

1. An actinic ray-sensitive or radiation-sensitive resin composition comprising:
a resin (A) including a repeating unit (i) represented by a formula (N-0) below, a repeating unit (ii) having a cyano group and a lactone structure, and a repeating unit (iii) having a phenolic hydroxy group,
wherein a content of a repeating unit having an acid-decomposable group in the resin (A) relative to all repeating units in the resin (A) is 35 mol % or more, 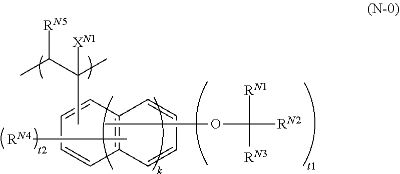
in the formula (N-0), X^{N1} represents a hydrogen atom, a halogen atom, a hydroxy group, or an organic group;
k represents 0 or 1;
R^{N1} to R^{N3} each independently represent an alkyl group having 1 to 12 carbon atoms or a cycloalkyl group having 3 to 12 carbon atoms;
two among R^{N1} to R^{N3} may be bonded together to form a ring;
R^{N4} represents a halogen atom, a hydroxy group, or an organic group;
when a plurality of R^{N1} to R^{N4} are present, the plurality of R^{N1} to R^{N4} may be individually the same or different;
R^{N5} represents a hydrogen atom or an organic group;
R^{N4} and R^{N5} may be bonded together to form a ring;
t1 represents an integer of 1 or more and (5+2k) or less; and
t2 represents an integer of 0 or more and (5+2k-t1) or less.

2. The actinic ray-sensitive or radiation-sensitive resin composition according to claim 1, wherein the repeating unit (i) is a repeating unit represented by a formula (N-1) below: 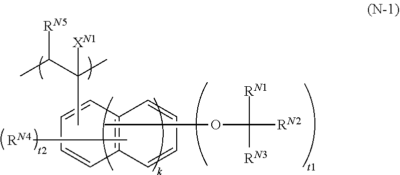
in the formula (N-1), each of X^{N1}, R^{N1} to R^{N5}, k, t1, and t2 has the same meaning as each of X^{N1}, R^{N1} to R^{N5}, k, t1, and t2 in the formula (N-0).

3. The actinic ray-sensitive or radiation-sensitive resin composition according to claim 1, wherein the repeating unit (i) is a repeating unit represented by a formula (N-2) below: 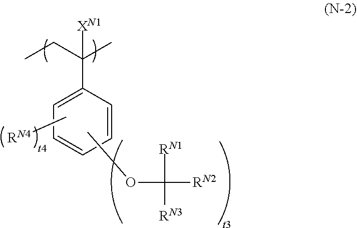
in the formula (N-2), each of X^{N1} and R^{N1} to R^{N4} has the same meaning as each of X^{N1} and R^{N1} to R^{N4} in the general formula (N-0); t3 represents an integer of 1 or more and 5 or less;
and t4 represents an integer of 0 or more and 4 or less.

4. The actinic ray-sensitive or radiation-sensitive resin composition according to claim 1, wherein the repeating unit (ii) is a repeating unit represented by a formula (Q-1) below: 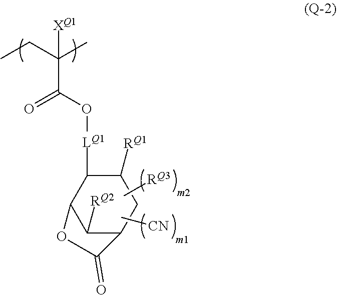
in the formula (Q-1), X^{Q1} represents a hydrogen atom, a halogen atom, a hydroxy group, or an organic group;
L^{Q1} represents a single bond or a divalent organic group;
R^{Q1} and R^{Q2} each independently represent a hydrogen atom, an alkyl group having 1 to 5 carbon atoms, an alkoxy group having 1 to 5 carbon atoms, or an alkylthio group having 1 to 5 carbon atoms, or R^{Q1} and R^{Q2} are bonded together to represent an alkylene group having 1 to 6 carbon atoms that may include at least one of an oxygen atom or a sulfur atom, an ether bond, or a thioether bond;
R^{Q3} represents a halogen atom, a hydroxy group, or an organic group;
m1 represents an integer of 1 to 6; and
m2 represents an integer of 0 to 5.

5. The actinic ray-sensitive or radiation-sensitive resin composition according to claim 1, wherein the repeating unit (i) is a repeating unit represented by a formula (N-3) below: 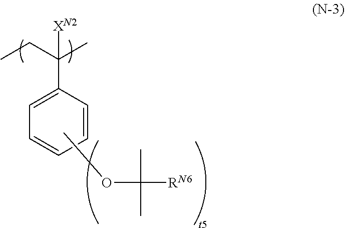
in the formula (N-3), X^{N2} represents a hydrogen atom, a halogen atom, or a methyl group; R^{N6} represents a methyl group or an ethyl group; and t5 represents 1 or 2.

6. The actinic ray-sensitive or radiation-sensitive resin composition according to claim 1, wherein the resin (A) includes a repeating unit represented by a formula (E-1) below: 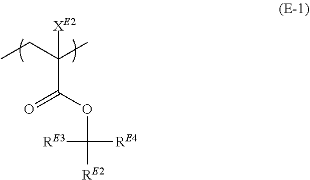
in the formula (E-1), X^{E1} represents a hydrogen atom, a halogen atom, a hydroxy group, or an organic group; R^{E1} to R^{E3} each independently represent a hydrocarbon group having 1 to 12 carbon atoms; two among R^{E1} to R^{E3} may be bonded together to form a ring; and when hydrocarbon groups represented by R^{E1} to R^{E3} include alkylene groups, a part of the alkylene groups may be replaced by an ether group, a thioether group, or a carbonyl group.

7. The actinic ray-sensitive or radiation-sensitive resin composition according to claim 1, wherein the content of the repeating unit having an acid-decomposable group in the resin (A) relative to the all repeating units in the resin (A) is 40 mol % or more.

8. The actinic ray-sensitive or radiation-sensitive resin composition according to claim 1, wherein the content of the repeating unit having an acid-decomposable group in the resin (A) relative to the all repeating units in the resin (A) is 45 mol % or more.

9. The actinic ray-sensitive or radiation-sensitive resin composition according to claim 1, wherein the resin (A) includes a repeating unit represented by a formula (E-2) below: 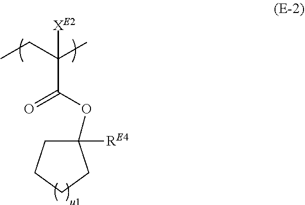
in the formula (E-2), X^{E2} represents a hydrogen atom, a halogen atom, or a methyl group; R^{E4} represents a hydrocarbon group having 6 or less carbon atoms; and u1 represents 1 or 2.

10. The actinic ray-sensitive or radiation-sensitive resin composition according to claim 1, wherein the resin (A) has a molecular-weight dispersity of 1.70 or less.

11. The actinic ray-sensitive or radiation-sensitive resin composition according to claim 1, comprising an onium salt compound as a compound other than the resin (A).

12. The actinic ray-sensitive or radiation-sensitive resin composition according to claim 1, comprising a photoacid generator.

13. The actinic ray-sensitive or radiation-sensitive resin composition according to claim 1, wherein a total number of carbon atoms of R^{N1} to R^{N3} above is 3 to 25.

14. An actinic ray-sensitive or radiation-sensitive film formed from the actinic ray-sensitive or radiation-sensitive resin composition according to claim 1.

15. A pattern forming method comprising:
using the actinic ray-sensitive or radiation-sensitive resin composition according to claim 1 to form an actinic ray-sensitive or radiation-sensitive film on a substrate;
exposing the actinic ray-sensitive or radiation-sensitive film; and
using a developer to develop the exposed actinic ray-sensitive or radiation-sensitive film to form a pattern.

16. A method for producing an electronic device, the method comprising the pattern forming method according to claim 15.
